(19) United States
(12) Patent Application Publication
(10) Pub. No.: US 2025/0163278 A1
(43) Pub. Date: May 22, 2025

(54) CONDUCTIVE ARTICLES AND METHODS FOR ADDITIVE MANUFACTURING THEREOF

(71) Applicant: PPG INDUSTRIES OHIO, INC., Cleveland, OH (US)

(72) Inventors: Bret Michael Boyle, Pittsburgh, PA (US); Cynthia Kutchko, Pittsburgh, PA (US); Connor Andrew Accettulla, Natrona Heights, PA (US); Kevin Mark Valdisera, Pittsburgh, PA (US); Nicolas B. Duarte, Allison Park, PA (US); David Leanordo Gonzalez Arellano, Cheswick, PA (US)

(73) Assignee: PPG INDUSTRIES OHIO, INC., Cleveland, OH (US)

(21) Appl. No.: 18/841,047

(22) PCT Filed: Feb. 22, 2023
(86) PCT No.: PCT/US2023/062971

§ 371 Date: Aug. 23, 2024

Related U.S. Application Data
(60) Provisional application No. 63/312,985, filed on Feb. 23, 2022.

(51) Int. Cl. C09D 5/24; B29C 64/118; B29C 64/314; B29K 33/00; B29K 75/00; B29K 105/00; B29K 505/10; B29K 505/14; B29L 31/34; B33Y 10/00; B33Y 40/10; B33Y 70/10; B33Y 80/00; C08K 7/00; C08K 9/02; C09D 7/40; C09D 7/62; C09D 175/02; C09D 179/02; G01D 5/24

(52) U.S. Cl. CPC C09D 5/24; B29C 64/118; B29C 64/314; B33Y 10/00; B33Y 40/10; B33Y 70/10; B33Y 80/00; C09D 7/62; C09D 7/70; C09D 175/02; C09D 179/02; G01D 5/24; B29K 2033/00; B29K 2075/02; B29K 2105/0005; B29K 2505/10; B29K 2505/14; B29K 2995/0005; B29K 2995/0077; B29K 2995/0082; B29K 2995/0096; B29L 2031/3425; C08K 7/00; C08K 9/02; C08K 2201/001

(57) ABSTRACT

Aspects of the disclosure relate to a method of forming an article including: combining first and second chemical components that are reactive with each other to form a coreactive composition; depositing the coreactive composition to form a conductive portion of an article; wherein, 48 hours after depositing, the conductive portion comprises: a tensile modulus of at least 5 MPa; and an electrical conductivity of at least 2 S/m; wherein the coreactive composition comprising: a solvent content less than 5 wt %; and a conductive filler content effective for the conductive portion to reach the electrical conductivity of at least 2 S/m.

### CROSS-REFERENCE TO RELATED APPLICATIONS

This application claims the benefit under 35 U.S.C. § 119(e) of U.S. Provisional Application No. 63/312,985, filed on Feb. 23, 2022 which is incorporated by reference in its entirety.

### FIELD

The present disclosure relates to conductive articles and methods and compositions for additive manufacturing thereof. The present disclosure further relates to articles with at least a conductive portion and methods and compositions for additively manufacturing thereof. The linear sealing components may be used in automotive, architectural, industrial, and aerospace applications.

### BACKGROUND

Additive manufacturing facilitates the ability to fabricate complex parts. However, many additive manufacturing methods are limited to the use of certain materials and chemistries, such as thermoplastics. Additive manufacturing compositions and methods that facilitate the fabrication of conductive and durable parts are desired.

### SUMMARY

Aspects of the present disclosure relate to combining first and second chemical components that are reactive with each other to form a coreactive composition; depositing the coreactive composition to form a conductive portion of an article; wherein, 48 hours after depositing, the conductive portion comprises: a tensile modulus of at least 5 MPa; and an electrical conductivity of at least 2 S/m; wherein the coreactive composition comprising: a solvent content less than 5 wt %; and a conductive filler content effective for the conductive portion to reach the electrical conductivity of at least 2 S/m.

### DESCRIPTION OF THE DRAWINGS

The drawings described herein are for illustration purposes only. The drawings are not intended to limit the scope of the present disclosure.

FIG. 1A is an image showing an additively manufactured capacitive sensor before activation.

FIG. 1B is an image showing the additively manufactured capacitive sensor of FIG. 2A after activation.

FIG. 2A is an image showing an additively manufactured conductive filament on a substrate.

FIG. 2B is an image showing an additively manufactured conductive filament substantially embedded in a matrix.

FIG. 3 is an image showing an additively manufactured conductive strip in a flex state.

### DETAILED DESCRIPTION

### I. Definitions

For purposes of the following detailed description, it is to be understood that the invention may assume various alternative variations and step sequences, except where expressly specified to the contrary. Moreover, other than in any operating examples or where otherwise indicated, all numbers expressing, for example, quantities of ingredients used in the specification and claims are to be understood as being modified in all instances by the term “about.” Accordingly, unless indicated to the contrary, the numerical parameters set forth in the following specification and attached claims are approximations that may vary depending upon the desired properties to be obtained by the present invention. At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard variation found in their respective testing measurements.

Also, it should be understood that any numerical range recited herein is intended to include all sub-ranges subsumed therein. For example, a range of “1 to 10” is intended to include all sub-ranges between (and including) the recited minimum value of 1 and the recited maximum value of 10, that is, having a minimum value equal to or greater than 1 and a maximum value of equal to or less than 10.

The use of the singular includes the plural and plural encompasses singular, unless specifically stated otherwise. In addition, the use of “or” means “and/or” unless specifically stated otherwise, even though “and/or” may be explicitly used in certain instances.

“Extrusion” refers to a process used to create articles in which material is pushed through a die. An extrusion die has a shape and dimensions suitable to build an article. An extrusion die may have a fixed shape or a shape that can be changed intermittently or continuously during extrusion. Co-extrusion can be used to combine one or more compositions forming the extrudate. Co-extrusion can be used to provide regions having different compositions across the profile of a part. For example, a core of an extrudate can have one composition, one side of the extrudate can have a second composition, and one side of the extrudate can have a third composition. For example, a part can be fabricated having an aesthetic exterior surface and an electrically conductive inner surface and/or an electrically conductive inner region.

“Formed from” or “prepared from” denotes open, e.g., comprising, language. As such, it is intended that a composition “formed from” or “prepared from” a list of recited components be a composition comprising at least the recited components or the reaction product of at least the recited components, and can further comprise other, non-recited components used to form or prepare the composition.

“Reaction product of” means chemical reaction product(s) of the recited reactants and can include partial reaction products as well as fully reacted products and other reaction products that are present in a lesser amount.

“Monomer” refers to a compound characterized, for example, by a molecular weight less than 1,000 Da, less than 800 Da, less than 600 Da, less than 500 Da, or less than 400 Da. A monomer may or may not have repeating units. A monomer can comprise two or more, such as from 2 to 6, reactive functional groups. A monomer encompasses certain polyfunctionalizing agents. Upon curing, a monomer need not be incorporated into the cured polymer network.

“Polyfunctionalizing agent” refers to a compound having reactive functionality of three or more, such as from 3 to 6. A polyfunctionalizing agent can have three reactive functional groups and can be referred to as a trifunctionalizing agent. A polyfunctionalizing agent can have, for example, reactive terminal thiol groups, reactive terminal alkenyl groups, reactive isocyanate groups, reactive epoxy groups, reactive Michael donor groups, reactive Michael acceptor groups, or reactive amine. A polyfunctionalizing agent can have a calculated molecular weight, for example, less than 2,000 Da, less than 1,800 Da, less than 1,400 Da, less than 1,200 Da, less than 1,000 Da, less than 800 Da, less than 700 Da, less than 600 Da, less than 500 Da, less than 400 Da, less than 300 Da, or less than 200 Da. For example, a polyfunctionalizing agent can have a calculated molecular weight from 100 Da to 2,000 Da, from 200 Da to 2,000 Da, from 200 Da to 1,800 Da, from 300 Da to 1,500 Da, or from 300 Da to 1,000 Da. A polyfunctionalizing agent can have the structure of Formula (1) B(−V)_{z} where B¹ is the core of the polyfunctionalizing agent, each V is a moiety terminated in a reactive functional group such as a thiol group, an alkenyl group, an epoxy group, an isocyanate group, or a Michael acceptor group, and z is an integer from 3 to 6, such as 3, 4, 5, or 6.

“Prepolymer” refers to oligomers, homopolymers, and copolymers including block copolymers and graft copolymers. A prepolymer can have a number average molecular weight, for example, from 1,000 Da to 20,000 Da, from 1,000 Da to 10,000 Da, or from 2,000 Da to 5,000 Da. For thiol-terminated prepolymers, molecular weights are number average molecular weights “Mn” as determined by end group analysis using iodine titration. For prepolymers that are not thiol-terminated, the number average molecular weights are determined by gel permeation chromatography using polystyrene standards. A prepolymer such as a thiol-terminated sulfur-containing prepolymer provided by the present disclosure can be combined with a curing agent to provide a curable composition, which can cure to provide a cured polymer network. Prepolymers are liquid at room temperature (25° C.) and pressure (760 torr; 101 kPa).

“Reactive functional group” refers to a chemical group capable of chemically reacting with another reactive functional group.

“Coreactive composition” refers to a composition comprising at least two coreactive compounds capable of chemically reacting with each other.

“Gel time” refers to the duration from when a coreactive composition is first mixed to the time the composition becomes a solid and is no longer stirrable by hand.

“Tack free time” refers to the duration from when a reactive composition is first mixed to the time a cotton ball applied to the surface of the reactive composition does not adhere.

“Full cure time” refers to duration between the time when mutually coreactive components are first combined and mixed to form a reactive composition until the time when the hardness of the composition no longer increases.

“Isocyanate” refers to a —N═C═O group.

“Alkenyl” refers to a —CH═CH₂ group.

“Alkynyl” refers to a —C≡CH group.

A “polyalkenyl” refers to a compound having at least two alkenyl groups. The at least two alkenyl groups can be terminal alkenyl groups and such polyalkenyls can be referred to as alkenyl-terminated compounds. Alkenyl groups can also be pendent alkenyl groups. A polyalkenyl can be a dialkenyl, having two alkenyl groups. A polyalkenyl can have more than two alkenyl groups such as from three to six alkenyl groups. A polyalkenyl can comprise a single type of polyalkenyl, can be a combination of polyalkenyls having the same alkenyl functionality, or can be a combination of polyalkenyls having different alkenyl functionalities.

“Thiol” refers to an —SH group.

“Amine” refers to a —N(R)₂ group where each R is independently selected from hydrogen and an organic group. An amine can comprise a primary amine group (—NH₂), a secondary amine group (—NH—), a tertiary amine group (—NH₃), or a combination of any of the foregoing.

“Michael donor” refers to compounds capable of reacting with activated alkenyl groups in a 1,4-addition reaction. Examples of Michael donors include activated methylenes such as malonates and nitroalkanes.

“Michael acceptor” refers to an activated alkene, such as an alkenyl group proximate to an electron-withdrawing group such as a ketone, nitro, halo, nitrile, carbonyl, or nitro group. Michael acceptors are well known in the art. A “Michael acceptor group” refers to an activated alkenyl group and an electron-withdrawing group. A Michael acceptor group can be selected from a vinyl ketone, a vinyl sulfone, a quinone, an enamine, a ketimine, oxazolidine, and an acrylate. Other examples of Michael acceptors include acrylate esters, acrylonitrile, acrylamides, maleimides, alkyl methacrylates, cyanoacrylates. Other Michael acceptors include vinyl ketones, α,β-unsaturated aldehydes, vinyl phosphonates, acrylonitrile, vinyl pyridines, certain azo compounds, R-keto acetylenes and acetylene esters.

“Actinic radiation” refers to energy that can be applied to a composition to generate a reaction initiating species from a photopolymerization initiator upon irradiation therewith, and includes, for example, α-rays, γ-rays, X-rays, ultraviolet (UV) light, visible light, infrared, or an electron beam.

“Residence time” refers to the duration after two mutually reactive components are first mixed to form a coreactive composition until the time the coreactive composition is extruded from a deposition apparatus such as, for example, the time when the coreactive composition is extruded from a nozzle connected to a mixer. For example, a nozzle can have a length between where the nozzle is coupled to a mixer and the exit orifice, and the length of time that a coreactive composition is in the nozzle is the residence time.

Specific gravity is determined according to ASTM D1475.

Shore A hardness is measured using a Type A durometer in accordance with ASTM D2240.

Tensile strength and elongation are measured according to AMS 3279.

“Viscosity” is measured using an Anton Paar MCR 302 rheometer with a gap from 1 mm at 25° C. and a shear rate of 100 sec⁻¹. “Low shear viscosity” is measured using an Anton Paar MCR 302 rheometer with a gap from 1 mm at 25° C. and a shear rate of 1 sec⁻¹. High shear viscosity” is measured using an Anton Paar MCR 302 rheometer with a gap from 1 mm at 25° C. and a shear rate of 100 sec⁻¹. Dynamic viscosity is measured using an Anton Paar MCR 302 rheometer with a 25 mm-diameter parallel plate spindle, an oscillation frequency of 1 Hz and amplitude of 0.3%, and with a rheometer plate temperature of 25° C.

Reference is now made to certain compounds, compositions, and methods of the present invention. The disclosed compounds, compositions, and methods are not intended to be limiting of the claims. To the contrary, the claims are intended to cover all alternatives, modifications, and equivalents.

### II. Introduction

Additive manufacturing using coreactive components has several advantages compared to alternative additive manufacturing methods. Additive manufacturing using coreactive components can create stronger parts because the materials forming successive layers can be co-reacted to form bonds between the layers. Also, because the coreactive components may have a low viscosity when first combined, higher filler content can be used while being able to maintain manufacturability of the coreactive composition. The higher filler content can be used, for example, to modify the physical, mechanical, thermal, magnetic, and/or electrical properties of the materials of the built article. The use of coreactive compounds with different coreactive functional groups can extend the chemistries used in additively manufacturing parts to provide improved properties such as solvent resistance, electrical conductivity, thermal conductivity, and low density. Finally, because the curing rate of the coreactive compounds can be fast, coreactive additive manufacturing can facilitate the use of high speed, high throughput manufacturing.

For additive manufacturing of coreactive components it is generally desirable that the rate of reaction between the coreactive components and/or the manufacturing process be controlled such that the composition maintains a relatively low viscosity during deposition and then increases rapidly following application to provide a stable base upon which to apply subsequent layers. The low viscosity during deposition can facilitate faster printing rates and facilitate the use of simpler manufacturing equipment. When deposited, the composition can maintain an intended shape and can support overlying layers of the deposited composition.

The present disclosure relates to articles having at least a conductive portion, and methods and compositions for making thereof. In various examples, the compositions may include 100% or near 100% solids with minimal to no solvent content (e.g., less than 1%). Further, the compositions may include coreactive compositions (e.g., polyurea, urethane, epoxy, Aza-Michael addition systems) with conductive fillers (e.g., silver, copper, graphene) mixed in at high solids loadings (e.g., more than 50 wt % and/or 50 vol %). In certain examples, the compositions, upon deposition, may adhere to various types of surfaces, including plastic (e.g., cured polyurea), metal, ceramic, and glass (e.g., ITO-coated glass). In some examples, the deposited compositions may function as busbars or impedance-based capacitive sensor, depending on the printed pattern. In various examples, the composition may be deposited onto a transparent substrate or object in a way (e.g., with certain spacing and/or filament size) to be visually transparent or near-transparent to the eye. In some examples, compositions may be formulated to be, in addition to being electrically conductive, corrosion-resistant, flexible, and/or thermally conductive, such as by including additional fillers (organic or inorganic). The compositions may have conductivities on the order of bulk graphite.

Conductive compositions of the present disclosure may be deposited directly onto another 3D printed part. In certain examples, the deposited conductive compositions may further be embedded within a 3D printed part. For example, the deposition of the conductive composition may be part of a multi-material printing process configured to produce an article including regions having different materials and/or properties. In some examples, conductive fillers may be incorporated into thermoset reactive compositions and mixed prior to being deposited. In various examples, conductive compositions may be flexible, such as upon deposition and/or after cure, and may form a portion of a flexible article. In certain examples, conductive filaments deposited using conductive compositions of the present disclosure may have widths from 1 mm to 2 mm and thickness from 0.25 mm to 2 mm. In various examples, compositions of the present disclosure may cure and become conductive at room temperature without application of heat or actinic radiation.

Conductive compositions of the present disclosure may be formulated to meet one or more property metrics, including electrical conductivity, tensile strength, flexural strength, and/or corrosion-resistance. In some examples, morphology of conductive fillers may be selected such that, once the conductive compositions cure, the conductive network formed by the conductive fillers may maintain (e.g., in a deformed state) conductive even when bent, flexed, or deformed in other way. In some examples, to achieve an electrical conductivity target, a modest filler loading of 30 to 50 wt % may be desired for conductive fillers of larger size (e.g., silver flakes at 60 μm), whereas a larger filler loading of 70 to 80 wt % may be desired for conductive fillers of larger size (e.g., silver flakes at 10 μm). Such filler loading range may differ for different filler materials (e.g., silver, silver-coated copper, copper, graphene) and may or may not be dependent on the coreactive composition the conductive fillers are incorporated into (e.g., polyurea, polyurethane).

It is to be understood that the conductive compositions of the present disclosure may be used for a myriad of applications, including automotive, aerospace, architectural, and electronics. As an example, capacitive sensing circuits may be created by 3D printing a sensor pattern using a conductive composition of the present disclosure. As other examples, busbars for power distribution, embedded electronic interconnects or switches, and compression or extension sensors may also be created by 3D printing a sensor pattern using a conductive composition of the present disclosure.

Conductivity of the conductive composition may be modified by changing the mixing ratio of the components (e.g., coreactive components and fillers), such as dynamically during deposition via a mixer, such as in a mixing chamber where components may be fed therethrough. In some aspects, conductive fillers may be added to coreactive components prior to being combined into a single conductive coreactive composition. Circuits made using the conductive composition of the present disclosure may be used for power supply applications. In some aspects, deposition of the conductive composition above and/or below a non-conductive matrix at a print speed and/or lapse time may allow covalent bonding.

There are a number of chemistries that can be employed in additive manufacturing of coreactive components. Examples of coreactive systems include polyisocyanates and polyamines which form polyureas. Because of their versatility, polyureas are attractive for use in reactive additive manufacturing. The reaction of polyisocyanates and polyamines can proceed rapidly at room temperature thereby avoiding the need to control heat flow during deposition. The polyurea reaction can also proceed rapidly in the absence of a catalyst.

### III. Composition for Printing Conductive Parts

Compositions for additive manufacturing can comprise a combination of coreactive compounds and a conductive filler. Conductive compositions and conductive filler include materials, for example, that are electrically conductive, thermally conductive, magnetic, static dissipative, electroactive, photoactive, or a combination of any of the foregoing. A cured conductive composition may have more than one conductive property. For example, an electrically conductive material can also be thermally conductive. The materials can be characterized as having a high wt % and/or vol % loading of conductive material, such as a content of conductive particles greater than 20 wt % and/or greater than 20 vol %, where wt % and vol % are based on the total weight or volume of the conductive composition, respectively.

A composition can comprise a first coreactive component comprising a first coreactive compound, wherein the first coreactive compound comprises at least one first functional group; and a second coreactive component comprising a second coreactive compound, wherein the second coreactive compound comprises at least one second functional group, wherein the at least one first functional group is reactive with the at least one second functional group; and wherein the composition comprises a conductive filler.

The composition can be prepared by combining the first coreactive component and the second coreactive component to provide the composition. The first coreactive component and/or the second coreactive component can comprise filler. A third coreactive component can comprise filler and the third component can be added to the composition to provide a composition having filler.

### IV. Coreactive Compounds

Each of the first coreactive compound and the second coreactive compound can independently comprise at least one functional group. The first coreactive compound can comprise at least one functional group and the second coreactive compound can comprise at least one functional group, wherein the at least one first functional group is reactive with the at least one second functional group.

The first coreactive compound and the second coreactive compound can be reactive at a temperature, for example, less than 50° C., less than 40° C., less than 30° C., or less than 20° C.

The first coreactive compound and the second coreactive compound can be reactive at a temperature, for example from 5° C. to 50° C., from 10° C. to 40° C., from 15° C. to 30° C., from 20° C. to 25° C., or within any range defined between any of the foregoing two values and endpoints.

The reaction may take place in the presence of a catalyst or in the absence of a catalyst.

Each of the first coreactive compound and the second coreactive compound can independently comprise a monomer or a combination of monomers, a prepolymer or a combination of prepolymers, or a combination of any of the foregoing. The reactants can further include, for example, polyfunctionalizing agents, reactive diluents, and combinations of any of the foregoing.

A monomer can have, for example, a molecular weight less than 1,000 Da, less than 800 Da, less than 600 Da, less than 400 Da, or less than 200 Da.

A monomer can have, for example, a molecular weight from 100 Da to 1,000 Da, from 200 Da to 800 Da, from 400 Da to 600 Da, or within any range defined between any of the foregoing two values and endpoints.

A prepolymer can have a number average molecular weight, for example, less than 10,000 Da, less than 8,000 Da, less than 6,000 Da, or less than 4,000 Da.

A prepolymer can have a number average molecular weight, for example, from 1,000 Da to 10,000 Da, from 2,000 Da, to 8,000 Da, from 3,000 Da to 6,000 Da, or within any range defined between any of the foregoing two values and endpoints.

Prepolymers can include copolymers such as alternating copolymers, random copolymers, and/or block copolymers.

A prepolymer can comprises any suitable backbone. A prepolymer backbone can be selected, for example, based on the end use requirements of the part or article to be fabricated using the conductive co-reactive composition. A prepolymer backbone can be selected based considerations of tensile strength, elongation, thermal resistance, chemical resistance, low temperature flexibility, hardness, and a combination of any of the foregoing.

For example, a prepolymer backbone can comprise a polythioether, a polysulfide, a polyformal, a polyisocyanate, a polyurea, polycarbonate, polyphenylene sulfide, polyethylene oxide, polystyrene, acrylonitrile-butadiene-styrene, polycarbonate, styrene acrylonitrile, poly(methylmethacrylate), polyvinylchloride, polybutadiene, polybutylene terephthalate, poly(p-phenyleneoxide), polysulfone, polyethersulfone, polyethylenimine, polyphenylsulfone, acrylonitrile styrene acrylate, polyethylene, syndiotactic or isotactic polypropylene, polylactic acid, polyamide, ethyl-vinyl acetate homopolymer or copolymer, polyurethane, copolymers of ethylene, copolymers of propylene, impact copolymers of propylene, polyetheretherketone, polyoxymethylene, syndiotactic polystyrene (SPS), polyphenylene sulfide (PPS), liquid crystalline polymer (LCP), homo- and copolymer of butene, homo- and copolymers of hexene; and combinations of any of the foregoing.

Examples of other suitable polymers include polyolefins (such as polyethylene, linear low density polyethylene (LLDPE), low density polyethylene (LDPE), high density polyethylene, polypropylene, and olefin copolymers), styrene/butadiene rubbers (SBR), styrene/ethylene/butadiene/styrene copolymers (SEBS), butyl rubbers, ethylene/propylene copolymers (EPR), ethylene/propylene/diene monomer copolymers (EPDM), polystyrene (including high impact polystyrene), poly(vinyl acetates), ethylene/vinyl acetate copolymers (EVA), poly(vinyl alcohols), ethylene/vinyl alcohol copolymers (EVOH), poly(vinyl butyral), poly(methyl methacrylate) and other acrylate polymers and copolymers (including such as methyl methacrylate polymers, methacrylate copolymers, polymers derived from one or more acrylates, methacrylates, ethyl acrylates, ethyl methacrylates, butyl acrylates, butyl methacrylates and the like), olefin and styrene copolymers, acrylonitrile/butadiene/styrene (ABS), styrene/acrylonitrile polymers (SAN), styrene/maleic anhydride copolymers, isobutylene/maleic anhydride copolymers, ethylene/acrylic acid copolymers, poly(acrylonitrile), polycarbonates (PC), polyamides, polyesters, liquid crystalline polymers (LCPs), poly(lactic acid), poly(phenylene oxide) (PPO), PPO-polyamide alloys, polysulfone (PSU), polyetherketone (PEK), polyetheretherketone (PEEK), polyimides, polyoxymethylene (POM) homo- and copolymers, polyetherimides, fluorinated ethylene propylene polymers (FEP), poly(vinyl fluoride), poly(vinylidene fluoride), poly(vinylidene chloride), and poly(vinyl chloride), polyurethanes (thermoplastic and thermosetting), aramides (such as Kevlar® and Nomex®), polytetrafluoroethylene (PTFE), polysiloxanes (including polydimethylenesiloxane, dimethylsiloxane/vinylmethylsiloxane copolymers, vinyldimethylsiloxane terminated poly(dimethylsiloxane)), elastomers, epoxy polymers, polyureas, alkyds, cellulosic polymers (such as ethyl cellulose, ethyl hydroxyethyl cellulose, carboxymethyl cellulose, cellulose acetate, cellulose acetate propionates, and cellulose acetate butyrates), polyethers and glycols such as poly(ethylene oxide)s (also known as poly(ethylene glycol)s, poly(propylene oxide)s (also known as poly(propylene glycol)s, and ethylene oxide/propylene oxide copolymers, acrylic latex polymers, polyester acrylate oligomers and polymers, polyester diol diacrylate polymers, and UV-curable resins.

Examples of suitable elastomers include polyurethanes, copolyetheresters, rubbers such as butyl rubbers and natural rubbers, styrene/butadiene copolymers, styrene/ethylene/butadiene/styrene copolymer (SEBS), polyisoprene, ethylene/propylene copolymers (EPR), ethylene/propylene/diene monomer copolymers (EPDM), polysiloxanes, and polyethers such as poly(ethylene oxide), poly(propylene oxide), and their copolymers.

Examples of suitable polyamides include aliphatic polyamides (such as polyamide 4,6; polyamide 6,6; polyamide 6; polyamide 11; polyamide 12; polyamide 6,9; polyamide 6,10; polyamide 6,12; polyamide 10,10; polyamide 10,12; and polyamide 12,12), alicyclic polyamides, and aromatic polyamides such as poly(m-xylylene adipamide) (polyamide MXD, 6), and polyterephthalamides such as poly(dodecamethylene terephthalamide) (polyamide 12,T), poly(decamethylene terephthalamide) (polyamide 10,T), poly(nonamethylene terephthalamide) (polyamide 9,T), the polyamide of hexamethylene terephthalamide and hexamethylene adipamide, the polyamide of hexamethyleneterephthalamide, and 2-methylpentamethyleneterephthalamide).

Examples of suitable polyesters include poly(butylene terephthalate) (PBT), poly(ethylene terephthalate) (PET), poly(1,3-propylene terephthalate) (PPT), poly(ethylene naphthalate) (PEN), and poly(cyclohexanedimethanol terephthalate) (PCT).

A prepolymer can be terminated in any suitable functional group to achieve a desired curing chemistry. For example, a commercially available prepolymer can be reacted with a coreactive compound have a desired functional group and a group reactive with a terminal group of the commercially available prepolymer to adapt the commercially available prepolymer to a particular curing chemistry.

Each of the first coreactive compound and the second coreactive compound can comprise a respective reactive functionality such as, for example, a reactive functionality less than 12, less than 10, less than 8, less than 6, or less than 4. Each of the first coreactive compound and the second coreactive compound can independently comprise a reactive functionality greater of 2 or more, greater than 3, greater than 5, or greater than 10. Each of the first coreactive compound and the second coreactive compound can comprise a respective reactive functionality, for example, from 2 to 12, from 2 to 8, from 2 to 6, from 2 to 4, from 2 to 3, or within any range defined between any of the foregoing two values and endpoints. Each of the first coreactive compound and the second coreactive compound can independently have a functionality, for example, of 2, 3, 4, 5, 6, 7, 8, 9, 10, 11, or 12.

Each of the first coreactive compound and the second coreactive compound can independently comprise a combination of coreactive compounds having different reactive functionalities. The combination of coreactive compounds can be characterized by a non-integer value of reactive functionalities such as from 2.1 to 3.9, or from 2.1 to 2.9.

Each of the functional groups of the first coreactive compound and/or the second coreactive compound can be the same or at least some of the functional group can be different. Each of the first coreactive compound and the second coreactive compound can independently comprise a combination of coreactive compounds having the same functional group, a combination of coreactive compounds having different functional groups, or a combination of coreactive compounds in which some have the same functional group and other coreactive compounds have a different functional group.

### V. Functional Groups

The first functional group is reactive with the second functional group. The first functional group and the second functional group can react at a temperature, for example, less than 50° C., less than 40° C., less than 30° C., or less than 20° C. The first functional group and the second functional group can react at a temperature, for example from 5° C. to 50° C., from 10° C. to 40° C., from 15° C. to 30° C., from 20° C. to 25° C., or within any range defined between any of the foregoing two values and endpoints.

A first functional group can be a saturated functional group and the second functional group can be an unsaturated group. Each of the first functional group and the second functional can comprise a saturated functional group. Each of the first functional group and the second functional can comprise an unsaturated functional group.

A saturated functional group refers to a functional group having a single bond. Examples of saturated functional groups include thiol, hydroxyl, primary amine, secondary amine, and epoxy groups.

An unsaturated functional group refers to a group having a reactive double bond. Examples of unsaturated functional groups include alkenyl groups, Michael acceptor groups, isocyanate groups, acyclic carbonate groups, acetoacetate groups, carboxylic acid groups, vinyl ether groups, (meth)acrylate groups, and malonate groups.

The first functional group can be a carboxylic acid group and the second functional group can be an epoxy group.

The first functional group can be a Michael acceptor group such as an acrylate group, a maleic group, or a fumaric group, and the second functional group can be a primary amine group or a secondary amine group.

The first functional group can be an isocyanate group and the second functional group can be a primary amine group, a secondary amine group, a hydroxyl group, or a thiol group.

The first functional group can be a cyclic carbonate group, an acetoacetate group, or an epoxy group; and the second functional group can be a primary amine group, or a secondary amine group.

The first functional group can be a thiol group, and the second functional group can be an alkenyl group, a vinyl ether group, a (meth)acrylate group.

The first functional group can be a Michael acceptor group such as (meth)acrylate group and the second functional group can be a malonate group.

The first functional group can be a thiol group, and the second functional group can be an alkenyl group, an epoxy group, an isocyanate group, an alkynyl group, or a Michael acceptor group.

The first functional group can be a Michael donor group, and the second functional group can be a Michael acceptor group.

Both the first functional group and the second functional group can be thiol groups.

Both the first functional group and the second functional group can be alkenyl groups.

Both the first functional group and the second functional group can be Michael acceptor groups such as (meth)acrylate groups.

Automated methods of applying the multilayer sealants can facilitate the use with other curing chemistries, such as fast curing chemistries, for practical use in sealants.

A fast curing chemistry refers to a chemistry in which the co-reactive compounds have a gel time less than 5 minutes, less than 4 minutes, less than 3 minutes, less than 2 minutes, less than 1 minute, less than 45 seconds, less than 30 seconds, less than 15 seconds, or less than 5 seconds. Coreactive compounds can have a gel time, for example, from 0.1 seconds to 5 minutes, from 0.2 seconds to 3 minutes, from 0.5 seconds to 2 minutes, from 1 second to 1 minute, from 2 seconds to 40 seconds, or within any range defined between any of the foregoing two values and endpoints. Gel time is the time following mixing the coreactive compounds when the coreactive compounds are no longer stirrable by hand.

Examples of useful fast curing chemistries include hydroxyl/isocyanate, amine/isocyanate, epoxy/epoxy, and Michael acceptor/Michael acceptor reactions.

The cure rate for any of these chemistries can be modified by including an appropriate catalyst.

### VI. Michael Addition

Compositions provided by the present disclosure may employ Michael addition curing chemistries. Compositions employing a Michael addition curing chemistry can comprise a Michael acceptor compound and a Michael donor compound.

The Michael acceptor compound can comprise a Michael acceptor monomer, a Michael acceptor prepolymer, or a combination thereof. A Michael acceptor compound can comprise a Michael acceptor compound having a Michael acceptor functionality of two, a Michael acceptor functionality from 3 to 6, or a combination thereof.

The Michael donor compound can comprise a Michael donor monomer, a Michael donor prepolymer, or a combination thereof. A Michael donor compound can comprise a Michael donor compound having a Michael donor functionality of two, a Michael donor functionality from 3 to 6, or a combination thereof.

The first and second coreactive compounds can include, for example, primary amine-functional components and acrylate, maleic, or fumaric-functional components. Coreactive compounds that are useful primary amine-functional components include polyoxyalkyleneamines containing two or more primary amine groups attached to a backbone, derived, for example, from propylene oxide, ethylene oxide, or a mixture thereof. Examples of such amines include those available under the designation Jeffamine™ from Huntsman Corporation. Such amines can have a molecular weight ranging from 200 Da to 7500 Da, such as, for example, Jeffamine™ D-230, D-400, D-2000, T-403, and T-5000. Coreactive compounds useful as acrylate functional components include the acrylate functional components listed previously as embodiments of (poly)methacrylate. Coreactive compounds useful as maleic or fumaric components include polyesters prepared from maleic anhydride, maleic acid, fumaric acid, or their corresponding C₁₋₆ alkyl esters.

A Michael acceptor group refers to an activated alkenyl group such as an alkenyl group proximate to an electron-withdrawing group such as a ketone, nitro, halo, nitrile, carbonyl, sulfonyl, or nitro group. Examples of Michael acceptor groups include vinyl ketone, vinyl sulfone, quinone, enamine, ketimine, aldimine, oxazolidine, acrylate, acrylate esters, acrylonitrile, acrylamide, maleimide, alkylmethacrylates, vinyl phosphonates, and vinyl pyridines.

Examples of suitable catalysts for Michael addition chemistries include tributylphosphine, triisobutylphosphine, tri-tertiary-butylphosphine, trioctyl phosphine, tris(2,4,4-trimethylpentyl)phosphine, tricyclopentylphosphine, tricyclohexalphosphine, tri-n-octylphosphine, tri-n-dodecylphosphine, triphenyl phosphine, and dimethyl phenyl phosphine.

Michael donors include amines, hydroxyl group containing oligomers or polymers, acetoacetates, malonates, and combinations of any of the foregoing.

Examples of suitable Michael donors, Michael acceptors and suitable catalysts are provided in Table 1.

TABLE 1
Michael donor/acceptor pairs

| Michael donors | Michael acceptors | Catalysts |
|---|---|---|
| Acetylacetonates | (Meth)acrylates | Strong bases such as |
| | | DBU, DBN, TMG, TMP, |
| | | TBD (MFC) |
| Malonates | Cyanoacrylates | Nucleophilic catalysts |
| | | such as |
| | | dimethylphenylphosphine |
| Nitroalkanes | Vinylethers | Tetrabutylammonium |
| | | fluoride |
| Any other active | Vinylpyridine | |
| methylene | | |

For example, a Michael donor can comprise an acetylacetonate monomer and/or an acetylacetonate prepolymer and a Michael acceptor can comprise a (methyl)acrylate monomer and/or a (meth)acrylate prepolymer, and a catalyst can comprise DBU, DBN, TMG, TMP, TBD, or a combination of any of the foregoing. For example, a Michael donor can comprise a malonate monomer and/or a malonate prepolymer and a Michael acceptor can comprise a cyanoacrylate monomer and/or a cyanoacrylate prepolymer, and a catalyst can comprise a nucleophilic catalyst such as dimethylphenylphosphine. For example, a Michael donor can comprise a nitroalkane monomer and/or a nitroalkane prepolymer and a Michael acceptor can comprise a vinyl ether monomer and/or a vinyl ether prepolymer, and a catalyst can comprise tetrabutylammonium fluoride. For example, a Michael donor can comprise a monomer and/or a prepolymer comprising an active methylene group and a Michael acceptor can comprise a monomer and/or a prepolymer comprising a vinyl pyridine.

Compositions provided by the present disclosure can comprise a substantially stoichiometric ratio of the first functional group to the second functional group.

The first coreactive compound and the second coreactive compound can be combined in a suitable equivalent ratio to form a cured composition provided by the present disclosure. For example, the equivalent ratio of the first functional group to the second functional group in a composition can be from 1:1 to 1.5:1, from 1:1 to 1.45:1, from 1:1 to 3:1, from 1.2:1 to 1.5:1, from 1.2:1 to 1.4:1, or within any range defined between any of the foregoing two values and endpoints. For example, the equivalent ratio of the first functional group to the second functional group in composition can be from 2:1 to 1:2, from 1.5:1 to 1:1.5, from 1.1:1 to 1:1.1, or within any range defined between any of the foregoing two values and endpoints.

### VII. Polyisocyanates/Polyamines

A polyisocyanate can comprise a polyisocyanate prepolymer, a polyisocyanate monomer, or a combination thereof.

A polyisocyanate can include a polyisocyanate prepolymer prepared by reacting a prepolymer having terminal groups reactive with isocyanate groups with a polyisocyanate such as a diisocyanate. For example, a polyisocyanate prepolymer can be prepared by reacting a polyol prepolymer and/or a polyamine prepolymer with a polyisocyanate such as a diisocyanate. Suitable polyisocyanate prepolymers are commercially available.

Suitable monomeric polyisocyanates include, for example, isophorone diisocyanate (IPDI), which is 3,3,5-trimethyl-5-isocyanato-methyl-cyclohexyl isocyanate; hydrogenated diisocyanates such as cyclohexylene diisocyanate, 4,4′-methylenedicyclohexyl diisocyanate (H₁₂MDI); mixed aralkyl diisocyanates such as tetramethylxylyl diisocyanates, OCN—C(—CH₃)₂—C₆H₄C(CH₃)₂—NCO; and polymethylene isocyanates such as 1,4-tetramethylene diisocyanate, 1,5-pentamethylene diisocyanate, 1,6-hexamethylene diisocyanate (HMDI or HDI), 1,7-heptamethylene diisocyanate, 2,2,4- and 2,4,4-trimethylhexamethylene diisocyanate, 1,10-decamethylene diisocyanate, and 2-methyl-1,5-pentamethylene diisocyanate.

Aliphatic isocyanates can be useful in producing three-dimensional polyurea articles that are resistant to degradation by UV light.

Examples of suitable monomeric aromatic polyisocyanates include phenylene diisocyanate, toluene diisocyanate (TDI), xylene diisocyanate, 1,5-naphthalene diisocyanate, chlorophenylene 2,4-diisocyanate, bitoluene diisocyanate, dianisidine diisocyanate, tolidine diisocyanate and alkylated benzene diisocyanates generally; methylene-interrupted aromatic diisocyanates such as methylenediphenyl diisocyanate, especially the 4,4′-isomer (MDI) including alkylated analogs such as 3,3′-dimethyl-4,4′-diphenylmethane diisocyanate and polymeric methylenediphenyl diisocyanate.

Suitable polyisocyanates also include polyisocyanates prepared from dimers and trimers of diisocyanate monomers. Dimers and trimers of diisocyanate monomers can be prepared, for example, by methods described in U.S. Pat. No. 5,777,061 at column 3, line 44 through column 4, line 40, which is incorporated by reference in its entirety. Dimers and trimers of diisocyanate monomers may contain linkages selected from isocyanurate, uretdione, biuret, allophanate and combinations thereof, such as Desmodur® N3600, Desmodur® CP2410, and Desmodur® N3400, available from Bayer Material Science.

A polyisocyanate can also comprise a polyisocyanate prepolymer. For example, a polyisocyanate can include an isocyanate-terminated polyether diol, an isocyanate-terminated extended polyether diol, or a combination thereof. An extended polyether diol refers to a polyether diol that has been reacted with an excess of a diisocyanate resulting in an isocyanate-terminated polyether prepolymer with increased molecular weight and urethane linkages in the backbone. Examples of polyether diols include Terathane® polyether diols such as Terathane® 200 and Terathane® 650 available from Invista or the PolyTHF® polyether diols available from BASF. Isocyanate-terminated polyether prepolymers can be prepared by reacting a diisocyanate and a polyether diol as described in U.S. Application Publication No. 2013/0244340. The number average molecular weight of an extended isocyanate-terminated prepolymer can be, for example, from 250 Da to 10,000 Da, or from 500 Da to 7,500 Da.

A polyisocyanate prepolymer can include an isocyanate-terminated polytetramethylene ether glycol such as polytetramethylene ether glycols produced through the polymerization of tetrahydrofuran. Examples of suitable polytetramethylene ether glycols include Polymeg® polyols (LyondellBasell), PolyTHF® polyether diols (BASF), or Terathane® polyols (Invista).

A polyisocyanate prepolymer can include an isocyanate-terminated polyetheramine. Examples of polyether amines include Jeffamine® polyetheramines (Huntsman Corp.), and polyetheramines available from BASF. Examples of suitable polyetheramines include polyoxypropylenediamine.

A polyisocyanate prepolymer having a suitable backbone can be prepared by reacting, for example, any of the prepolymers disclosed herein with a coreactive compound having a group reactive with the prepolymer and one or more isocyanate groups.

A polyisocyanate prepolymer can include a difunctional isocyanate, a trifunctional isocyanate, a difunctional isocyanate-terminated prepolymer, an extended difunctional isocyanate-terminated prepolymer, or a combination of any of the foregoing.

A polyisocyanate can include monomeric polyisocyanate or combination of monomeric polyisocyanates. A monomeric polyisocyanate can be a diisocyanate or can have an isocyanate functionality, for example from 3 to 6.

Examples of suitable monomeric polyisocyanates include isophorone diisocyanate (IPDI), which is 3,3,5-trimethyl-5-isocyanato-methyl-cyclohexyl isocyanate; hydrogenated materials such as cyclohexylene diisocyanate, 4,4′-methylenedicyclohexyl diisocyanate (H₁₂MDI); mixed aralkyl diisocyanates such as tetramethylxylyl diisocyanates, OCN—C(CH₃)₂—C₆H₄C(CH₃)₂—NCO; and polymethylene isocyanates such as 1,4-tetramethylene diisocyanate, 1,5-pentamethylene diisocyanate, 1,6-hexamethylene diisocyanate (HMDI or HDI), 1,7-heptamethylene diisocyanate, 2,2,4-and 2,4,4-trimethylhexamethylene diisocyanate, 1,10-decamethylene diisocyanate and 2-methyl-1,5-pentamethylene diisocyanate.

Suitable monomeric aromatic polyisocyanates include phenylene diisocyanate, toluene diisocyanate (TDI), xylene diisocyanate, 1,5-naphthalene diisocyanate, chlorophenylene 2,4-diisocyanate, bitoluene diisocyanate, dianisidine diisocyanate, tolidine diisocyanate and alkylated benzene diisocyanates generally; methylene-interrupted aromatic diisocyanates such as methylenediphenyl diisocyanate, especially the 4,4′-isomer (MDI) including alkylated analogs such as 3,3′-dimethyl-4,4′-diphenylmethane diisocyanate and polymeric methylenediphenyl diisocyanate.

An amine-functional coreactive component used to produce a three-dimensional polyurea article may include primary amines, secondary amines, tertiary amines, or combinations thereof. A polyamine can be a diamine or a polyamine having an amine functionality, for example from 3 to 6, or a combination thereof. A polyamine can be a monomeric polyamine, a polyamine prepolymer, or a combination thereof.

Examples of suitable monomeric aliphatic polyamines include, ethylene diamine, 1,2-diaminopropane, 1,4-diaminobutane, 1,3-diaminopentane, 1,6-diaminohexane, 2-methyl-1,5-pentane diamine, 2,5-diamino-2,5-dimethylhexane, 2,2,4- and/or 2,4,4-trimethyl-1,6-diamino-hexane, 1,11-diaminoundecane, 1,12-diaminododecane, 1,3- and/or 1,4-cyclohexane diamine, 1-amino-3,3,5-trimethyl-5-aminomethyl-cyclohexane, 2,4- and/or 2,6-hexahydrotolulene diamine, 2,4′- and/or 4,4′-di amino-dicyclohexyl methane, 5-amino-1,3,3-trimethylcyclohexanemethylamine (isophoronediamine), 1,3-cyclohexanebis(methylamine) (1,3 BAC), and 3,3′-dialkyl-4,4′-diaminodicyclohexyl methanes (such as 3,3′-dimethyl-4,4′-diaminodicyclohexyl methane and 3,3′-diethyl-4,4′-diaminodicyclohexyl methane), 2,4- and/or 2,6-diaminotoluene and 2,4′- and/or 4,4′-diaminodiphenyl methane, or mixtures thereof.

Suitable secondary amines include acrylates and methacrylate-modified amines. By “acrylate and methacrylate modified amines” includes both mono- and poly-acrylate modified amines as well as acrylate or methacrylate modified mono- or poly-amines. Acrylate or methacrylate modified amines can include aliphatic amines.

A secondary amine may include an aliphatic amine, such as a cycloaliphatic diamine. Such amines are available commercially from Huntsman Corporation (Houston, TX) under the designation of Jefflink™ such as Jefflink™ 754. The amine may be provided as an amine-functional resin. Such amine-functional resins may be a relatively low viscosity, amine-functional resins suitable for use in the formulation of high solids polyurea three-dimensional articles. An amine-functional resin may comprise an ester of an organic acid, for example, an aspartic ester-based amine-functional reactive resin that is compatible with isocyanates; e.g., one that is solvent-free. An example of such polyaspartic esters is the derivative of diethyl maleate and 1,5-diamino-2-methylpentane, available commercially from Bayer Corporation, PA under the trade name Desmophen™ NH1220. Other suitable coreactive compounds containing aspartate groups may be employed as well.

A polyamine can include high molecular weight primary amines, such as polyoxyalkyleneamines. Polyoxyalkyleneamines contain two or more primary amino groups attached to a backbone, derived, for example, from propylene oxide, ethylene oxide, or a mixture thereof. Examples of such amines include polyoxypropylenediamine and glycerol tris[poly(propylene glycol), amine-terminated]ether such as those available under the designation Jeffamine™ from Huntsman Corporation. Such polyetheramines can have a number average molecular weight from 200 Da to 7,500 Da, such as, for example, Jeffamine™ D-230, D-400, D-2000, T-403 and T-5000.

An amine-functional coreactive component may also include an aliphatic secondary amine such as Clearlink® 1000, available from Dor-Ketal Chemicals, LLC.

An amine-functional coreactive component can comprise an amine-functional aspartic acid ester, a polyoxyalkylene primary amine, an aliphatic secondary amine, or a combination of any of the foregoing.

A polyamine prepolymer having a suitable backbone can be prepared by reacting, for example, any of the prepolymers disclosed herein with a coreactive compound having a group reactive with the prepolymer and one or more amine groups.

A polyamine prepolymer can include a difunctional polyamine, a trifunctional isocyanate, a difunctional amine-terminated prepolymer, an extended difunctional amine-terminated prepolymer, or a combination of any of the foregoing.

A polyamine can include monomeric polyamine or combination of monomeric polyamines. A monomeric polyamine can be a diisocyanate or can have an amine functionality, for example from 3 to 6.

### VIII. Thiol-Ene

In coreactive compositions a first coreactive compound can comprise a polyalkenyl and a second coreactive compound can comprise a polythiol. The polyalkenyl and the polythiol can be independently selected from a monomer, an oligomer, a prepolymer, or a combination of any of the foregoing.

A polyalkenyl can comprise, for example, a polyvinyl ether monomer and a monomeric polyalkenyl polyfunctionalizing agent such as triallyl cyanurate.

A polythiol can be a monomeric polythiol or a polythiol prepolymer such as a thiol-terminated sulfur-containing prepolymer. A thiol-terminated sulfur-containing prepolymer can comprise a thiol-terminated polythioether prepolymer, a thiol-terminated polysulfide prepolymer, a thiol-terminated sulfur-containing polyformal prepolymer, a thiol-terminated monosulfide prepolymer, or a combination of any of the foregoing.

A sulfur-containing prepolymer can comprise a thiol-terminated polythioether prepolymer or combinations of thiol-terminated polythioether prepolymers. Examples of suitable thiol-terminated polythioether prepolymers are disclosed, for example, in U.S. Pat. No. 6,172,179, which is incorporated by reference in its entirety. A thiol-terminated polythioether prepolymer can comprise Permapol® P3.1E, Permapol® P3.1E-2.8, Permapol® L56086, or a combination of any of the foregoing, each of which is available from PPG Aerospace. These Permapol® products are encompassed by the thiol-terminated polythioether prepolymers of Formula (2) and Formula (2a). Thiol-terminated polythioethers include prepolymers described in U.S. Pat. No. 7,390,859 and urethane-containing polythiols described in U.S. Application Publication Nos. 2017/0369757 and 2016/0090507.

A sulfur-containing prepolymer can comprise a polythioether prepolymer having a moiety of Formula (2):

—S—R¹—[S-A-S—R¹—]ₙ—S— (2)
where,
   n is an integer from 1 to 60;
   each R¹ is independently selected from C₂₋₁₀ alkanediyl, C₆₋₈ cycloalkanediyl, C₆₋₁₄ alkanecycloalkanediyl, C₅₋₈ heterocycloalkanediyl, and —[(CHR³)ₚ—X—]_{q}(CHR³)ᵣ, where,
      p is an integer from 2 to 6;
      q is an integer from 1 to 5;
      r is an integer from 2 to 10;
      each R³ is independently selected from hydrogen and methyl; and
      each X is independently selected from O, S, S—S, and NR, wherein R is selected from hydrogen and methyl; and
   each A is independently a moiety derived from a polyvinyl ether of Formula (3) and a polyalkenyl polyfunctionalizing agent of Formula (4):

CH₂═CH—O—(R²—O)ₘ—CH═CH₂ (3)

B(—R³—CH═CH₂)_{z} (4)
wherein,
   m is an integer from 0 to 50;
   each R² is independently selected from C₁₋₁₀ alkanediyl, C₆₋₈ cycloalkanediyl, C₆₋₁₄ alkanecycloalkanediyl, and —[(CHR)ₚX—]_{q}(CHR)ᵣ—, wherein p, q, r, R, and X are as defined as for R¹⁵;
   B represents a core of a z-valent, polyalkenyl polyfunctionalizing agent B(—R³—CH═CH₂)_{z} wherein,
   z is an integer from 3 to 6; and
   each R³ is independently selected from C₁₋₁₀ alkanediyl, C₁₋₁₀ heteroalkanediyl, substituted C₁₋₁₀ alkanediyl, and substituted C₁₋₁₀ heteroalkanediyl.

In moieties of Formula (2), each A can independently be selected from a moiety of Formula (3a) and a moiety of Formula (4a):

—(CH₂)₂—O—(R²—O)ₘ—(CH₂)₂— (3a)

B{—R³—(CH₂)₂—}₂{—R³—(CH₂)₂—S—[—R¹⁵—S-G-S—R¹—SH}_{z-2} (4a)
where m, R¹, R², R³, A, and z are defined as in Formula (3) and Formula (4).

A sulfur-containing prepolymer can comprise a thiol-terminated sulfur-containing prepolymer.

For example, a thiol-terminated sulfur-containing prepolymer can comprise a thiol-terminated polythioether prepolymer of Formula (2a):

HS—R¹—[S-A-S—R¹—]ₙ—SH (2a)
where A and R¹ are defined as for Formula (2).

A thiol-terminated sulfur-containing prepolymer can comprise a thiol-terminated polysulfide prepolymer or a combination of thiol-terminated polysulfide prepolymers.

A polysulfide prepolymer refers to a prepolymer that contains one or more polysulfide linkages, i.e., —Sₓ— linkages, where x is from 2 to 4, in the prepolymer backbone. A polysulfide prepolymer can have two or more sulfur-sulfur linkages. Suitable thiol-terminated polysulfide prepolymers are commercially available, for example, from AkzoNobel and Toray Industries, Inc. under the tradenames Thioplast® and from Thiokol-LP®, respectively.

Examples of suitable polysulfide prepolymers are disclosed, for example, in U.S. Pat. Nos. 4,623,711; 6,172,179; 6,509,418; 7,009,032; and 7,879,955.

Examples of suitable thiol-terminated polysulfide prepolymers include Thioplast™ G polysulfides such as Thioplast™ G1, Thioplast™ G4, Thioplast™ G10, Thioplast™ G12, Thioplast™ G21, Thioplast™ G22, Thioplast™ G44, Thioplast™ G122, and Thioplast™ G131, which are commercially available from AkzoNobel. Thioplast™ G resins are liquid polysulfide prepolymers that are blends of di- and tri-functional molecules where the difunctional polysulfide prepolymers have the structure of Formula (5a) or can comprise a moiety of Formula (5):

HS—(—R—S—S—)ₐ—R—SH (5a)

—(—R—S—S—)ₙ—R— (5)
and the trifunctional polysulfide polymers can have the structure of Formula (6a) or can comprise a moiety of Formula (6):

HS—(—R—S—S—)ₐ—CH₂—CH{—CH₂—(—S—S—R—)_{b}—SH}{—(—S—S—R—)_{c}—SH} (6a)

—S—(—R—S—S—)ₐ—CH₂—CH{—CH₂—(—S—S—R—)_{b}—S—}{—(—S—S—R—)_{c}—S—} (6)
where each R is —(CH₂)₂—O—CH₂—O—(CH₂)₂—, and n=a+b+c, where the value for n may be from 7 to 38 depending on the amount of the trifunctional cross-linking agent (1,2,3-trichloropropane; TCP) used during synthesis of the polysulfide prepolymer. Thioplast™ G polysulfides can have a number average molecular weight from less than 1,000 Da to 6,500 Da, a SH content from 1% to greater than 5.5%, and a cross-linking density from 0% to 2.0%.

Examples of suitable thiol-terminated polysulfide prepolymers also include Thiokol™ LP polysulfides available from Toray Industries, Inc. such as Thiokol™ LP2, Thiokol™ LP3, Thiokol™ LP12, Thiokol™ LP23, Thiokol™ LP33, and Thiokol™ LP55. Thiokol™ LP polysulfides have a number average molecular weight from 1,000 Da to 7,500 Da, a —SH content from 0.8% to 7.7%, and a cross-linking density from 0% to 2%. Thiokol™ LP polysulfide prepolymers have the general structure of Formula (7a) or can comprise a moiety of Formula (7):

HS—[(CH₂)₂—O—CH₂—O—(CH₂)₂—S—S—]ₙ—(CH₂)₂O—CH₂—O—(CH₂)₂—SH (7a)

—S—[(CH₂)₂O—CH₂—O—(CH₂)₂—S—S—]ₙ—(CH₂)₂O—CH₂—O—(CH₂)₂—S— (7)
where n can be such that the number average molecular weight from 1,000 Da to 7,500 Da, such as, for example an integer from 8 to 80.

A thiol-terminated sulfur-containing prepolymer can comprise a Thiokol-LP® polysulfide, a Thioplast® G polysulfide, or a combination thereof.

A thiol-terminated polysulfide prepolymer can comprise a thiol-terminated polysulfide prepolymer of Formula (8a) or can comprise a moiety of Formula (8):

HS—R—(S_{y}—R)ᵣ—SH (8a)

—R—(S_{y}—R)ᵣ— (8)
where,
   t can be an integer from 1 to 60;
   q can be an integer from 1 to 8;
   p can be an integer from 1 to 10;
   r can be an integer from 1 to 10;
   y has an average value within a range from 1.0 to 1.5; and
   each R can independently be selected from branched alkanediyl, branched arenediyl, and a moiety having the structure —(CH₂)ₚ—O—(CH₂)_{q}—O—(CH₂)ᵣ—.

Examples of thiol-terminated polysulfide prepolymers of Formula (8) and (8a) are disclosed, for example, in U.S. Application Publication No. 2016/0152775, in U.S. Pat. No. 9,079,833, and in U.S. Pat. No. 9,663,619.

A thiol-terminated polysulfide prepolymer can comprise a thiol-terminated polysulfide prepolymer of Formula (9a) or can comprise a moiety of Formula (9):

HS—(R—O—CH₂—O—R—Sₘ—)ₙ₋₁—R—O—CH₂—O—R—SH (9a)

—(R—O—CH₂—O—R—Sₘ—)ₙ₋₁—R—O—CH₂—O—R— (9)
where R is C₂₋₄ alkanediyl, m is an integer from 1 to 8, and n is an integer from 2 to 370.

A thiol-terminated sulfur-containing prepolymer can comprise a thiol-terminated sulfur-containing polyformal prepolymer or a combination of thiol-terminated sulfur-containing polyformal prepolymers. Sulfur-containing polyformal prepolymers useful in sealant applications are disclosed, for example, in U.S. Pat. No. 8,729,216 and in U.S. Pat. No. 8,541,513, each of which is incorporated by reference in its entirety.

A thiol-terminated sulfur-containing prepolymer can comprise a thiol-terminated monosulfide prepolymer or a combination of thiol-terminated monosulfide prepolymers.

A thiol-terminated monosulfide prepolymer can comprise a thiol-terminated monosulfide prepolymer comprising a moiety of Formula (10):

—S—R²—[—S—(R—X)ₚ—(R¹—X)_{q}—R²]ₙ—S— (10)
wherein,
   each R can independently be selected from C₂₋₁₀ alkanediyl, such as C₂₋₆ alkanediyl; C₂₋₁₀ branched alkanediyl, such as C₃₋₆ branched alkanediyl or a C₃₋₆ branched alkanediyl having one or more pendant groups which can be, for example, alkyl groups, such as methyl or ethyl groups; C₆₋₈ cycloalkanediyl; C₆₋₁₄ alkylcycloalkyanediyl, such as C₆₋₁₀ alkylcycloalkanediyl; and C₈₋₁₀ alkylarenediyl;
   each R¹ can independently be selected from hydrogen, C₁₋₁₀ n-alkanediyl, such as C₁₋₆ n-alkanediyl, C₂₋₁₀ branched alkanediyl, such as C₃₋₆ branched alkanediyl having one or more pendant groups which can be, for example, alkyl groups, such as methyl or ethyl groups; C₆₋₈ cycloalkanediyl; C₆₋₁₄ alkylcycloalkanediyl, such as C₆₋₁₀ alkylcycloalkanediyl; and C₈₋₁₀ alkylarenediyl;
   each R² can independently be selected from hydrogen, C₁₋₁₀ n-alkanediyl, such as C₁₋₆ n-alkanediyl, C₂₋₁₀ branched alkanediyl, such as C₃₋₆ branched alkanediyl having one or more pendant groups which can be, for example, alkyl groups, such as methyl or ethyl groups; C₆₋₈ cycloalkanediyl group; C₆₋₁₄ alkylcycloalkanediyl, such as a C₆₋₁₀ alkylcycloalkanediyl; and C₈₋₁₀ alkylarenediyl;
   each X can independently be selected from O or S;
   p can be an integer from 1 to 5;
   q can be an integer from 0 to 5; and
   n can be an integer from 1 to 60, such as from 2 to 60, from 3 to 60, or from 25 to 35.

A thiol-terminated monosulfide prepolymer can comprise a thiol-terminated monosulfide prepolymer of Formula (11a), a thiol-terminated monosulfide prepolymer of Formula (11b), a thiol-terminated monosulfide prepolymer of Formula (11c), or a combination of any of the foregoing:

HS—R²—[—S—(R—X)ₚ—(R¹—X)_{q}R²—]ₙ—SH (11a)

{HS—R²—[—S—(R—X)ₚ—(R¹—X)_{g}—R²—]ₙ—S—V′—}_{z}B (11b)

{R⁴S—R²[—S—(R—X)ₚ(R¹—X)_{q}—R²—]ₙ—S—V′—}_{z}B (11c)
wherein,
   each R can independently be selected from C₂₋₁₀ alkanediyl, such as C₂₋₆ alkanediyl; C₂₋₁₀ branched alkanediyl, such as C₃₋₆ branched alkanediyl or a C₃₋₆ branched alkanediyl having one or more pendant groups which can be, for example, alkyl groups, such as methyl or ethyl groups; C₆₋₈ cycloalkanediyl; C₆₋₁₄ alkylcycloalkanediyl, such as C₆₋₁₀ alkylcycloalkanediyl; and C₈₋₁₀ alkylarenediyl;
   each R¹ can independently be selected from hydrogen, C₁₋₁₀ n-alkanediyl, such as C₁₋₆ n-alkanediyl, C₂₋₁₀ branched alkanediyl, such as C₃₋₆ branched alkanediyl having one or more pendant groups which can be, for example, alkyl groups, such as methyl or ethyl groups; C₆₋₈ cycloalkanediyl; C₆₋₁₄ alkylcycloalkanediyl, such as C₆₋₁₀ alkylcycloalkanediyl; and C₈₋₁₀ alkylarenediyl;
   each R² can independently be selected from hydrogen, C₁₋₁₀ n-alkanediyl, such as C₁₋₆ n-alkanediyl, C₂₋₁₀ branched alkanediyl, such as C₃₋₆ branched alkanediyl having one or more pendant groups which can be, for example, alkyl groups, such as methyl or ethyl groups; C₆₋₈ cycloalkanediyl group; C₆₋₁₄ alkylcycloalkanediyl, such as a C₆₋₁₀ alkylcycloalkanediyl; and C₈₋₁₀ alkylarenediyl;
   each X can independently be selected from O and S;
   p can be an integer from 1 to 5;
   q can be an integer from 0 to 5; and
   n can be an integer from 1 to 60, such as from 2 to 60, from 3 to 60, or from 25 to 35 and
   B represents a core of a z-valent polyfunctionalizing agent B(−V)_{z} wherein:
      z can be an integer from 3 to 6; and
      each V can be a moiety comprising a terminal group reactive with a thiol group;
   each —V′— can be derived from the reaction of −V with a thiol; and
   each R⁴ can independently be selected from hydrogen and a bond to a polyfunctionalizing agent B(−V)_{z.} through a moiety of Formula (11).

A thiol-terminated monosulfide prepolymer can comprise a thiol-terminated monosulfide prepolymer comprising a moiety of Formula (12a) or can comprise a moiety of Formula (12):

—[—S(RX)ₚ—C(R¹)₂—(X—R)_{g}—]ₙ—S— (12)

H—[—S—(R—X)ₚ—C(R¹)₂—(X—R)_{q}—]ₙ—SH (12a)
wherein,
   each R can independently be selected from C₂₋₁₀ alkanediyl, such as C₂₋₆ alkanediyl; a C₃₋₁₀ branched alkanediyl, such as a C₃₋₆ branched alkanediyl or a C₃₋₆ branched alkanediyl having one or more pendant groups which can be, for example, alkyl groups, such as methyl or ethyl groups; a C₆₋₈ cycloalkanediyl; a C₆₋₁₄ alkylcycloalkyanediyl, such as a C₆₋₁₀ alkylcycloalkanediyl; and a C₈₋₁₀ alkylarenediyl;
   each R¹ can independently be selected from hydrogen, C₁₋₁₀ n-alkanediyl, such as a C₁₋₆ n-alkanediyl, C₃₋₁₀ branched alkanediyl, such as a C₃₋₆ branched alkanediyl having one or more pendant groups which can be, for example, alkyl groups, such as methyl or ethyl groups; a C₆₋₈ cycloalkanediyl group; a C₆₋₁₄ alkylcycloalkanediyl, such as a C₆₋₁₀ alkylcycloalkanediyl; and a C₈₋₁₀ alkylarenediyl;
   each X can independently be selected from O and S;
   p can be an integer from 1 to 5;
   q can be an integer from 1 to 5; and
   n can be an integer from 1 to 60, such as from 2 to 60, from 3 to 60, from 25 to 35, or within any range defined between any of the foregoing two values and endpoints.

### IX. Fillers

Compositions provided by the present disclosure can have less than 50 wt % of the first and second coreactive compounds, less than 40 wt %, less than 30 wt %, less than 20 wt %, less than 10 wt %, or less than 5 wt % of the first and second coreactive compounds, where wt % is based on the total weight of the first and second coreactive compounds.

Compositions provided by the present disclosure can have from 5 wt % to 50 wt % of the first and second coreactive compounds, from 5 wt % to 40 wt %, from 5 wt % to 30 wt %, from 5 wt % to 20 wt %, or within any range defined between any of the foregoing two values and endpoints of the first and second coreactive compounds, where wt % is based on the total weight of the first and second coreactive compounds.

Compositions provided by the present disclosure can have less than 50 vol % of the first and second coreactive compounds, less than 40 vol %, less than 30 vol %, less than 20 vol %, less than 10 vol %, or less than 5 vol % of the first and second coreactive compounds, where vol % is based on the total volume of the first and second coreactive compounds.

Compositions provided by the present disclosure can have from 5 vol % to 50 vol % of the first and second coreactive compounds, from 5 vol % to 40 vol %, from 5 vol % to 30 vol %, from 5 vol % to 20 vol %, or within any range defined between any of the foregoing two values and endpoints of the first and second coreactive compounds, where vol % is based on the total volume of the first and second coreactive compounds.

Compositions provided by the present disclosure can comprise, for example, greater than 50 wt % of a conductive filler, greater than 60 wt %, greater than 70 wt %, greater than 80 wt %, less than 90 wt %, greater than 95 wt % of a conductive filler, or greater than 98 wt % of a conductive filler where wt % is based on the total weight of the composition.

Compositions provided by the present disclosure can comprise, for example, less than 50 wt % of a conductive filler, less than 60 wt %, less than 70 wt %, less than 80 wt %, less than 90 wt %, less than 95 wt % of a conductive filler, or less than 98 wt % of a conductive filler where wt % is based on the total weight of the composition.

Compositions provided by the present disclosure can comprise, for example, from 50 wt % to 98 wt % of a conductive filler, from 55 wt % to 95 wt %, from 60 wt % to 95 wt %, from 70 wt % to 95 wt %, from 80 wt % to 95 wt %, or within any range defined between any of the foregoing two values and endpoints of a conductive filler, where wt % is based on the total weight of the composition.

Compositions provided by the present disclosure can comprise, for example, greater than 50 vol % of a conductive filler, greater than 60 vol %, greater than 70 vol %, greater than 80 vol %, greater than 90 vol %, greater than 95 vol % of a conductive filler, or greater than 98 vol % of a conductive filler, where vol % is based on the total volume of the composition.

Compositions provided by the present disclosure can comprise, for example, less than 50 vol % of a conductive filler, less than 60 vol %, less than 70 vol %, less than 80 vol %, less than 90 vol %, less than 95 vol % of a conductive filler, or less than 98 vol % of a conductive filler, where vol % is based on the total volume of the composition.

Compositions provided by the present disclosure comprise, for example, from 50 vol % to 98 vol %, 55 vol % to 95 vol % of a conductive filler, from 60 vol % to 95 vol %, from 70 vol % to 95 vol %, from 80 vol % to 95 vol %, or within any range defined between any of the foregoing two values and endpoints of a conductive filler, where vol % is based on the total volume of the composition.

### IX (a). Conductive Fillers

Compositions provided by the present disclosure can include a conductive filler or a combination of conductive filler. A conductive filler can include electrically conductive filler, semiconductive filler, thermally conductive filler, magnetic filler, EMI/RFI shielding filler, static dissipative filler, electroactive filler, or a combination of any of the foregoing.

A filler can be electrically conductive, semiconductive, thermally conductive, magnetic, provide EMI/RFI shielding, be static dissipative, and/or electroactive to various degrees. The various conductive filler can be combined to achieve desired properties such as electrical conductivity, electrical resistivity, thermal conductivity, EMI/RFI shielding effectiveness, and/or ability to dissipate static charge.

A conductive filler can have any suitable shape and/or dimensions. For example, an electrically conductive filler can be in form of particles, powders, flakes, platelets, filaments, fiber, crystals, or a combination of any of the foregoing.

A conductive filler can comprise a combination of conductive filler having different shapes, different dimensions, different properties such as, for example, different thermal conduction, electrical conduction, magnetic permittivity, electromagnetic properties, or a combination of any of the foregoing.

A conductive filler can be a solid or can be in the form of a substrate such as a particle having a coating of a conductive material. For example, a conductive filler can be a low-density microcapsule having an exterior conductive coating.

### IX (b). Electrically Conductive Fillers

To render a part electrically conductive, the concentration of an electrically conductive filler can be above the electrical percolation threshold, where a conductive network of electrically conductive particles is formed. Once the electrical percolation threshold is achieved, the increase in conductivity as function of filler loading can be modeled by a simple power-law expression:

$${σ}_{c} = {{σ}_{f} ( φ - {φ}_{c} )}_{t} \qquad Eqn 1$$

where φ is the filler volume fraction, φ_{c} is the percolation threshold, σ_{f} is the filler conductivity, φ is the composite conductivity, and t is a scaling component. The filler need not be in direct contact for current flow and conduction can take place via tunneling between thin layers of coreacted compounds surrounding the electrically conductive filler particles, and this tunneling resistance can be the limiting factor in the conductivity of an electrically conductive composite.

Compositions provided by the present disclosure can comprise an electrically conductive filler or combination of electrically conductive filler.

Examples of suitable electrically conductive filler include metals, metal alloys, conductive oxides, semiconductors, carbon, and combinations of any of the foregoing.

Other examples of electrically conductive filler include electrically conductive noble metal-based filler such as pure silver; noble metal-plated noble metals such as silver-plated gold; noble metal-plated non-noble metals such as silver plated cooper, nickel or aluminum, for example, silver-plated aluminum core particles or platinum-plated copper particles; noble-metal plated glass, plastic or ceramics such as silver-plated glass microspheres, noble-metal plated aluminum or noble-metal plated plastic microspheres; noble-metal plated mica; and other such noble-metal conductive filler. Non-noble metal-based materials can also be used and include, for example, non-noble metal-plated non-noble metals such as copper-coated iron particles or nickel-plated copper; non-noble metals, e.g., copper, aluminum, nickel, cobalt; non-noble-metal-plated-non-metals, e.g., nickel-plated graphite and non-metal materials such as carbon black and graphite. Combinations of electrically conductive filler and shapes of electrically conductive filler can be used to achieve a desired conductivity, EMI/RFI shielding effectiveness, hardness, and other properties suitable for a particular application.

Carbon fibers such as graphitized carbon fibers can also be used to impart electrical conductivity to compositions of the present disclosure. Carbon fibers formed by vapor phase pyrolysis methods and graphitized by heat treatment and which are hollow or solid with a fiber diameter ranging from 0.1 micron to several microns, have high electrical conductivity. Carbon microfibers such as nanotubes or carbon fibrils having an outer diameter of less than 0.1 μm to tens of nanometers can be used as electrically conductive filler. An example of graphitized carbon fiber suitable for conductive compositions of the present disclosure include Panex® 30MF (Zoltek Companies, Inc., St. Louis, Mo.), a 0.921 μm diameter round fiber having an electrical resistivity of 0.00055 Ω-cm.

The average particle size of an electrically conductive filler can be within a range useful for imparting electrical conductivity to a polymer-based composition. For example, the particle size of the one or more filler can range from 0.25 μm to 250 μm, can range from 0.25 μm to 75 μm, or can range from 0.25 μm to 60 μm. Composition provided by the present disclosure can comprise Ketjenblack® EC-600 JD (AkzoNobel, Inc., Chicago, Ill.), an electrically conductive carbon black characterized by an iodine absorption of 1,000 mg/g to 11,500 mg/g (J0/84-5 test method), and a pore volume of 480 cm³/100 g to 510 cm³/100 g (DBP absorption, KTM 81-3504). An electrically conductive carbon black filler is Black Pearls® 2000 (Cabot Corporation, Boston, MA).

Electrically conductive compositions provided by the present disclosure can comprise more than one electrically conductive filler and the more than one electrically conductive filler can be of the same or different materials and/or shapes. For example, a composition can comprise electrically conductive Ni fibers, and electrically conductive Ni-coated graphite in the form of powder, particles or flakes. The amount and type of electrically conductive filler can be selected to produce a coreactive composition which, when cured, exhibits a sheet resistance (four-point resistance) of less than 0.50 Ω/cm², or a sheet resistance less than 0.15 Ω/cm². The amount and type of filler can also be selected to provide effective EMI/RFI shielding over a frequency range of from 1 MHz to 18 GHz for an aperture sealed using a sealant composition of the present disclosure.

Organic filler, inorganic filler, and low-density filler can be coated with a metal to provide conductive filler.

### IX (c). Graphene Fillers

An electrically conductive filler can include graphene.

Graphene comprises a densely packed honeycomb crystal lattice made of carbon atoms having a thickness equal to the atomic size of one carbon atom, i.e., a monolayer of sp² hybridized carbon atoms arranged in a two-dimensional lattice.

Graphene can comprise graphenic carbon particles. Graphenic carbon particles refer to carbon particles having structures comprising one or more layers of one-atom-thick planar sheets of sp²-bonded carbon atoms that are densely packed in a honeycomb crystal lattice. An average number of stacked layers can be less than 100, for example, less than 50. An average number of stacked layers can be 30 or less, such as 20 or less, 10 or less, or, in some cases, 5 or less. Graphenic carbon particles can be substantially flat, however, at least a portion of the planar sheets may be substantially curved, curled, creased or buckled. Graphenic carbon particles may not have a spheroidal or equiaxed morphology.

Graphene can have a thickness, measured in a direction perpendicular to the carbon atom layers, less than 10 nm, less than 5 nm, or less than 4, 3, 2, or 1 nm. Graphene can be, for example, from 1 atom layer up to 3, 6, 9, 12, 20 or 30 atom layers thick. Graphene can have a width and length, measured in a direction parallel to the carbon atoms layers, of at least 50 nm, such as more than 100 nm, more than 100 nm up to 500 nm, or from 100 nm to 200 nm. Graphene can be in the form of flakes, platelets or sheets having relatively high aspect ratios (aspect ratio being defined as the ratio of the longest dimension of a particle to the shortest dimension of the particle) of greater than 3:1, such as greater than 10:1.

Graphenic carbon particles can have a relatively low oxygen content. For example, graphenic carbon particles can, even when having a thickness of no more than 5 nm or no more than 2 nm, have an oxygen content of no more than 2 atomic wt %, such as no more than 1.5 or 1 atomic wt %, or no more than 0.6 atomic wt %, such as about 0.5 atomic wt %. The oxygen content of the graphenic carbon particles can be determined using X-ray Photoelectron Spectroscopy.

Graphenic carbon particles have a BET specific surface area of at least 50 m²/g, such as from 70 m²/g to 1000 m²/g, or, in some cases, 200 m²/g to 1000 m²/g, from 200 m²/g to 400 m²/g, or within any range defined between any of the foregoing two values and endpoints.

Graphenic carbon particles can have a Raman spectroscopy 2D/G peak ratio of at least 1:1, for example, at least 1.2:1 or 1.3:1. The 2D/G peak ratio refers to the ratio of the intensity of the 2D peak at 2692 cm⁻¹ to the intensity of the G peak at 1,580 cm⁻¹.

Graphene used in electrically conductive compositions can have a relatively low bulk density. For example, graphene can have a bulk density (tap density) of less than 0.2 g/cm³, such as less than 0.1 g/cm³. The bulk density of graphene can be determined, for example, by placing 0.4 grams of graphene in a glass measuring cylinder having a readable scale. The cylinder can be raised approximately one inch and tapped 100 times, by striking the base of the cylinder onto a hard surface, to allow the graphene to settle within the cylinder. The volume of the particles can then be measured, and the bulk density can be calculated by dividing 0.4 gm by the measured volume, where the bulk density can be expressed in terms of g/cm³.

Graphenic carbon particles can have a compressed density and a percent densification that is less than the compressed density and percent densification of graphite powder and certain types of substantially flat graphenic carbon particles such as those formed from exfoliated graphite. Lower compressed density and lower percent densification are each currently believed to contribute to better dispersion and/or rheological properties than graphenic carbon particles exhibiting higher compressed density and higher percent densification. The compressed density of the graphenic carbon particles is 0.9 or less, such as less than 0.8, less than 0.7, such as from 0.6 to 0.7. The percent densification of the graphenic carbon particles is less than 40%, such as less than 30%, such as from 25 to 30%.

The compressed density of graphenic carbon particles can be calculated from a measured thickness of a given mass of the particles after compression. For example, the measured thickness can be determined by subjecting 0.1 g of the graphenic carbon particles to cold press under 15,000 pound of force in a 1.3 cm die for 45 min, wherein the contact pressure is 500 MPa. The compressed density of the graphenic carbon particles can then calculated from this measured thickness according to the following equation: Compressed Density (gm/cm³)=0.1 gm×3.14×(1.3 cm⁻²)²×(measured thickness in cm). The percent densification of the graphenic carbon particles can then be determined as the ratio of the calculated compressed density of the graphenic carbon particles to 2.2 g/cm³, which is the density of graphite.

The percent densification of graphene can then be determined as the ratio of the calculated compressed density of the graphene, to 2.2 g/cm³, which is the density of graphite.

Graphene can have a measured bulk liquid conductivity of at least 100 μS (microsiemens), such as at least 120 μS, such as at least 140 μS immediately after mixing and at later points in time, such as at 10 min, or 20 min, or 30 min, or 40 min. The bulk liquid conductivity of graphene can be determined using the following procedure. A sample comprising 0.5% solution of graphene in butyl Cellosolve® can be sonicated for 30 min with a bath sonicator. Immediately following sonication, the sample can be placed in a standard calibrated electrolytic conductivity cell (K=1). A Fisher Scientific AB 30 conductivity meter can be introduced to the sample to measure the conductivity of the sample. The conductivity can be plotted over the course of about 40 min.

Suitable graphene can be made, for example, by thermal processes. For example, graphene can be produced from carbon-containing precursor materials that are heated to high temperatures in a thermal zone. For example, the graphene can be produced by the systems and methods disclosed in U.S. Pat. No. 8,486,363 and its counterparts.

Graphenic carbon particles can comprise exfoliated graphite and have different characteristics in comparison with the thermally produced graphenic carbon particles, such as different size distributions, thicknesses, aspect ratios, structural morphologies, oxygen contents, and chemical functionalities at the basal planes/edges.

Graphenic carbon particles can be functionalized. Functionalized graphenic carbon particles refers to graphenic carbon particles in which organic groups are bonded to the graphenic carbon particles. The graphenic carbon particles can be functionalized through the formation of covalent bonds between the carbon atoms of a particle and other chemical moieties such as carboxylic acid groups, sulfonic acid groups, hydroxyl groups, halogen atoms, nitro groups, amine groups, aliphatic hydrocarbon groups, phenyl groups and the like. For example, functionalization with carbonaceous materials may result in the formation of carboxylic acid groups on the graphenic carbon particles. Graphenic carbon particles may also be functionalized by other reactions such as Diels-Alder addition reactions, 1,3-dipolar cycloaddition reactions, free radical addition reactions and diazonium addition reactions. Hydrocarbon and phenyl groups may be further functionalized. For graphenic carbon particles having a hydroxyl functionality, the hydroxyl functionality can be modified and extended by reacting these groups with, for example, an organic isocyanate.

Different types of graphenic carbon particles may be used in the present composition. For example, when thermally produced graphenic carbon particles are combined with commercially available graphenic carbon particles a bi-modal distribution, tri-modal distribution, or other distribution of graphenic carbon particle characteristics and/or properties may be achieved. The graphenic carbon particles contained in the compositions may have multi-modal particle size distributions, aspect ratio distributions, structural morphologies, edge functionality differences, oxygen content, and combinations of any of the foregoing.

When both thermally produced graphenic carbon particles and commercially available graphenic carbon particles, e.g., from exfoliated graphite, are used to produce a bi-modal graphenic particle size distribution, the relative amounts of the different types of graphenic carbon particles are controlled to produce desired conductivity properties of the coatings. For example, thermally produced graphenic particles may comprise from 1 wt % to 50 wt %, and the commercially available graphenic carbon particles may comprise from 50 wt % to 99 wt %, based on the total weight of the graphenic carbon particles.

Compositions provided by the present disclosure can comprise, for example, may comprise from 2 wt % to 50 wt %, from 4 wt % to 40 wt %, from 6 wt % to 35 wt %, from 10 wt % to 30 wt %, or within any range defined between any of the foregoing two values and endpoints thermally produced graphenic carbon particles. Compositions provided by the present disclosure can comprise thermally produced graphenic carbon nanoparticles as well as graphenic carbon particles produced by other methods, and also other forms of carbon or graphite.

Filler used to impart electrical conductivity and EMI/RFI shielding effectiveness can be used in combination with graphene. Examples of electrically conductive filler for use in combination with graphene include electrically conductive noble metal-based filler; noble metal-plated noble metals; noble metal-plated non-noble metals; noble-metal plated glass, plastic or ceramics; noble-metal plated mica; and other noble-metal conductive filler. Non-noble metal-based materials can also be used and include, for example, non-noble metal-plated non-noble metals; non-noble metals; non-noble-metal-plated-nonmetals. Examples of suitable materials and combinations are disclosed, for example, in U.S. Application Publication No. 2004/0220327 A1.

Electrically conductive non-metal filler, such as carbon nanotubes, carbon fibers such as graphitized carbon fibers, and electrically conductive carbon black, can also be used in coreactive compositions in combination with graphene. An example of suitable graphitized carbon fiber is PANEX 3OMF (Zoltek Companies, Inc.), a 0.921-μm diameter round fiber having an electrical resistivity of 0.00055 Ω-cm. Examples of suitable electrically conductive carbon black include Ketjenblack® EC-600 JD (Akzo Nobel, Inc.), an electrically conductive carbon black characterized by an iodine absorption within a range from 1,000 mg/g to 11,500 mg/g (J0/84-5 test method), and a pore volume of 480-510 cm³/100 gm (DBP absorption, KTM 81-3504) and Blackpearls® 2000 and REGAL® 660R (Cabot Corporation, Boston, MA.). Compositions can comprise carbon nanotubes having a length dimension, for example, from 5 μm to 30 μm, and a diameter from 10 nm to 30 nms. Carbon nanotubes can have dimensions of 11 nm by 10 μm.

### IX (d). Magnetic Fillers

Conductive filler can comprise magnetic filler or a combination of magnetic filler.

The magnetic filler can include a soft magnetic metal. This can enhance permeability of the magnetic mold resin. As a main component of the soft magnetic metal, at least one magnetic material selected from Fe, Fe—Co, Fe—Ni, Fe—Al, and Fe—Si may be used. A magnetic filler can be a soft magnetic metal having a high bulk permeability. As the soft magnetic metal, at least one magnetic material selected can be Fe, FeCo, FeNi, FeAl, and FeSi may be used. Specific examples include a permalloy (FeNi alloy), a super permalloy (FeNiMo alloy), a sendust (FeSiAl alloy), an FeSi alloy, an FeCo alloy, an FeCr alloy, an FeCrSi alloy, FeNiCo alloy, and Fe. Other examples of magnetic filler include iron-based powder, iron-nickel based powder, iron powder, ferrite powder, Alnico powder, Sm2Co17 powder, Nd—B—Fe powder, barium ferrite BaFe2O4, bismuth ferrite BiFeO3, chromium dioxide CrO2, SmFeN, NdFeB, and SmCo.

A surface of the magnetic filler can be insulation-coated or can have a film thickness of the insulation coating equal to or larger than 10 nm.

A surface of the magnetic filler can be insulation-coated with a metal oxide such as Si, Al, Ti, Mg or an organic material for enhancing fluidity, adhesion, and insulation performance.

### IX (e). Metal Fillers

Examples of suitable metal filler include, for example, silver, copper, aluminum, platinum, palladium, nickel, chromium, gold, bronze, and colloidal metals. Examples of suitable metal oxides include antimony tin oxide and indium tin oxide and materials such as filler coated with metal oxides. Suitable, metal and metal-oxide coated materials include metal coated carbon and graphite fibers, metal coated glass fibers, metal coated glass beads, metal coated ceramic materials such as ceramic beads. These materials can be coated with a variety of metals, including nickel.

Examples of conductive materials include metallic such as silver, copper, gold, platinum, palladium, tungsten, and iron; nanomaterials such as nanoparticles, nanorods, nanowires, nanotubes, and nanosheets; conductive oxides such as indium tin oxide, antimony oxide, and zinc oxide; conducting polymers such as poly(3,4-ethylenedioxythiophene) polystyrene sulfonate (PEDOT:PSS), polyacetylene, polythiophenes, and other conjugated polymers; carbonaceous nanomaterials such as graphene (single or multi-layer), carbon-nanotubes (CNTs, single or multi-walled), graphene nanoribbons, and fullerenes; and reactive metal systems such as metal oxide nanoparticles. Carbonaceous nanomaterials and metallic materials are stable at very high temperatures and therefore can be useful in high-temperature parts.

### IX (f). Carbonaceous Materials Other than Graphene Fillers

Examples of carbonaceous materials for use as conductive filler other than graphene and graphite include, for example, graphitized carbon black, carbon fibers and fibrils, vapor-grown carbon nanofibers, metal coated carbon fibers, carbon nanotubes including single- and multi-walled nanotubes, fullerenes, activated carbon, carbon fibers, expanded graphite, expandable graphite, graphite oxide, hollow carbon spheres, and carbon foams.

### IX (g). Semiconductor Fillers

Conductive filler can include semiconductors or combinations of semiconductors.

Examples of suitable semiconductive materials include semiconducting nanomaterials such as nanoparticles, nanorods, nanowires, nanotubes, and nanosheets, semiconducting metal oxides such as tin oxide, antimony oxide, and indium oxide, semiconducting polymers such as PEDOT:PSS, polythiophenes, poly(p-phenylene sulfide), polyanilines, poly(pyrrole)s, poly(acetylene)s, poly(p-phenylene vinylene), polyparaphenylene, any other conjugated polymer, and semiconducting small molecules, for example, having a molecular mass less than 5,000 Da, such as rubrene, pentacene, anthracene, and aromatic hydrocarbons. Some specific examples of the semiconducting nanomaterials include quantum dots, III-V or II-VI semiconductors, Si, Ge, transition metal dichalcogenides such as WS₂, WSe₂, and MoSe₈, graphene nanoribbons, semiconducting carbon nanotubes, and fullerenes and fullerene derivatives.

### IX (h). Fiber Fillers

A conductive filler can include conductive fiber or a combination of conductive fiber.

Examples of suitable metal fiber include steel, titanium, aluminum, gold, silver, and alloys of any of the foregoing.

Examples of suitable ceramic fiber include metal oxide such as alumina fibers, aluminasilicate fibers, boron nitride fibers, silicon carbide fibers, and combinations of any of the foregoing.

Examples of suitable inorganic fiber include carbon, alumina, basalt, calcium silicate, and rock wool.

A fiber can be a glass fiber such as S-glass fiber, E-glass fiber, soda-lime-silica fiber, basalt fiber, or quartz fiber. Glass fibers may be in the form of woven and/or braided glass fiber, or non-woven glass fibers.

A fiber can include carbon such as graphite fiber, glass fiber, ceramic fiber, silicon carbide fiber, polyimide fiber, polyamide fiber, and/or polyethylene fiber. Continuous fiber can comprise titanium, tungsten, boron, shape memory alloy, graphite, silicon carbide, boron, aramid, poly(p-phenylene-2,6-benzobisoxazole), and combinations of any of the foregoing.

Fiber capable of withstanding high temperature include, for example, carbon fiber, high-strength glass (SiO₂) fiber, oxide fiber, alumina fiber, ceramic fiber, metal fiber, and fibers of high temperature thermoplastics or thermosets.

A filler can include carbon nanotubes, fullerenes, or a combination thereof.

A filler can include graphene or other, flat polycyclic aromatic hydrocarbon. Graphene can be used to impart thermal conductivity, electrical conductivity EMI/RFI shielding capability, and/or anti-static properties to a built article.

### IX (i). Carbon Nanotube Fillers

A filler can include carbon nanotubes. Suitable carbon nanotubes can be characterized by a thickness or length, for example, from 1 nm to 5,000 nm.

Suitable carbon nanotubes can be cylindrical in shape and structurally related to fullerenes. Suitable carbon nanotubes can be open or capped at their ends. Suitable carbon nanotubes can comprise, for example, more than 90 wt %, more than 95 wt %, more than 99 wt %, or more than 99.9 wt % carbon, where wt % is based on the total weight of the carbon nanotube.

Suitable carbon nanotubes can be prepared by any suitable method known in the art. For example, carbon nanotubes can be prepared by the catalyst decomposition of hydrocarbons such as catalytic carbon vapor deposition (CCVD). Other methods for preparing carbon nanotubes include the arc-discharge method, the plasma decomposition of hydrocarbons, and the pyrolysis of selected polyolefin under selected oxidative conditions. The starting hydrocarbons can be acetylene, ethylene, butane, propane, ethane, methane or any other gaseous or volatile carbon-containing compound. The catalyst, if present, can be used in either pure or in a supported form. Purification can remove undesirable by-products and impurities.

Nanotubes can exist as single-walled nanotubes (SWNT) and multi-walled nanotubes (MWNT), for example, as nanotubes having one single wall and nanotubes having more than one wall, respectively. In single-walled nanotubes a one atom thick sheet of atoms, for example, a one atom thick sheet of graphite (also called graphene), is rolled seamlessly to form a cylinder. Multi-walled nanotubes consist of a number of such cylinders arranged concentrically.

A multi-walled carbon nanotube can have, for example, on average from 5 to 15 walls.

Nanotubes, irrespective of whether they are single-walled or multi-walled, may be characterized by their outer diameter or by their length or by both.

Single-walled nanotubes can be characterized by a diameter of at least 0.5 nm, such as at least 1 nm, or at least 2 nm. A SWNT can have a diameter less than 50 nm, such as less than 30 nm, or less than 10 nm. A length of single-walled nanotubes can be at least 0.05 μm, at least 0.1 μm, or at least 1 μm. A length can be less than 50 mm, such as less than 25 mm.

Multi-walled nanotubes can be characterized by an outer diameter of at least 1 nm, such as at least 2 nm, 4 nm, 6 nm, 8 nm, or at least 9 nm. An outer diameter can be less than 100 nm, less than 80 nm, 60 nm, 40 nm, or less than 20 nm. The outer diameter can be from 9 nm to 20 nm. A length of a multi-walled nanotube can be less than 50 nm, less than 75 nm, or less than 100 nm. A length can be less than 500 μm, or less than 100 μm. A length can be from 100 nm to 10 μm. A multi-walled carbon nanotube can have an average outer diameter from 9 nm to 20 nm and/or an average length from 100 nm to 10 μm.

Carbon nanotubes can have a BET surface area, for example, from 200 m²/g to 400 m²/g.

Carbon nanotubes can have a mean number of from 5 walls to 15 walls.

Compositions can comprise an antioxidant or a combination of antioxidants to maintain the conductivity of carbon nanotubes, as well as other conductive filler. Examples of suitable antioxidants include phenolic antioxidants such as pentaerythritol tetrakis[3-(3′,5′-di-tert-butyl-4′-hydroxyphenyl)propionate](herein referred to as Irganox® 1010), tris(2,4-di-tert-butylphenyl) phosphite (herein referred to as Irgafos® 168), 3DL-α-tocopherol, 2,6-di-tert-butyl-4-methylphenol, dibutylhydroxyphenylpropionic acid stearyl ester, 3,5-di-tert-butyl-4-hydroxyhydrocinnamic acid, 2,2′-methylenebis(6-tert-butyl-4-methyl-phenol), hexamethylene bis[3-(3,5-di-tert-butyl-4-hydroxyphenyl)propionate], benzenepropanamide, N,N′-1,6-hexanediyl bis[3,5-bis(1,1-dimethylethyl)-4-hydroxy], diethyl 3.5-di-tert-butyl-4-hydroxybenzyl phosphonate, calcium bis[monoethyl(3,5-di-tert-butyl-4-hydroxylbenzyl)phosphonate], triethylene glycol bis(3-tert-butyl-4-hydroxy-5-methylphenyl)propionate, 6,6′-di-tert-butyl-4,4′-butylidenedi-m-cresol, 3,9-bis(2-(3-(3-tert-butyl-4-hydroxy-5-methylphenyl)propionyloxy-1,1-dimethylethyl)-2,4,8,10-tetraoxaspiro[5.5]undecane, 1,3,5-trimethyl-2,4,6-tris(3,5-di-tert-butyl-4-hydroxybenzyl)benzene, 1,1,3-tris(2-methyl-4-hydroxy-5-tert-butylphenyl)butane, (2,4,6-trioxo-1,3,5-triazine-1,3,5(2H,4H,6H)-triyl)triethylene tris[3-(3,5-di-tert-butyl-4-hydroxyphenyl)propionate], tris(3,5-di-tert-butyl-4-hydroxybenzyl) isocyanurate, tris(4-tert-butyl-3-hydroxy-2,6-dimethylbenzyl) isocyanurate, ethylene bis[3,3-bis(3-tert-butyl-4-hydroxyphenyl)butyrate], and 2,6-bis[[3-(1,1-dimethylethyl)-2-hydroxy-5-methylphenyl]octahydro-4,7-methano-1H-indenyl]-4-methyl-phenol.

Suitable antioxidants also include, for example, phenolic antioxidants with dual functionality such 4,4′-thio-bis(6-tert-butyl-m-methyl phenol), 2,2′-sulfanediylbis(6-tert-butyl-4-methylphenol), 2-methyl-4,6-bis(octylsulfanylmethyl)phenol, thiodiethylene bis[3-(3,5-di-tert-butyl-4-hydroxyphenyl)propionate], 2,6-di-tert-butyl-4-(4,6-bis(octylthio)-1,3,5-triazin-2-ylamino)phenol, N-(4-hydroxyphenyl)stearamide, bis(1,2,2,6,6-pentamethyl-4-piperidyl) [[3,5-bis(1,1-dimethylethyl)-4-hydroxyphenyl]methyl]butylmalonate, 2,4-di-tert-butylphenyl 3,5-di-tert-butyl-4-hydroxybenzoate, hexadecyl 3,5-di-tert-butyl-4-hydroxybenzoate, and 2-(1,1-dimethylethyl)-6-[[3-(1,1-dimethylethyl)-2-hydroxy-5-methylphenyl]-methyl]-4-methylphenyl acrylate. Suitable antioxidants also include, for example, aminic antioxidants such as N-phenyl-2-naphthylamine, poly(1,2-dihydro-2,2,4-trimethyl-quinoline), N-isopropyl-N′-phenyl-p-phenylenediamine, N-phenyl-1-naphthylamine, and 4,4-bis(α,α-dimethylbenzyl)diphenylamine.

### IX (i). Thermally-Conductive Fillers

Compositions provided by the present disclosure can comprise a thermally-conductive filler or combination of thermally-conductive filler.

Compositions provided by the present disclosure can comprise a thermally-conductive filler or combination of thermally-conductive filler.

A thermally conductive filler can include, for example, metal nitrides such as boron nitride, silicon nitride, aluminum nitride, boron arsenide, carbon compounds such as diamond, graphite, carbon black, carbon fibers, graphene, and graphenic carbon particles, metal oxides such as aluminum oxide, magnesium oxide, beryllium oxide, silicon dioxide, titanium oxide, nickel oxide, zinc oxide, copper oxide, tin oxide, metal hydroxides such as aluminum hydroxide or magnesium hydroxide, carbides such as silicon carbide, minerals such as agate and emery, ceramics such as ceramic microspheres, mullite, silica, silicon carbide, carbonyl iron, cerium (III) molybdate, copper, zinc, or combinations of any of the foregoing.

### IX (k). Optically Active Fillers

A filler can include phosphors, electroactive particles, quantum dots, nano-diamonds, photonic crystals, and combinations of any of the foregoing.

A phosphor refers to any type of wavelength converting material capable of absorbing light of at least one wavelength and capable of emitting light at another wavelength. Examples of phosphors include quantum dots, which are semiconductor materials having a size, composition, and structure in which the electrical and optical characteristics differ from the bulk properties due to quantum confinement effects. Fluorescence of quantum dots results from the excitation of a valence electron by light absorption, followed by the emission at a lower energy wavelength as the excited electrons return to the ground state. Quantum confinement causes the energy difference between the valence and conduction bands to change depending on the size, composition and structure of a quantum dot. For example, the larger the quantum dot, the lower the energy of its fluorescence spectrum. The photoluminescence emission wavelength of a quantum dot can have a sharp emission spectrum and exhibit a high quantum efficiency.

Quantum dots can have any suitable geometry such as, for example, rods, disks, prolate spheroids, and crystalline, polycrystalline, or amorphous nanoparticles that can convert light at a suitable wavelength or range of wavelengths, absorb selected wavelengths of light, and/or convert one form of energy into another.

Examples of quantum dot semiconductor materials include, for example, Groups II-VI, III-V, IV-VI semiconductor materials. Suitable quantum dot materials include CdS, CdSe, CdTe, ZnS, ZnSe, ZnTe, GaAs, GaP, GaAs, GaSb, HgS, HgSe, HgTe, InAs, InP, InSb, AlAs, AlP, and AlSb. Other examples of suitable quantum dot materials include InGaP, ZnSeTe, ZnCdS, ZnCdSe, and CdSeS. Multi-core structures are also possible. Examples of multicore quantum dot configurations include a quantum dot having a semiconductor core material, a thin metal layer to protect the core from oxidation and to facilitate lattice matching, and a shell to enhance the luminescence properties. The core and shell layers can be formed from the same material, and may be formed, for example, from any of the listed semiconductor materials. A metal layer can comprise Zn or Cd.

Ligands can be bound to quantum dots, for example, to promote ligands to promote solubility of the quantum dots in the polymerizable composition, which can provide for higher vol % loadings without agglomeration. Ligands can be derived from a coordinating solvent that may be included in the reaction mixture during the growth process. Examples of suitable ligands include fatty acid ligands, long chain fatty acid ligands, alkyl phosphines, alkyl phosphine oxides, alkyl phosphonic acids, alkyl phosphinic acids, pyridines, furans, and amines. Specific examples include pyridine, tri-n-octyl phosphine (TOP), tri-n-octyl phosphine oxide (TOPO), tris-hydroxylpropylphosphine (tHPP) and octadecylphosphonic acid (ODPA).

Examples of other phosphor particles include phosphors that intrinsically exhibit photoluminescence because of the composition. Examples of phosphor particles that exhibit luminescence due to the composition include sulfides, aluminates, oxides, silicates, nitrides, YAG (optionally doped with cerium), and terbium aluminum garnet (TAG) based materials. Other exemplary materials include yellow-green emitting phosphors: (Ca,Sr,Ba)Al₂O₄:Eu, (Lu,Y) 3Al₅O₁₂:Ce³⁺ (LuAG, YAG), Tb₃Al₅O₁₂:Ce³⁺ (TAG); orange-red emitting phosphors: BaMgAl₁₀O₁₇:Eu²⁺ (Mn²⁺), Ca₂Si₅N₈:Eu²⁺, (Zn,Mg)S:Mn, (Ca,Sr,Ba)S:Eu²⁺; UV-deep blue absorbing phosphors for blue and yellow-green emission: (Mg,Ca,Sr,Ba)₂SiO₄:Eu²⁺, (Mg,Ca,Sr,Ba)₃Si₂O₇:Eu²⁺, Ca₈Mg(SiO₄)₄Cl₂:Eu²⁺; and phosphors that can emit over the full visible spectrum depending on composition and processing (Sr,Ca,Ba)SiₓO_{y}N_{z}:Eu²⁺, Y₂O₂S:Eu³⁺, (Ca,Mg,Y)ᵥSi_{w}AlₓO_{y}N_{z}:Eu². A phosphor particle can have a dimension, for example, from 1 μm to 20 μm. A phosphor particle can have a dimension, for example, from 100 nm to 1 μm. A phosphor particle can be combination of phosphors having different particles sizes.

### IX (1). Non-Electrically Conductive Fillers

Compositions provided by the present disclosure can comprise a non-conductive filler or a combination of non-conductive filler. A non-conductive filler can comprise, for example, an inorganic filler, an organic filler, a low-density filler, or a combination of any of the foregoing. A non-conductive filler can comprise an organic filler, an inorganic filler, a low-density filler, or a combination of any of the foregoing. non-conductive filler can be added to a composition, for example, to improve the physical properties of a cured composition and/or to reduce the weight of a cured composition. A non-conductive filler can be rendered conductive, for example, by coating the surface of the non-conductive filler with a conductive layer.

Inorganic filler useful in compositions provided by the present disclosure and useful for aviation and aerospace applications include calcium carbonate, precipitated calcium carbonate, calcium hydroxide, hydrated alumina (aluminum hydroxide), fumed silica, silica, precipitated silica, silica gel, and combinations of any of the foregoing. For example, an inorganic filler can include a combination calcium carbonate and fumed silica, and the calcium carbonate and fumed silica can be treated and/or untreated. An inorganic filler can comprise calcium carbonate and fumed silica.

An inorganic filler can be coated or uncoated. For example, an inorganic filler can be coated with a hydrophobic material, such as a coating of polydimethylsiloxane.

Suitable calcium carbonate filler include products such as Socal® 31, Socal® 312, Socal® U1S1, Socal® UaS2, Socal® N2R, Winnofil® SPM, and Winnofil® SPT available from Solvay Special Chemicals. A calcium carbonate filler can include a combination of precipitated calcium carbonates.

Inorganic filler can be surface treated to provide hydrophobic or hydrophilic surfaces that can facilitate dispersion and compatibility of the inorganic filler with other components of a coreactive composition. An inorganic filler can include surface-modified particles such as, for example, surface modified silica. The surface of silica particles can be modified, for example, to be tailor the hydrophobicity or hydrophilicity of the surface of the silica particle. The surface modification can affect the dispensability of the particles, the viscosity, the curing rate, and/or the adhesion.

Compositions provided by the present disclosure can comprise silica gel or combination of silica gel. Suitable silica gels include Gasil® silica gel available from PQ Corporation, and Sylysia®, CariAct® and Sylomask® silica gel available from Fuji Silysia Chemical Ltd.

Suitable organic filler can also have acceptable adhesion to the sulfur-containing polymer matrix. An organic filler can include solid particles, hollow particles, or a combination thereof. The particles can be generally spherical (referred to as powders), generally non-spherical (referred to as particulates), or a combination thereof.

The organic particles can have a mean particle diameter less than, for example, 100 μm, 50 μm, 40 μm, 30 μm, or less than 25 μm, as determined according to ASTM E-2651-13. A powder can comprise particles having a mean particle diameter with a range from 0.25 μm to 100 μm, 0.5 μm to 50 μm, from 0.5 μm to 40 μm, from 0.5 μm to 30 μm, from 0.5 μm to 20 μm, from 0.1 μm to 10 μm, or within any range defined between any of the foregoing two values and endpoints. Organic filler particles can comprise nano-powders, comprising particles characterized by a mean particle size, for example, from 1 nm to 100 nm.

An organic filler can have a specific gravity, for example, less than 1.6, less than 1.4, less than 1.15, less than 1.1, less than 1.05, less than 1, less than 0.95, less than 0.9, less than 0.8, or less than 0.7, where specific gravity is determined according to ISO 787 (Part 10). Organic filler can have a specific gravity, for example, within a range from 0.85 to 1.6, within a range from 0.85 to 1.4, within a range from 0.85 to 1.1, within a range from 0.9 to 1.05, from 0.9 to 1.05, or within any range defined between any of the foregoing two values and endpoints where specific gravity is determined according to ISO 787 (Part 10).

Organic filler can comprise thermoplastics, thermosets, or a combination thereof. Examples of suitable organic filler include epoxies, epoxy-amides, ETFE copolymers, polyethylenes, polypropylenes, polyvinylidene chlorides, polyvinylfluorides, TFE, polyamides, polyimides, ethylene propylenes, perfluorohydrocarbons, fluoroethylenes, polycarbonates, polyetheretherketones, polyetherketones, polyphenylene oxides, polyphenylene sulfides, polyether sulfones, thermoplastic copolyesters, polystyrenes, polyvinyl chlorides, melamines, polyesters, phenolics, epichlorohydrins, fluorinated hydrocarbons, polycyclics, polybutadienes, polychloroprenes, polyisoprenes, polysulfides, polyurethanes, isobutylene isoprenes, silicones, styrene butadienes, liquid crystal polymers, and combinations of any of the foregoing.

Examples of suitable organic filler include polyamides such as polyamide 6 and polyamide 12, polyimides, polyethylene, polyphenylene sulfides, polyether sulfones, polysulfones, polyetherimides, polyvinyl fluorides, thermoplastic copolyesters, and combinations of any of the foregoing.

Examples of suitable polyamide 6 and polyamide 12 particles are available from Toray Plastics as grades SP-500, SP-10, TR-1, and TR-2. Suitable polyamides are also available from the Arkema Group under the tradename Orgasol®, and from Evonik Industries under the tradename Vestosin®. For example, Ganzpearl® polyamides such as Ganzpearl® GPA-550 and GPA-700 are available from Persperse Sakai Trading, New York, NY.

Examples of suitable polyimide filler are available from Evonik Industries under the tradename P84®NT.

An organic filler can include a polyethylene, such as an oxidized polyethylene powder. Suitable polyethylenes are available, for example, from Honeywell International, Inc. under the tradename ACumist®, from INEOS under the tradename Eltrex®, and Mitsui Chemicals America, Inc. under the tradename Mipelon™.

The use of organic filler such as polyphenylene sulfide in sealants is disclosed in U.S. Pat. No. 9,422,451. Polyphenylene sulfide is a thermoplastic engineering resin that exhibits dimensional stability, chemical resistance, and resistance to corrosive and high temperature environments. Polyphenylene sulfide engineering resins are commercially available, for example, under the tradenames Ryton® (Chevron), Techtron® (Quadrant), Fortron® (Celanese), and Torelina® (Toray). Polyphenylene sulfide resins are generally characterized by a specific gravity from about 1.3 to about 1.4, where specific gravity is determined according to ISO 787 (Part 10). Polyphenylene sulfide particles having a density of 1.34 g/cm³ and a mean particle diameter of 0.2 μm to 0.25 μm (in water, or from 0.4 μm to 0.5 μm in isopropanol) are available from Toray Industries, Inc.

Polyether sulfone particles are available from Toray Industries, Inc., which have a density of 1.37 g/cm³ and a mean particle diameter from 5 μm to 60 μm.

Thermoplastic copolyester particles can be obtained from Toray Industries, Inc.

An organic filler can have any suitable shape. For example, an organic filler can comprise fractions of crushed polymer that have been filtered to a desired size range. An organic filler can comprise substantially spherical particles. Particles can be non-porous or can be porous. A porous particle can have a network of open channels that define internal surfaces.

An organic filler can have a specific gravity, for example, less than 1.15, less than 1.1, less than 1.05, less than 1, less than 0.95, less than 0.9, less than 0.8, or less than 0.7. Organic filler can have a specific gravity, for example, within a range from 0.85 to 1.15, within a range from 0.9 to 1.1, within a range from 0.9 to 1.05, or from 0.85 to 1.05.

### IX (m). Low-Density Fillers

An organic filler can include a low density such as a modified, expanded thermoplastic microcapsules. Suitable modified expanded thermoplastic microcapsules can include an exterior coating of a melamine or urea/formaldehyde resin.

Compositions provided by the present disclosure can comprise low density microcapsules. A low-density microcapsule can comprise a thermally expandable microcapsule.

A thermally expandable microcapsule refers to a hollow shell comprising a volatile material that expands at a predetermined temperature. Thermally expandable thermoplastic microcapsules can have an average initial particle size of 5 μm to 70 μm, in some cases 10 μm to 24 μm, or from 10 μm to 17 μm. The term “average initial particle size” refers to the average particle size (numerical weighted average of the particle size distribution) of the microcapsules prior to any expansion. The particle size distribution can be determined using a Fischer Sub-Sieve Sizer or by optical inspection.

A thermally expandable thermoplastic microcapsule can comprise a volatile hydrocarbon within a wall of a thermoplastic resin. Examples of hydrocarbons suitable for use in such microcapsules include methyl chloride, methyl bromide, trichloroethane, dichloroethane, n-butane, n-heptane, n-propane, n-hexane, n-pentane, isobutane, isopentane, iso-octane, neopentane, petroleum ether, and aliphatic hydrocarbons containing fluorine, such as Freon™, and combinations of any of the foregoing.

Examples of materials suitable for forming the wall of a thermally expandable microcapsule include polymers of vinylidene chloride, acrylonitrile, styrene, polycarbonate, methyl methacrylate, ethyl acrylate, and vinyl acetate, copolymers of these monomers, and combinations of the polymers and copolymers. A crosslinking agent may be included with the materials forming the wall of a thermally expandable microcapsule.

Examples of suitable thermoplastic microcapsules include Expancel™ microcapsules such as Expancel™ DE microspheres available from AkzoNobel. Examples of suitable Expancel™ DE microspheres include Expancel™ 920 DE 40 and Expancel™ 920 DE 80. Suitable low-density microcapsules are also available from Kureha Corporation.

Suitable low-density filler such as low-density microcapsules can have a mean diameter (d0.5), for example, from 1 μm to 100 μm, from 10 μm to 80 μm, from 10 μm to 50 μm, or within any range defined between any of the foregoing two values and endpoints as determined according to ASTM D1475.

Low density filler such as low density microcapsules can be characterized by a specific gravity within a range from 0.01 to 0.09, from 0.04 to 0.09, within a range from 0.04 to 0.08, within a range from 0.01 to 0.07, within a range from 0.02 to 0.06, within a range from 0.03 to 0.05, within a range from 0.05 to 0.09, from 0.06 to 0.09, within a range from 0.07 to 0.09, or within any range defined between any of the foregoing two values and endpoints wherein the specific gravity is determined according to ASTM D1475. Low density filler such as low-density microcapsules can be characterized by a specific gravity less than 0.1, less than 0.09, less than 0.08, less than 0.07, less than 0.06, less than 0.05, less than 0.04, less than 0.03, or less than 0.02, wherein the specific gravity is determined according to ASTM D1475.

Low density filler such as low microcapsules can be characterized by a mean particle diameter from 1 μm to 100 μm and can have a substantially spherical shape. Low density filler such as low-density microcapsules can be characterized, for example, by a mean particle diameter from 10 μm to 100 μm, from 10 μm to 60 μm, from 10 μm to 40 μm, from 10 μm to 30 μm, or within any range defined between any of the foregoing two values and endpoints as determined according to ASTM D1475.

Low density filler can comprise uncoated microcapsules, coated microcapsules, or combinations thereof.

Low density filler such as low-density microcapsules can comprise expanded microcapsules or microballoons having a coating of an aminoplast resin such as a melamine resin. Aminoplast resin-coated particles are described, for example, in U.S. Pat. No. 8,993,691, which is incorporated by reference in its entirety. Such microcapsules can be formed by heating a microcapsule comprising a blowing agent surrounded by a thermoplastic shell. Uncoated low-density microcapsules can be reacted with an aminoplast resin such as a urea/formaldehyde resin to provide a coating of a thermoset resin on the outer surface of the particle.

Low density filler such as low-density microcapsules can comprise thermally expandable thermoplastic microcapsules having an exterior coating of an aminoplast resin, such as a melamine resin. The coated low-density microcapsules can have an exterior coating of a melamine resin, where the coating can have a thickness, for example, less than 2 μm, less than 1 μm, or less than 0.5 μm. The melamine coating on the lightweight microcapsules is believed to render the microcapsules reactive with the thiol-terminated polythioether prepolymer and/or the polyepoxide curing agent, which enhances the fuel resistance, and renders the microcapsules resistant to pressure.

The thin coating of an aminoplast resin can have a film thickness of less than 25 μm, less than 20 μm, less than 15 μm, or less than 5 μm. The thin coating of an aminoplast resin can have a film thickness of at least 0.1 nanometers, such as at least 10 nanometers, or at least 100 nanometers, or, in some cases, at least 500 nanometers.

Aminoplast resins can be based on the condensation products of formaldehyde, with an amino- or amido-group carrying substance. Condensation products can be obtained from the reaction of alcohols and formaldehyde with melamine, urea or benzoguanamine. Condensation products of other amines and amides can also be employed, for example, aldehyde condensates of triazines, diazines, triazoles, guanidines, guanamines and alkyl- and aryl-substituted derivatives of such compounds, including alkyl- and aryl-substituted ureas and alkyl- and aryl-substituted melamines. Examples of such compounds include N,N′-dimethyl urea, benzourea, dicyandiamide, formaguanamine, acetoguanamine, glycoluril, ammeline, 2-chloro-4,6-diamino-1,3,5-triazine, 6-methyl-2,4-diamino-1,3,5-triazine, 3,5-diaminotriazole, triaminopyrimidine, 2-mercapto-4,6-diaminopyrimidine and 3,4,6-tris(ethylamino)-1,3,5 triazine. Suitable aminoplast resins can also be based on the condensation products of other aldehydes such as acetaldehyde, crotonaldehyde, acrolein, benzaldehyde, furfural, and glyoxal.

An aminoplast resin can comprise a highly alkylated, low-imino aminoplast resin which has a degree of polymerization less than 3.75, such as less than 3.0, or less than 2.0. The number average degree of polymerization can be defined as the average number of structural units per polymer chain. For example, a degree of polymerization of 1.0 indicates a completely monomeric triazine structure, while a degree of polymerization of 2.0 indicates two triazine rings joined by a methylene or methylene-oxy bridge. Degree of polymerization represents an average degree of polymerization value as determined by gel permeation chromatography using polystyrene standards.

An aminoplast resin can contain methylol or other alkylol groups, and at least a portion of the alkylol groups can be etherified by reaction with an alcohol. Examples of suitable monohydric alcohols include alcohols such as methanol, ethanol, propanol, butanol, pentanol, hexanol, heptanol, benzyl alcohol, other aromatic alcohols, cyclic alcohols such as cyclohexanol, monoethers of glycols, and halogen-substituted or other substituted alcohols, such as 3-chloropropanol and butoxyethanol. Aminoplast resins can be substantially alkylated with methanol or butanol.

An aminoplast resin can comprise a melamine resin. Examples of suitable melamine resins include methylated melamine resins (hexamethoxymethylmelamine), mixed ether melamine resins, butylated melamine resins, urea resins, butylated urea resins, benzoguanamine and glycoluril resins, and formaldehyde free resins. Such resins are available, for example, from Allnex Group and Hexion. Examples of suitable melamine resins include methylated melamine resins such as Cymel™ 300, Cymel™ 301, Cyme™ 303LF, Cymel™ 303ULF, Cymel™ 304, Cymel™ 350, Cymel 3745, Cymel™ XW-3106, Cymel™ MM-100, Cymel™ 370, Cymel™ 373, Cymel™ 380, ASTRO MEL™601, ASTRO MEL™ 601ULF, ASTRO MEL™400, ASTRO MEL™ NVV-3A, Aricel PC-6A, ASTRO MEL™ CR-1, and ASTRO SET™ 90.

A suitable aminoplast resin can comprise a urea-formaldehyde resin.

Amninoplast resin-coated particles are distinct from uncoated particles that are merely incorporated into a polymer network, such as is the case when uncoated low-density particles are dispersed in a film-forming binder. For aminoplast resin-coated particles, a thin film is deposited on the exterior surface of individual discrete particles such as thermally expanded microcapsules. These aminoplast resin-coated particles may then be dispersed in a film-forming binder, thereby resulting in dispersion of the coated particles throughout a polymer network. The thin coating of an aminoplast resin can cover, for example from 70% to 100%, from 80% to 100%, from 90% to 100%, or within any range defined between any of the foregoing two values and endpoints of the exterior surface of a low-density particle such as a thermally expanded microcapsule. The coating of an aminoplast resin can form a substantially continuous covering on the exterior surface of a low-density particle.

Low density microcapsules can be prepared by any suitable technique, including, for example, as described U.S. Pat. Nos. 8,816,023 and 8,993,691, each of which is incorporated by reference in its entirety. Coated low density microcapsules can be obtained, for example, by preparing an aqueous dispersion of microcapsules in water with a melamine resin, under stirring. A catalyst may then be added and the dispersion heated to, for example, a temperature from 50° C. to 80° C. Low density microcapsules such as thermally expanded microcapsules having a polyacrylonitrile shell, de-ionized water and an aminoplast resin such as a melamine resin can be combined and mixed. A 10% w/w solution of para-toluene sulfuric acid in distilled water can then be added and the mixture reacted at 60° C. for about 2 hours. Saturated sodium bicarbonate can then be added and the mixture stirred for 10 minutes. The solids can be filtered, rinsed with distilled water, and dried overnight at room temperature. The resulting powder of aminoplast resin-coated microcapsules can then be sifted through a 250 μm sieve to remove and separate agglomerates.

Prior to application of an aminoplast resin coating, a thermally-expanded thermoplastic microcapsule can be characterized by a specific gravity, for example, within a range from 0.01 to 0.05, within a range from 0.015 to 0.045, within a range from 0.02 to 0.04, or within a range from 0.025 to 0.035, or within any range defined between any of the foregoing two values and endpoints, wherein the specific gravity is determined according to ASTM D1475. For example, Expancel™ 920 DE 40 and Expancel™ 920 DE 80 can be characterized by a specific gravity of about 0.03, wherein the specific gravity is determined according to ASTM D1475.

Following coating with an aminoplast resin, an aminoplast-coated microcapsule can be characterized by a specific gravity, for example, within a range from 0.02 to 0.08, within a range from 0.02 to 0.07, within a range from 0.02 to 0.06, within a range from 0.03 to 0.07, within a range from 0.03 to 0.065, within a range from 0.04 to 0.065, within a range from 0.045 to 0.06, within a range from 0.05 to 0.06, or within any range defined between any of the foregoing two values and endpoints. wherein the specific gravity is determined according to ASTM D1475.

### IX (n). Other Non-Conductive Fillers

Non-conductive filler can include non-conductive fiber. A non-conductive fiber can comprise an inorganic fiber, an organic fiber, a ceramic fiber, or a combination of any of the foregoing. Examples of suitable fiber include glass, silica, ceramic, organic materials, and synthetic fibers. Examples of suitable synthetic fibers include nylon, polyester, polypropylene, meta-aramid, para-aramid, polyphenylene sulfide, and rayon. Fiber can serve to impart tensile strength, electrical conductivity, thermal conductivity, EMI/RFI shielding, flexural modulus, flexural strength, and/or tensile modulus, to a built article.

### X. Additives

Compositions provided by the present disclosure can include various additives such as, for example, rheology modifiers (e.g., silica or other filler), flow control agents, plasticizers, thermal stabilizers, UV stabilizers, wetting agents, dispersing auxiliaries, deformers, filler, reactive diluents, flame retardants, catalysts, pigments, solvents, adhesion promoters, and combinations of any of the foregoing.

A composition provided by the present disclosure can include various additives such as rheology modifiers (e.g., silica or other particulate filler), flow control agents, plasticizers, stabilizers, wetting agents, dispersing auxiliaries, defoamers, pigment and other colorants, fire retardant, adhesion promoter, catalyst or other performance or property modifiers such as barium sulfate, clay or magnesium compounds as required to impart barrier or corrosion resistance properties.

### XI. Catalyst

Compositions provided by the present disclosure can comprise a catalyst or combination of catalysts selected to catalyze a reaction between the first coreactive compound and the second coreactive compound.

### XII. UV Photoinitiator

Compositions provided by the present disclosure can include a photoinitiator or combination of photoinitiators. The radiation can be actinic radiation that can apply energy that can generate an initiating species from a photopolymerization initiator upon irradiation therewith, and widely includes α-rays, γ-rays, X-rays, ultraviolet (UV) light, visible light, or an electron beam. For example, the photoinitiator can be a UV photoinitiator.

For example, compositions comprising a polythiol and a polyalkenyl can be cured using actinic radiation. The polythiol/polyalkenyl system can be cured solely be free radical photoinitiation or can be partially cured by a photoinitiated free-radical mechanism. The polythiol/polyalkenyl composition include an amine catalyst. The polythiol/polyalkenyl composition can include a dark cure catalyst. For example, dark cure thiol/alkenyl catalysts are disclosed in U.S. Pat. No. 9,796,858 B2, in PCT International Publication No. WO 2017/087055 A1, and in PCT International Application No. PCT/US2018/36746, filed on Jun. 8, 2018.

Examples of suitable UV photoinitiators include α-hydroxyketones, benzophenone, a, α-diethoxyacetophenone, 4,4-diethylaminobenzophenone, 2,2-dimethoxy-2-phenylacetophenone, 4-isopropylphenyl 2-hydroxy-2-propyl ketone, 1-hydroxycyclohexyl phenyl ketone, isoamyl p-dimethylaminobenzoate, methyl 4-dimethylaminobenzoate, methyl O-benzoylbenzoate, benzoin, benzoin ethyl ether, benzoin isopropyl ether, benzoin isobutyl ether, 2-hydroxy-2-methyl-1-phenylpropan-1-one, 2-isopropylthioxanthone, dibenzosuberone, 2,4,6-trimethylbenzoyldiphenylphosphine oxide, bisacyclphosphine oxide.

Examples of suitable benzophenone photoinitiators include 2-hydroxy-2-methyl-1-phenyl-1-propanone, 2-hydroxy-1,4,4-(2-hydroxyethoxy)phenyl]-2-methyl-1-propanone, α-dimethoxy-α-phenylacetophenone, 2-benzyl-2-(dimethylamino)-1-[4-(4-morpholinyl) phenyl]-1-butanone, and 2-methyl-1-[4-(methylthio)phenyl]-2-(4-morpholinyl)-1-propanone.

Examples of suitable oxime photoinitiators include (hydroxyimino)cyclohexane, 1-[4-(phenylthio)phenyl]-octane-1,2-dione-2-(O-benzoyloxime), 1-[9-ethyl-6-(2-methylbenzoyl)-9H-carbazol-3-yl]-ethanone-1-(O-acetyloxime), trichloromethyl-triazine derivatives), 4-(4-methoxystyryl)-2,6-trichloromethyl-1,3,5-triazine), 4-(4-methoxyphenyl)-2,6-trichloromethyl-1,3,5-triazine, and α-aminoketone (1-(4-morpholinophenyl)-2-dimethylamino-2-benzyl-butan-1-one).

Examples of suitable phosphine oxide photoinitiators include diphenyl (2,4,6-trimethylbenzoyl)-phosphine oxide (TPO) and phenylbis(2,4,6-trimethyl benzoyl) phosphine oxide (BAPO).

Other examples of suitable UV photoinitiators include the Irgacure™ products from BASF, for example the products Irgacure™ 184, Irgacure™ 500, Irgacure™ 1173, Irgacure™ 2959, Irgacure™ 745, Irgacure™ 651, Irgacure™ 369, Irgacure™ 907, Irgacure™ 1000, Irgacure™ 1300, Irgacure™ 819, Irgacure™ 819DW, Irgacure™ 2022, Irgacure™ 2100, Irgacure™ 784, Irgacure™ 250; in addition, the Irgacure™ products from BASF are used, for example the products Irgacure™ MBF, Darocur™ 1173, Darocur™ TPO, Darocur™ 4265.

A UV photoinitiator can comprise, for example, 2,2-dimethoxy-1,2-diphenylethan-1-one (Irgacure® 651, Ciba Specialty Chemicals), 2,4,6-trimethylbenzoyl-diphenyl-phosphineoxide (Darocur® TPO, Ciba Specialty Chemicals), or a combination thereof.

Other examples of suitable photoinitiators include Darocur® TPO (available from Ciba Specialty Chemicals), Lucirin® TPO (available from BASF), Speedcure® TPO (available from Lambson), Irgacure® TPO (available from Ciba Specialty Chemicals, and Omnirad® (available from IGM Resins), and combinations of any of the foregoing.

Compositions provided by the present disclosure can comprise from 1 wt % to 5 wt %, from 1.5 wt % to 4.5 wt %, from 2 wt % to 4 wt %, from 2.5 wt % to 3.5 wt %, or within any range defined between any of the foregoing two values and endpoints of a UV photoinitiator or combination of UV photoinitiators, where wt % is based on the total weight of the composition.

### XIII. Adhesion Promoter

Compositions provided by the present disclosure can include an adhesion promoter or combination of adhesion promoters.

Compositions provided by the present disclosure can comprise, for example, less than 0.1 wt % of an adhesion promoter, less than 0.2 wt %, less than 0.3 wt % or less than 0.4 wt % of an adhesion promoter, where wt % is based on the total weight of the curable composition. A composition provided by the present disclosure can comprise, for example from 0.05 wt % to 0.4 wt %, from 0.05 wt % to 0.3 wt %, from 0.05 wt % to 0.2 wt %, or within any range defined between any of the foregoing two values and endpoints, of an adhesion promoter.

Compositions provided by the present disclosure can comprise an adhesion promoter or combination of adhesion promoters. An adhesion promoter can include a phenolic adhesion promoter, a combination of phenolic adhesion promoters, an organo-functional silane, a combination of organo-functional silanes, or a combination of any of the foregoing. An organosilane can be an amine-functional silane.

Compositions provided by the present disclosure can comprise a phenolic adhesion promoter, an organosilane, or a combination thereof. A phenolic adhesion promoter can comprise a cooked phenolic resin, an un-cooked phenolic resin, or a combination thereof. Examples of suitable adhesion promoters include phenolic resins such as Methylon® phenolic resin, and organosilanes, such as epoxy-, mercapto- or amine-functional silanes, such as Silquest® organosilanes.

Phenolic adhesion promoters can comprise the reaction product of a condensation reaction of a phenolic resin with one or more prepolymers.

Examples of suitable phenolic resins include 2-(hydroxymethyl)phenol, (4-hydroxy-1,3-phenylene)dimethanol, (2-hydroxybenzene-1,3,4-triyl) trimethanol, 2-benzyl-6-(hydroxymethyl)phenol, (4-hydroxy-5-((2-hydroxy-5-(hydroxymethyl)cyclohexa-2,4-dien-1-yl)methyl)-1,3-phenylene)dimethanol, (4-hydroxy-5-((2-hydroxy-3,5-bis(hydroxymethyl)cyclohexa-2,4-dien-1-yl)methyl)-1,3-phenylene)dimethanol, and a combination of any of the foregoing.

Suitable phenolic resins can be synthesized by the base-catalyzed reaction of phenol with formaldehyde.

Phenolic adhesion promoters can comprise the reaction product of a condensation reaction of a Methylon® resin, a Varcum® resin, or a Durez® resin available from Durez Corporation with a thiol-terminated polysulfide such as a Thioplast® resin.

Examples of Methylon® resins include Methylon® 75108 (allyl ether of methylol phenol, see U.S. Pat. No. 3,517,082) and Methylon® 75202.

Examples of Varcum® resins include Varcum® 29101, Varcum® 29108, Varcum® 29112, Varcum® 29116, Varcum® 29008, Varcum® 29202, Varcum® 29401, Varcum® 29159, Varcum® 29181, Varcum® 92600, Varcum® 94635, Varcum® 94879, and Varcum® 94917.

An example of a Durez® resin is Durez® 34071.

provided by the present disclosure can comprise an organo-functional adhesion promoter such as an organo-functional silane. An organo-functional silane can comprise hydrolyzable groups bonded to a silicon atom and at least one organofunctional group. An organo-functional silane can have the structure R^{a}—(CH₂)ₙ—Si(—OR)₃₋ₙR^{b}ₙ, where R^{a} is an organofunctional group, n is 0, 1, or 2, and R and R^{b} is alkyl such as methyl or ethyl. Examples of organofunctional groups include epoxy, amino, methacryloxy, or sulfide groups. An organofunctional silane can be a dipodal silane having two or more silane groups, a functional dipodal silane, a non-functional dipodal silane or a combination of any of the foregoing. An organofunctional silane can be a combination of a monosilane and a dipodal silane.

An amine-functional silane can comprise a primary amine-functional silane, a secondary amine-functional silane, or a combination thereof. A primary amine-functional silane refers to a silane having primary amino group. A secondary amine-functional silane refers to a silane having a secondary amine group. An amine-functional silane can comprise, for example, from 40 wt % to 60 wt % of a primary amine-functional silane; and from 40 wt % to 60 wt % of a secondary amine-functional silane; from 45 wt % to 55 wt % of a primary amine-functional silane and from 45 wt % to 55 wt % of a secondary amine-functional silane; or from 47 wt % to 53 wt % of a primary amine-functional silane and from 47 wt % to 53 wt % of a secondary amine-functional silane; where wt % is based on the total weight of the amine-functional silane in a composition.

A secondary amine-functional silane can be a sterically hindered amine-functional silane. In a sterically hindered amine-functional silane the secondary amine can be proximate a large group or moiety that limits or restricts the degrees of freedom of the secondary amine compared to the degrees of freedom for a non-sterically hindered secondary amine. For example, in a sterically hindered secondary amine, the secondary amine can be proximate a phenyl group, a cyclohexyl group, or a branched alkyl group.

Amine-functional silanes can be monomeric amine-functional silanes having a molecular weight, for example, from 100 Da to 1,000 Da, from 100 Da to 800 Da, from 100 Da to 600 Da, from 200 Da to 500 Da, or within any range defined between any of the foregoing two values and endpoints.

Examples of suitable primary amine-functional silanes include 4-aminobutyltriethoxysilane, 4-amino-3,3-dimethylbutyltrimethoxysilane, N-(2-aminoethyl)-3-aminopropyltriethoxysilane, 3(m-aminophenoxy)propyltrimethoxysilane, m-aminophenyltrimethoxysilane, p-aminophenyltrimethoxysilane, 3-aminopropyltriethoxysilane, 3-aminopropyltrimethoxysilane, 3-aminopropyltris(methoxyethoxyethoxy)silane, 11-aminoundecyltriethoxysilane, 2-(4-pyridylethyl)triethoxysilane, 2-(2-pyridylethyltrimethoxysilane, N-(3-trimethoxysilylpropyl)pyrrole, 3-aminopropylsilanetriol, 4-amino-3,3-dimethylbutylmethyldimethoxysilane, 3-aminopropylmethyldiethoxysilane, 1-amino-2-(dimethylethoxysilyl)propane, 3-aminopropyldiisopropylene ethoxysilane, and 3-aminopropyldimethylethoxysilane.

Examples of suitable diamine-functional silanes include aminoethylaminomethyl)phenethyltrimethoxysilane and N-(2-aminoethyl)-3-aminopropyltrimethoxysilane.

Examples of suitable secondary amine-functional silanes include 3-(N-allylamino)propyltrimethoxysilane, n-butylaminopropyltrimethoxysilane, tert-butylaminopropyltrimethoxysilane, (N,N-cylohexylaminomethyl)methyldiethoxysilane, (N-cyclohexylaminomethyl)triethoxysilane, (N-cyclohexylaminopropyl)trimethoxysilane, (3-(n-ethylamino)isobutyl)methyldiethoxysilane, (3-(N-ethylamino)isobutyl)trimethoxysilane, N-methylaminopropylmethyldimethoxysilane, N-methylaminopropyltrimethoxysilane, (phenylaminomethyl)methyldimethoxysilane, N-phenylaminomethyltriethoxysilane, and N-phenylaminopropyltrimethoxysilane.

Suitable amine-functional silanes are commercially available, for example, from Gelest Inc. and from Dow Corning Corporation.

Compositions provided by the present disclosure can comprise less than 3 wt % of an adhesion promoter, less than 2 wt %, less than 1 wt % or less than 0.5 wt %, where wt % is based on the total weight of the composition.

### XIV. Corrosion Inhibitor

Compositions provided by the present disclosure can comprise one or more corrosion inhibitor. Examples of suitable corrosion inhibitors include, but are not limited to, zinc phosphate-based corrosion inhibitors, for example, micronized Halox® SZP-391, Halox® 430 calcium phosphate, Halox® ZP zinc phosphate, Halox® SW-111 strontium phosphosilicate Halox® 720 mixed metal phosphor-carbonate, and Halox® 550 and 650 proprietary organic corrosion inhibitors commercially available from Halox. Other suitable corrosion inhibitors include Heucophos® ZPA zinc aluminum phosphate and Heucophos® ZMP zinc molybdenum phosphate, commercially available from Heucotech Ltd, PA.

### XV. Reactive Diluents

Compositions provided by the present disclosure can comprise a reactive diluent or combination of reactive diluents. A reactive diluent can be used to reduce the viscosity of the composition. A reactive diluent can be a low molecular weight compound having at least one functional group capable of reacting with at least one of the major reactants of the composition and become part of the cross-linked network. A reactive diluent can have, for example, one functional group, or two functional group. A reactive dilute can be used to control the viscosity of a composition or improve the wetting of filler in a composition. Examples of suitable reactive diluents include organo-functional vinyl ethers such as compounds having the structure CH₂═CH—O—(CH₂)ₜ—R where t is an integer from 2 to 10, and R is a hydroxyl, amine, or epoxy group, and vinyl-based diluents such as styrene, α-methyl styrene and para-vinyl toluene; vinyl acetate; and/or n-vinyl pyrrolidone.

### XVI. Rheological Agents

Compositions provided by the present disclosure can also include a reactive rheological modifier such as a polyethylene, a polyethylene or a propylene/ethylene copolymer. Other examples of suitable plasticizers include phthalates, terephathlic, isophathalic, hydrogenated terphenyls, quaterphenyls and higher or polyphenyls, phthalate esters, chlorinated paraffins, modified polyphenyl, tung oil, benzoates, dibenzoates, thermoplastic polyurethane plasticizers, phthalate esters, naphthalene sulfonate, trimellitates, adipates, sebacates, maleates, sulfonamides, organophosphates, polybutene, butyl acetate, butyl cellosolve, butyl carbitol acetate, dipentene, tributyl phosphate, hexadecanol, diallyl phthalate, sucrose acetate isobutyrate, epoxy ester of iso-octyl tallate, benzophenone and combinations of any of the foregoing.

### XVII. Busbars

Compositions provided by the presence disclosure can also comprise, in addition to a conductive filler and one or more coreactive compounds, other inorganic materials as appropriate for particular application. For example, compositions for forming solar cell electrodes can comprise silver (Ag) particles and glass frit, and an organic vehicle such as an organic binder, solvent, and additives. An organic binder can be used to impart a desired viscosity and/or rheological property to a composition to facilitate deposition solar cell electrodes. The organic binder can also facilitate homogeneous dispersion of the inorganic component of the composition within the printable composition. In compositions provided by the present disclosure the first and second coreactive compounds can serve as the organic binder.

A composition provided by the present disclosure for use in solar cell electrodes can comprise a loading of silver particles. Compositions provided by the present disclosure can include silver particles as the primary electrically conductive material. The silver particles can have an average particle diameter D50, for example, from 1 μm to 200 μm, from 1 μm to 150 μm, from 1 μm to 100 μm, from 1 μm to 50 μm, from 1 μm to 30 μm, from 1 μm to 20 μm, or within any range defined between any of the foregoing two values and endpoints. The silver particles can comprise a combination of silver particles with the different silver particles characterized by a different mean particle diameter. The silver particles can be characterized by a distribution of particle diameters.

The silver particles can have an average particle diameter (D50), for example, from 0.1 μm to about 10 μm, from 0.5 μm to 5 μm, or within any range defined between any of the foregoing two values and endpoints. The average particle diameter may be measured using, for example, using a Horiba LA-960 particle size analyzer after dispersing the conductive silver particles in isopropyl alcohol (IPA) at 25° C. for 3 minutes by ultrasonication. Within this range of average particle diameter, the composition can provide low contact resistance and low line resistance.

The silver particles may have, for example, a spherical, flake or amorphous shape, or a combination of any of the foregoing.

A composition provided by the present disclosure for use in solar cell electrodes can comprise, for example, from 60 wt % to 95 wt %, from 70 wt % to 95 wt %, from 80 wt % to 95 wt %, from 85 wt % to 95 wt % of silver particles, or within any range defined between any of the foregoing two values and endpoints, where wt % is based on the total weight of the composition.

Other electrically conductive particles suitable for use in solar cell applications may be used.

A composition provided by the present disclosure for use in solar cell electrodes can include inorganic particles such as fumed silica.

Fumed silica can be used to control the degree of etching of the anti-reflection layer by the glass frit and can minimize diffusion of the glass frit into the silicon wafer during the firing process, which would otherwise introduce undesirable impurities into the silicon substrate.

The fumed silica can be a synthetic silica prepared by a drying method and may have a high purity of about 99.9% or more. The fumed silica may be prepared, for example, by thermal decomposition of a chlorosilane compound in a gas phase.

The fumed silica can have a specific surface area, for example, from 20 m²/g to 500 m²/g, such as from 50 m²/g to t 200 m²/g. Within this range, it is possible to adjust the degree of etching and secure the flow for minimizing diffusion of impurities into the wafer during the firing process, thereby reducing series resistance due to the diffusion of impurities while improving fill factor and conversion efficiency. The fumed silica may have a specific surface area of about 20 m²/g, 30 m²/g, 40 m²/g, 50 m²/g, 60 m²/g, 70 m²/g, 80 m²/g, 90 m²/g, 100 m²/g, 110 m²/g, 120 m²/g, 130 m²/g, 140 m²/g, 150 m²/g, 160 m²/g, 170 m²/g, 180 m²/g, 190 m²/g, or 200 m²/g.

The fumed silica may be present in an amount, for example, of about 0.2 wt % or less, such as from 0.01 wt % to about 0.15 wt %, where wt % is based on the total weight of the composition. When the amount of fumed silica exceeds about 0.1 wt %, the viscosity of the composition can be too high for screen printing. The fumed silica may be present, for example, in an amount of 0.01 wt %, 0.02 wt %, 0.03 wt %, 0.04 wt %, 0.05 wt %, 0.06 wt %, 0.07 wt %, 0.08 wt %, 0.09 wt %, 0.1 wt %, where wt % is based on the total weight of the composition. A composition provided by the present disclosure for use in solar cell electrodes can comprise, for example, from 0.01 wt % to 0.15 wt %, from 0.03 wt % to 0.14 wt %, from 0.05 wt % to 0.13 wt %, from 0.07 wt % to 0.12 wt %, from 0.09 wt % to 0.11 wt % fumed silica, or within any range defined between any of the foregoing two values and endpoints, where wt % is based on the total weight of the composition.

Glass frit serves to enhance adhesion between the conductive silver particles and the silicon substrate and to form silver crystal grains in an emitter region by etching a passivation layer or antireflection coating (ARC) overlying the silicon substrate and aiding the partial dissolution or partial melting the silver particles so as to reduce contact resistance.

Glass frit can comprise a rare earth metal such as lanthanum, yttrium, or a combination thereof. Other suitable rare earth metals include scandium (Sc), cerium (Ce), praseodymium (Pr), neodymium Nd), promethium (Pm), samarium (Sm), europium (Eu), gadolinium (Gd), terbium (Tb), dysprosium (Dy), holmium (Ho), erbium Er), thulium (Tm), and lutetium (Lu).

Glass frit can comprise lead (Pb), bismuth (Bi), germanium (Ge), gallium (Ga), boron (B), iron (Fe), silicon (Si), zinc (Zn), tantalum (Ta), antimony (Sb), lanthanum (La), selenium (Se), phosphorus (P), chromium (Cr), lithium (Li), tungsten (W), magnesium (Mg), cesium (Cs), strontium (Sr), molybdenum (Mo), titanium (Ti), tin (Sn), indium (In), vanadium (V), barium (Ba), nickel (Ni), copper (Cu), sodium (Na), potassium (K), arsenic (As), cobalt (Co), zirconium (Zr), manganese (Mn), aluminum (Al), or a combination of any of the foregoing. For example, a glass frit can comprise lead Pb, tellurium Te, bismuth Bi, tungsten W, copper Cu, and a rare earth selected from lanthanum La, yttrium Y, or a combination thereof.

Glass frit may be formed from the corresponding oxides.

Glass frit can be characterized, for example, by an average particle diameter D50 within a range from 0.1 μm to about 20 μm and may be present in a composition provided by the present disclosure for use in solar cell electrodes in an amount of about 0.5 wt % to about 20 wt %, where wt % is based on the total weight of the composition. The average particle diameter can be determined using a particle size analyzer. The glass frit may have, for example, a spherical or amorphous shape. A composition provided by the present disclosure for use in solar cell electrodes can contain, for example, from 0.5 wt % to 5 wt % glass frit, from 1 wt % to 4 wt %, from 1.5 wt % to 4 wt %, from 1.5 wt % to 3.5 wt %, where wt %, or within any range defined between any of the foregoing two values and endpoints, is based on the total weight of the composition.

Glass frit can be characterized by a glass transition temperature (T_{g}) within a range from 200° C. to 800° C., such as, for example, within a range from 200° C. to 600° C., or within a range from 300° C. to 600° C.

Glass frit can comprise a combination of one or more types of glass frit having different average particle diameters and/or glass transition temperatures. For example, glass frit can comprise a combination of a first glass frit characterized by a glass transition temperature within a range from 200° C. to 320° C. and a second glass frit characterized by a glass transition temperature within a range from 300° C. to 550° C., where the weight ratio of the first glass frit to the second glass frit can range, for example, from about 1:0.2 to 1:1.

A composition provided by the present disclosure for use in solar cell electrodes can also comprise solvents and rheology control agents. However, using coreactive compounds these additives may be omitted. Alternatively, reactive diluents may be used.

The deposited composition in the form of electrical conductors such as grid lines can have, for example, a width from 0.5 mils to 4 mils, and a height from 0.1 mils to 1.5 mils.

After being applied to a Si substrate, a deposited composition can be dried, for example, at a temperature from 200° C. to 400° C. for from 10 seconds to 60 seconds, and then baked and fired at a temperature from 400° C. to 950° C., or from 30 seconds to 50 seconds, with a peak firing temperature in the range of 750° C. to 950° C., to provide frontside electrical conductors.

Electrical conductors having dimensions of 1.2 mm width and 16 μm height can exhibit electrical resistivity of 1.8 μΩ-cm and can exhibit an adhesion strength of at least 2 N on a silicon substrate, where the electrical conductivity is determined according to line resistivity electrical probe measurement and the adhesion strength is determined according to a 1800 solder tab pull test. For context, Ag thick-film busbars having a resistivity less than 2 μΩ-cm and an adhesion strength greater than 1.5 N are generally considered acceptable for use in the solar cell industry.

### XVIII. Composition—Content

### XVIII (a). Un-Cured Composition—Properties

Compositions provided by the present disclosure can have a viscosity capable of being deposited using additive manufacturing equipment. A suitable viscosity will in part be determined by the pressure capable of being applied by the dispensing equipment and by the temperature of the composition. The temperature can be controlled by heating and/or cooling the mixing apparatus and/or the composition.

A composition provided by the present disclosure can have a fast gel time, for example, less than 5 minutes, less than 4 minutes, less than 3 minutes, less than 2 minutes, less than 1 minute, less than 45 seconds, less than 30 seconds, less than 15 seconds, or less than 5 seconds. A composition can have a fast gel time, for example, from 0.1 seconds to 5 minutes, from 0.2 seconds to 3 minutes, from 0.5 seconds to 2 minutes, from 1 second to 1 minute, from 2 seconds to 40 seconds, or within any range defined between any of the foregoing two values and endpoints. Gel time is the time following mixing when the composition is no longer stirrable by hand.

A composition provided by the present disclosure can have an intermediate gel time, for example, form 5 minutes to 60 minutes, such as from 10 minutes to 40 minutes, from 20 minutes to 30 minutes, or within any range defined between any of the foregoing two values and endpoints.

A composition provided by the present disclosure can have a long gel time, for example, of greater than 60 minutes, greater than 2 hours, greater than 4 hours, greater than 6 hours, or greater than 12 hours.

A composition provided by the present disclosure have a viscosity at 25° C. and a shear rate at 0.1 sec⁻¹ to 100 sec⁻¹ from 200 cP to 50,000,000 cP, from 200 cP to 20,000,000 cP, from 1,000 cP to 18,000,000 cP, from 5,000 cP to 15,000,000 cP, from 5,000 cP to 10,000,000 cP, from 5,000 cP to 5,000,000 cP, from 5,000 cP to 1,000,000 cP, from 5,000 cP to 100,000 cP, from 5,000 cP to 50,000 cP, from 5,000 cP to 20,000 cP, from 6,000 cP to 15,000 cP, from 7,000 cP to 13,000 cP, from 8,000 cP to 12,000 cP, or within any range defined between any of the foregoing two values and endpoints. Viscosity values are measured using an Anton Paar MCR 302 rheometer with a gap from 1 mm at a temperature of 25° C. and a shear rate of 100 sec⁻¹.

A composition provided by the present disclosure can have a tack free time, for example, of less than 2 minutes, less than 4 minutes, less than 6 minutes, less than 8 minutes, less than 10 minutes, less than 20 minutes, or less than 30 minutes.

A composition provided by the present disclosure can have a time to a hardness of Shore 10A, for example, of less than 2 minutes, less than 4 minutes, less than 6 minutes, less than 8 minutes, less than 10 minutes, less than 20 minutes, or less than 30 minutes.

### XVIII b). Cured Composition—Properties

Cured compositions provided by the present disclosure can be electrically conductive. A cured composition can have a conductivity of at least about 10⁻⁸ S/m, from 10⁻⁶ S/m to 10⁵ S/m, or from 10⁻⁵ S/m to 10⁵ S/m. Cured compositions provided by the present disclosure can have conductivities of at least 0.001 S/m, of at least 0.01 S/m, of at least 0.1 S/m, of at least 1 S/m, of at least 10 S/m, of at least 100 S/m, at least 1000 S/m, at least 10,000 S/m, at least 20,000 S/m, at least 30,000 S/m, at least 40,000 S/m, at least 50,000 S/m, at least 60,000 S/m, at least 75,000 S/m, at least 10⁵ S/m, or at least about 10⁶ S/m.

A cured composition provided by the present disclosure can have a surface resistivity of less than 10,000 D/square, less than 5000 Ω/square, less than 1000 Ω/square, less than 700 Ω/square, less than 500 Ω/square, less than 350 Ω/square, less than 200 Ω/square, less than 200 Ω/square, less than 150 Ω/square, less than 100 Ω/square, less than 75 Ω/square, less than 50 Ω/square, less than 30 Ω/square, less than 20 f/square, or no greater than about 10 Ω/square, less than 5 Ω/square, less than 1 Ω/square, less than 0.1 Ω/square, less than 0.01 Ω/square, or less than 0.001 Ω/square.

A cured composition provided by the present disclosure can have a thermal conductivity from 0.1 to 50 W/(m-K), from 0.5 to 30 W/(m-K), from 1 to 30 W/(m-K), from 1 to 20 W/(m-K), from 1 to 10 W/(m-K), from 1 to 5 W/(m-K), from 2 to 25 W/(m-K), from 5 to 25 W/(m-K), or within any range defined between any of the foregoing two values and endpoints.

A cured composition provided by the present disclosure can exhibit shielding, for example, up to 120 dB at 10 GHz, 80 dB at 1 GHz, 60 dB at 10 GHz, greater than 100 dB from 1 KHz to 18 GHz. For certain applications shielding of 10 dB to 30 dB is a minimum requirement, from 20 to 90 dB is superior, and from 90 to 120 dB is exceptional shielding. EMI frequencies cover the range from 1 kHz to 309 MHz, and RFI frequencies encompass the range from 30 MHz to 10 GHz.

### XIX. System—Components

Compositions provided by the present disclosure can be provided as two or more coreactive components, where a first coreactive component comprises a first coreactive compound comprising at least one first functional group and a second coreactive component comprises a second coreactive compound comprising at least one second functional group, where the at least one first functional group is reactive with the at least one second functional group.

### XX. Method

Compositions provided by the present disclosure can be used in any suitable additive manufacturing technology, such as extrusion, jetting, and jetting.

The present disclosure includes the production of structural articles using three-dimensional printing. A three-dimensional article may be produced by forming successive portions or layers of an article by depositing a composition provided by the present disclosure onto a base and depositing successive layers of the composition to build the three-dimensional article. A first coreactive component comprising a first compound can be combined with a second coreactive component comprising a second compound to form a composition that can be deposited to provide a conductive part, a conductive portion of a part, or a conductive element on a part. A coreactive composition can be mixed and then deposited or the coreactive components be deposited separately. When deposited separately, the coreactive components can be deposited simultaneously, sequentially, or both simultaneously and sequentially.

By “portions of an article” is meant subunits of an article, such as layers of an article. The layers may be on successive horizontal parallel planes. The portions may be parallel planes of the deposited material or beads of the deposited material produced as discreet droplets or as a continuous stream of material. The at least two coreactive components may each be provided neat or may also include a solvent (organic and/or water) and/or other additives as described herein.

Coreactive components provided by the present disclosure may be substantially free of solvent. By substantially free is meant that the coreactive components comprise less than 5 wt %, less than 4 wt %, less than 2 wt %, or less than 1 wt % of solvent, where wt % is based on the total weight of a coreactive component. Similarly, a composition provided by the present disclosure may be substantially free of solvent, such as having less than 5 wt %, less than 4 wt %, less than 2 wt %, or less than 1 wt % of solvent, where wt % is based on the total weight of the composition.

Conductive articles and elements can be fabricated with the compositions provided by the present disclosure using coreactive additive manufacturing methods.

Additive manufacturing is intended to encompass a wide variety of robotic manufacturing methods. Additive manufacturing can take many forms depending, for example, on the materials being used and the size of the articles. An example of additive manufacturing which can be used to deposit compositions provided by the present disclosure is three-dimensional printing.

Coreactive additive manufacturing refers to robotic manufacturing methods in which at least two coreactive components are combined and mixed to form a coreactive composition, which is then deposited to provide part. Upon mixing, the coreactive compounds can react at a temperature, for example, at less than 50° C., or less than 30° C. such as from 20° C. to 25° C. and begin curing to form a thermoset polymer matrix. Alternatively, the coreactive compounds do not initially react when first combined but react when energy such as actinic radiation, heat, and/or a mechanical force such a shear force is applied to the coreactive composition; or the coreactive composition is exposed to a chemical initiator such as a catalyst or moisture. Coreactive compositions in which the curing reaction must be independently initiated are referred to as latent coreactive compositions.

Coreactive additive manufacturing also refers to robotic manufacturing methods in which a latent coreactive composition is activated and deposited to provide a part.

Robotic equipment for fabricating a conductive article can comprise one or more pumps, one or more mixers, and one or more nozzles. One or more coreactive compositions can be pumped into the one or more mixers and forced under pressure through one or more nozzles directed onto a surface or a previously applied layer.

The robotic equipment can comprise, for example, pressure controls, extrusion dies, coextrusion dies, coating applicators, temperature control elements, elements for applying energy to the coreactive composition, or combinations of any of the foregoing.

The robotic equipment can comprise a build apparatus for moving a nozzle in three dimensions with respect to a surface. The build apparatus can be controlled by a processor.

A conductive article can be fabricated by forming successive portions or layers of an article by depositing a coreactive composition comprising at least two coreactive components onto a substrate and thereafter depositing additional portions or layers of the coreactive composition over the underlying deposited portion or layer and/or adjacent the previously deposited portion or layer. Layers can be successively deposited on top of and/or adjacent a previously deposited layer to build a conductive article. A coreactive composition can be mixed and then deposited or the coreactive components can be deposited separately. When deposited separately, the coreactive components can be deposited simultaneously, sequentially, or both simultaneously and sequentially.

Coreactive compositions can be deposited using any suitable coreactive additive manufacturing equipment. The selection of a suitable coreactive additive manufacturing can depend on a number of factors including the deposition volume, the viscosity of the coreactive composition, the deposition rate, the reaction rate of the coreactive compounds, and the complexity and size of the conductive article being fabricated. Each of the two or more coreactive components can be introduced into an independent pump and injected into a mixer to combine and mix the two coreactive components to form the coreactive composition. A nozzle can be coupled to the mixer and the mixed coreactive composition can be forced under pressure or extruded through the nozzle.

A pump can be, for example, a positive displacement pump, a syringe pump, a piston pump, or a progressive cavity pump. The two pumps delivering the two coreactive components can be placed in parallel or placed in series. A suitable pump can be capable of pushing a liquid or viscous liquid through a nozzle orifice. This process can also be referred to as extrusion. A coreactive component can also be introduced into the mixer using two pumps in series.

For example, two or more coreactive components can be deposited by dispensing materials through a disposable nozzle attached to a progressive cavity two-component system where the coreactive components are mixed in-line. A two-component system can comprise, for example, two progressive cavity pumps that separately dose coreactive components into a disposable static mixer dispenser or into a dynamic mixer. Other suitable pumps include positive displacement pumps, syringe pumps, piston pumps, and progressive cavity pumps. After mixing to form a coreactive composition, the coreactive composition forms an extrudate as it is forced under pressure through one or more dies and/or one or nozzles to be deposited onto a base to provide an initial layer of a conductive article, and successive layers can be deposited onto and/or adjacent a previously deposited layer. The deposition system can be positioned orthogonal to the base, but also may be set at any suitable angle to form the extrudate such that the extrudate and deposition system form an obtuse angle with the extrudate being parallel to the base. The extrudate refers to the coreactive composition after the coreactive components are mixed, for example, in a static mixer or in a dynamic mixer. The extrudate can be shaped upon passing through a die and/or nozzle.

The base, the deposition system, or both the base and the deposition system may be moved to build up a three-dimensional conductive article. The motion can be made in a predetermined manner, which may be accomplished using any suitable CAD/CAM method and apparatus such as robotics and/or computerize machine tool interfaces.

An extrudate may be dispensed continuously or intermittently to form an initial layer and successive layers. For intermittent deposition, a deposition system may interface with a switch to shut off the pumps, such as the progressive cavity pumps and thereby interrupt the flow of the coreactive composition.

A deposition system can include an in-line static and/or dynamic mixer as well as separate pressurized pumping compartments to hold the at least two coreactive components and feed the coreactive components into the static and/or dynamic mixer. A mixer such as an active mixer can comprise a variable speed central impeller having high shear blades within a nozzle. A range of nozzles may be used which have a minimum dimension, for example, from 0.2 mm to 100 mm, from 0.5 mm to 75 mm, from 1 mm to 50 mm, from 5 mm to 25 mm, or within any range defined between any of the foregoing two values and endpoints. A nozzle can have a minimum dimension, for example, greater than 1 mm, greater than 2 mm, greater than 5 mm, greater than 10 mm, greater than 20 mm, greater than 30 mm, greater than 40 mm, greater than 50 mm, greater than 60 mm, greater than 70 mm, greater than 80 mm, or greater than 90 mm. A nozzle can have a minimum dimension, for example, less than 100 mm, less than 90 mm, less than 80 mm, less than 70 mm, less than 60 mm, less than 50 mm, less than 40 mm, less than 30 mm, less than 20 mm, less than 10 mm, or less than 5 mm. A nozzle can have any suitable cross-sectional dimension such as, for example, round, spherical, oval, rectangular, square, trapezoidal, triangular, planar, or other suitable shape. The aspect ratio or ratio of the orthogonal dimensions can be any suitable dimensions as appropriate for fabricating a conductive article such as a 1:1, greater than 1:2, greater than 1:3, greater than 1:5, or greater than 1:10.

A range of static and/or dynamic mixing nozzles may be used which have, for example, an exit orifice dimension from 0.6 mm to 2.5 mm, and a length from 30 mm to 150 mm. For example, an exit orifice diameter can be from 0.2 mm to 4.0 mm, from 0.4 mm to 3.0 mm, from 0.6 mm to 2.5 mm, from 0.8 mm to 2 mm, from 1.0 mm to 1.6 mm, or within any range defined between any of the foregoing two values and endpoints. A static mixer and/or dynamic can have a length, for example, from 10 mm to 200 mm, from 20 mm to 175 mm, from 30 mm to 150 mm, from 50 mm to 100 mm, or within any range defined between any of the foregoing two values and endpoints. A mixing nozzle can include a static and/or dynamic mixing section and a dispensing section coupled to the static and/or dynamic mixing section. The static and/or dynamic mixing section can be configured to combine and mix the coreactive materials. The dispensing section can be, for example, a straight tube having any of the above orifice diameters. The length of the dispensing section can be configured to provide a region in which the coreactive components can begin to react and build viscosity before being deposited on the article. The length of the dispensing section can be selected, for example, based on the speed of deposition, the rate of reaction of the co-reactants, and the viscosity of the coreactive composition.

A coreactive composition can have a residence time in the static and/or dynamic mixing nozzle, for example, from 0.25 seconds to 5 seconds, from 0.3 seconds to 4 seconds, from 0.5 seconds to 3 seconds, from 1 seconds to 3 seconds, or within any range defined between any of the foregoing two values and endpoints. Other residence times can be used as appropriate based on the curing chemistries and curing rates.

In general, a suitable residence time is less than the gel time of the coreactive composition.

Coreactive compositions can have a volume flow rate, for example, from 0.1 mL/min to 20,000 mL/min, such as from 1 mL/min to 12,000 mL/min, from 5 mL/min to 8,000 mL/min, from 10 mL/min to 6,000 mL/min, or within any range defined between any of the foregoing two values and endpoints. The volume flow rate can depend, for example, on the viscosity of a coreactive composition, the extrusion pressure, the nozzle diameter, and the reaction rate of the coreactive compounds.

A coreactive composition can be used at a deposition speed, for example, from 1 mm/sec to 400 mm/sec, such as from 5 mm/sec to 300 mm/sec, from 10 mm/sec to 200 mm/sec, from 15 mm/sec to 150 mm/sec, or within any range defined between any of the foregoing two values and endpoints. The deposition speed can depend, for example, on the viscosity of the coreactive composition, the extrusion pressure, the nozzle diameter, and the reaction rate of the coreactive compounds. The deposition speed refers to the speed at which a nozzle used to extrude a coreactive composition moves with respect to a surface onto which the coreactive composition is being deposited.

A static and/or dynamic mixing nozzle can be heated or cooled to control, for example, the rate of reaction between the coreactive compounds and/or the viscosity of the coreactive components. An orifice of a deposition nozzle can have any suitable shape and dimensions. A system can comprise multiple deposition nozzles. The nozzles can have a fixed orifice dimension and shape, or the nozzle orifice can be controllably adjusted. The mixer and/or the nozzle may be cooled to control an exotherm generated by the reaction of the coreactive compounds.

The speed at which the coreactive composition reacts to form the thermoset polymeric matrix can be determined and/or controlled the selection of the reactive functional groups of the coreactive compounds. The reaction speed can also be determined by factors that lower the activation energy of the reaction such as heat and/or catalysts.

Reaction rates can be reflected in the gel time of a coreactive composition. A fast curing chemistry refers to a chemistry in which the coreactive compounds have a gel time, for example, less than 30 minutes, less than 20 minutes, less than 10 minutes, less than 5 minutes, less than 4 minutes, less than 3 minutes, less than 2 minutes, less than 1 minute, less than 45 seconds, less than 30 seconds, less than 15 seconds, or less than 5 seconds. Coreactive compositions can have a gel time, for example, from 0.1 seconds to 5 minutes, from 0.2 seconds to 3 minutes, from 0.5 seconds to 2 minutes, from 1 second to 1 minute, from 2 seconds to 40 seconds, or within any range defined between any of the foregoing two values and endpoints. Gel time is the time following mixing the coreactive components when the coreactive composition is no longer stirrable by hand. A gel time of a latent coreactive composition refers to the time from when the curing reaction is first initiated until the coreactive composition is no longer stirrable by hand.

Because the coreactive components can be uniformly combined and mixed a coreactive composition can begin to cure immediately upon mixing, the dimensions of the coreactive composition and the extrudate that is forced through the nozzle is not particularly limited. Thus, coreactive additive manufacturing facilitates the use of large dimension extrudates, which facilitates the ability to rapidly fabricate both small and large conductive articles.

Coreactive additive manufacturing also can facilitate the ability to fabricate conductive articles having a wide range of material properties by either continuously or intermittently changing the coreactive composition during manufacturing.

For example, a coreactive composition can be changed by: (1) adjusting the volume ratio of one or more of the two or more coreactive components; (2) by introducing an additional coreactive component; (3) by removing one or more of the coreactive components; (4) by introducing a non-coreactive component; (5) by removing a non-coreactive component; (6) by changing one or more of the constituents of a coreactive component; (7) by changing one or more of the constituents of a non-coreactive component; or a combination of any of the foregoing.

By adjusting the combination of coreactive components and/or combination of non-coreactive components during fabrication of a conductive article, the deposited composition can be different in different portions of the conductive article. For example, certain portions of a conductive article can have a higher filler content than other portions of a conductive article; or certain portions of a conductive article can be more rigid than other portions of a conductive article. A thickness of conductive article can have different compositions that results from building up successive overlying layers having different coreactive compositions. For example, an upper surface of a conductive article exposed to the environment can highly chemically resistant and a lower surface of a conductive article can be designed to have enhanced bonding to an underlying surface. A width or lateral dimension of a conductive article can have different material properties such that, for example, one side of a conductive article is elastomeric and another side of a conductive article is rigid. The different properties of a conductive article can be provided by dynamically changing the coreactive composition while the conductive article is being fabricated.

Both the coreactive composition and the dimensions of an extrudate formed from the coreactive composition can be dynamically adjusted during the deposition process. In this way, different portions of a conductive article can be fabricated to have different properties during a continuous fabrication process. The different properties can be in a thickness dimension and/or a lateral dimension of the conductive article. For example, to change the dimensions of the deposited extrudate, the dimension of one or more nozzles used to deposit the extrudate can be dynamically changed while the conductive article is being fabricated. For example, certain regions of a conductive article can require fine detail and for these features depositing successive thin layers of a coreactive composition can be appropriate. In other regions of the conductive article without detail, it can be appropriate to deposit layers having relatively large dimensions.

Coreactive additive manufacturing methods facilitate the ability to change the coreactive composition of a deposited layer during fabrication and thereby fabricate a conductive article having various final material properties. The material properties can be selected based on the intended use of a conductive articles. A coreactive component refers to a composition comprising at least one coreactive compound, where the coreactive compound is coreactive with another coreactive compound contained in a separate coreactive component. A coreactive component can be introduced into a mixer via a pump where the coreactive component can be combined with a second coreactive component and upon mixing forms a coreactive composition.

In certain applications the coreactive components are combined and mixed to form a coreactive composition which can be stored. Although mixed, the coreactive compounds within the coreactive composition do not appreciably react under certain conditions until activated by exposing the coreactive composition to an initiator such as energy or a chemical initiator. Such coreactive compositions can be referred to as latent coreactive compositions. A latent coreactive composition can be stored in the dark, for example to shield the composition from UV light, or stored at low temperature to minimize reaction between the coreactive compounds. The latent coreactive composition can be activated to initiate the chemical reaction by exposing the latent coreactive composition, for example, to actinic radiation, heat, or mechanical force; or by adding a chemical initiator such as a catalyst or cure activator.

A non-coreactive component refers to a composition that does not comprise a coreactive compound. For example, a non-coreactive component can comprise a filler, a catalyst, an initiator, a cure activator, a cure accelerant, a colorant, a corrosion inhibitor, an adhesion promoter, and/or other additive or combination of additive suspended in a solvent, a plasticizer, a UV stabilizer, a rain erosion inhibitor, or dispersant. A non-coreactive component can be uniformly combined and mixed with the coreactive components or can be non-uniformly combined and mixed with the coreactive components.

The dimensions of the extrudate can be adjusted by controlling the diameter of the nozzle and with or without adjusting the flow rate of the coreactive composition. In this way, the dimensions of the extrudate can be continuously or discontinuously adjusted to accommodate the dimensions of a conductive article being fabricated. Thus, the thickness of a fabricated conductive article can be determined by the thickness of the deposited extrudate, which can be controlled by the dimensions of the nozzle. The thickness of a fabricated part need not be determined by the deposition of multiple overlying layers. A cross-section of an extrudate can be configured such that the composition is uniform throughout a cross-section. In a uniform coreactive composition each of the constituents of the coreactive composition are substantially uniformly dispersed and the concentration of each of the constituents is substantially the same throughout the conductive article. For example, a concentration of a constituent can be substantially the same when the concentration is within ±10%, within ±5%, within ±2%, or within ±1% throughout a layer of a conductive article or throughout the conductive article. Examples of constituents include the coreactive compounds and additives.

A cross-section of an extrudate can be configured such that the coreactive composition is non-uniform within the cross-section. For example, one portion of an extrudate cross-section can have one coreactive composition and another portion of an extrudate cross-section can have a different coreactive composition. The differences can be, for example, in the concentration of one or more of the constituents in the two different portions of the extrudate. For example, one portion can have a higher concentration of a filler and/or a higher concentration of one of the coreactive compounds than in another portion of the cross-section.

Alternatively, or in addition, the differences can be in the type of one or more of the constituents and/or the absence of one or more of the constituents in different cross-sectional portions of the extrudate. For example, one portion of an extrudate cross-section can have a coreactive prepolymer with a first backbone chemistry and the other portion can have a coreactive prepolymer with a different polymeric backbone chemistry. The two different portions can have the same curing chemistry or can have different curing chemistries.

In this way a structured extrudate can be used to impart different properties through a thickness of a part. A structured extrudate refers to an extrude in which the coreactive composition is different in a portion of a cross-section of the extrudate and/or in some portion of the length of the extrudate.

Thus, by dynamically varying the coreactive composition in different portions of the extrudate a conductive article part having different material properties in different regions of the conductive article can be fabricated.

The deposition speed of an extrudate can be selected based on parameters such as the flow rate of the coreactive composition, the viscosity of the coreactive composition, and the reaction rate of the coreactive compounds, such that the deposited extrudate retains an intended shape following deposition. For example, it can be important that the deposited layer not sag or shift and if necessary, support one or more overlying layers.

The deposition speed can also be selected such that at least a portion of an exterior surface of a previously deposited layer has not fully cured when a subsequent layer is applied onto the portion of the exterior surface that has not fully cured. In this way, the unreacted compounds in the first layer can then react with the unreacted compounds in the second layer to form covalent bonds and thereby enhance interlayer strength.

After a conductive article has been fabricated, the nozzle can be positioned to a discharge area, the flow of one of coreactive components can be stopped and the apparatus purged to prevent a partially or fully cured coreactive composition from forming within and clogging the apparatus. Alternatively, the introduction of all of the coreactive components can be stopped and a non-reactive composition introduced into the apparatus to purge and clean the system for subsequent use.

The size of the automated manufacturing equipment can be adapted to accommodate the size and features of the conductive article being manufactured.

For example, an additive manufacturing system can comprise a gantry system that can move a deposition nozzle within the horizontal plane and a vertical motion system for moving the nozzle vertically with respect to a surface.

As another example, an additive manufacturing system can consist of a robotic arm that can be suspended above a surface attached to a rotatable nozzle assembly.

The positioning of the additive manufacturing system can be controlled by a processor

The motion can be determined based on a CAD/CAM model of the conductive article being fabricated.

An extrudate comprising a coreactive composition can be deposited onto a coating such as a multilayer coating. The multilayer coating can be an exterior coating of a conductive article. The multilayer coating can be an aesthetic coating, a special effects coating, a haptic coating, a scratch resistant coating, a conductive coating, a reflective coating over a certain wavelength range, an absorptive coating over a certain wavelength range, a stain-resistant coating, or other exterior coating having desired characteristics. The coating can include an adhesion layer configured to facilitate bonding between the multilayer coating and the deposited extrudate. The coating can be an interior coating for facilitating bonding between the conductive article and a substrate.

Methods provided by the present disclosure include printing conductive elements on a fabricated part. Methods provided by the present disclosure include directly printing conductive parts.

Conductive features can be printed while an article is being fabricated. Using the methods provided by the present disclosure conductive parts can be fabricated. The entire part can be formed from a conductive composition or combination of conductive compositions, one or more portions of a part can be formed from a conductive composition, one or more different portions of a part can be formed using different conductive compositions, and/or one or surfaces of a part can be formed from a conductive composition provided by the present disclosure. In addition, internal regions of a part can be formed from a conductive composition provided by the present disclosure.

### XXI. Structured Compositions

Compositions provided by the present disclosure can be provided as a structured composition. A structured composition refers to a composition that is not homogeneous throughout.

For additive manufacturing, the components comprising the co-reactive compounds can be combined and mixed in a mixer and the composition forced through a nozzle of a dispenser to form an extrudate comprising the composition. The extrudate can be deposited onto a substrate and successive layers of the composition can be deposited to build an article.

A cross-section of the extrudate can have a homogeneous composition throughout the cross-section. Alternatively, certain portions of the cross-section and the corresponding longitudinal portions of the extrudate can have a composition that is different than other portions of the extrudate.

For example, the compositions can have a graded composition that varies continuously across a cross-section of the extrudate.

For example, the composition can vary discontinuously in various portions of the cross-sectional profile of the extrudate.

As it relates to conductivity, the conductive filler can be uniformly dispersed throughout the extrudate, or non-uniformly dispersed. For example, the conductive filler can be disposed on the surface or a portion of the surface of the extrudate. For example, the conductive filler can be disposed within the interior of the extrude. The exterior surface of an extrudate and the interior of the extrudate can comprise the same or a different conductive filler.

A structured composition such as a structured extrudate can be formed using a coextrusion die to apply a surface layer and/or an interior region of the extrudate with a composition comprising a conductive filler. A structured composition having a conductive surface can be prepared, for example, by spray coating a conductive composition onto the surface of the extrudate or coating the exterior surface of the extrudate using methods such as dip coating.

### XXII. Article—Properties

Compositions provided by the present disclosure can be used to fabricate conductive parts.

A surface of an electrically conductive part can have a surface resistivity, for example, less than 10⁶ Ohm/square, less than 10⁵ Ohm/square, less than 10⁴ Ohm/square, less than 10³ Ohm/square, less than 10² Ohm/square, less than 10 Ohm/square, less than 10⁻¹ Ohm/square, or less than 10⁻² Ohm/square. A surface of an electrically conductive part can have a surface resistivity, for example, from 10⁻² to 10², from 10² Ohm/square to 10⁶ Ohm/square, from 10³ Ohm/square to 10⁵ Ohm/square, or within any range defined between any of the foregoing two values and endpoints. Surface resistivity can be determined according to ASTM D257.

A surface of an electrically conductive part can have a volume resistivity, for example, less than 10⁶ Ohm/cm, less than 10⁵ Ohm/cm, less than 10⁴ Ohm/cm, less than 10³ Ohm/cm, less than 10² Ohm/cm, less than 10 Ohm/cm, less than 10⁻¹ Ohm/cm, or less than 10⁻² Ohm/cm. A surface of an electrically conductive part can have a volume resistivity, for example, from 10⁻² Ohm/cm to 10¹ Ohm/cm, from 10² Ohm/cm to 10⁶ Ohm/cm, from 10³ Ohm/cm to 10⁵ Ohm/cm, or within any range defined between any of the foregoing two values and endpoints. Volume resistivity can be determined according to ASTM D257.

An electrically conductive part can have an electrical conductivity, for example, greater than 1 S cm⁻¹, greater than 10 S cm⁻¹, greater than 100 S cm⁻¹, greater than 1,000 S cm⁻¹, or greater than 10,000 S cm⁻¹. An electrically conductive part can have an electrical conductivity from 1 S cm⁻¹ to 10,000 S cm⁻¹, from 10 S cm⁻¹ to 1,000 cm⁻¹ from 10 S cm⁻¹ to 500 S cm⁻¹, or within any range defined between any of the foregoing two values and endpoints.

A conductive part can exhibit an attenuation at frequencies within a range from 10 KHz to 20 GHz, for example, of greater than 10 dB, greater than 30 dB, greater than 60 dB, greater than 90 dB, or greater than 120 dB. An electrically conductive part can exhibit an attenuation at frequencies within a range from 10 KHz to 20 GHz, for example, of from 10 dB to 120 dB, from 20 dB to 100 dB, from 30 dB to 90 dB, from 40 dB to 70 dB, or within any range defined between any of the foregoing two values and endpoints.

A conductive part can exhibit a thermal conductivity from 0.1 to 50 W/(m-K), from 0.5 to 30 W/(m-K), from 1 to 30 W/(m-K), from 1 to 20 W/(m-K), from 1 to 10 W/(m-K), from 1 to 5 W/(m-K), from 2 to 25 W/(m-K), from 5 to 25 W/(m-K), or within any range defined between any of the foregoing two values and endpoints.

Compositions provided by the present disclosure can be used to fabricate a variety of electrical components.

Examples of electronic components that may be formed using compositions and methods provided by the present disclosure include conductors, resistors, capacitors, inductors, memristors, diodes, transistors, rectifiers, transducers, relays, chemical or electronic sensors, transformers, antennas, radio frequency identifiers (RFID), batteries, switches, light emitting diodes (LED), thermoelectric devices, piezo-responsive devices, and photovoltaics.

Examples of electronic components that may be formed using compositions and methods provided by the present disclosure include electromagnetic (EM) devices such as motors, inductors, and sensors. The constituents of a composition provided by the present disclosure can be selected for specific properties, for example, electrical or thermal conductivity, dielectric strength, and magnetic permeability.

Compositions provided by the present disclosure can be used to fabricate radio frequency identification (RFID) antenna, printed-circuit boards, smart card inductive components, smart labels, printed electronics, anti-EMI (electromagnetic interference), battery components, and anti-electrostatic materials.

Examples of articles capable of being made at least in part from the compositions provided by the present disclosure include fuel system components fuel tank filler pipes and connectors, fuel line connectors, fuel pumps, fuel pump and delivery module components, fuel injector components, and fuel filter housings, fuel line grounding clips, fuel tank flanges, fuel filter clamps, fuel tank caps, and components comprising heat dissipation elements, such as heat sink fins, fuel tanks; automotive components such as electrical and electronic system connectors and housings, body panels and other body components; airplane components; pipes and tubes; seals; gaskets; electrical and electronic switches, connectors, housings; heat sinks; circuit board housings; contacts; antennas; electrodes; battery and ultracapacitor components; sensor components and housings; electronic devices housings (such as for televisions, computer equipment, video game systems, displays, portable electronic devices such as cellular telephones, GPS receivers, music players, computers, game devices; rubber goods; tires; tanks and bottles such as gas and liquid tanks, cryotanks, and pressure vessels.

The compositions may be used in applications requiring electrical conductivity, static dissipative, electromagnetic interference shielding properties, and combinations of any of the foregoing.

Compositions provided by the present disclosure can be used to fabricate passivation of surfaces, such as metal surfaces, including exterior structures such as bridges and buildings. Examples of other uses of the compositions include UV radiation resistant coatings, abrasion resistant coatings, coatings having permeation resistance to liquids such as hydrocarbon, alcohols, water and/or gases, conductive coatings, and static dissipative coatings. The compositions can be used to make fabrics having electrical and/or thermal conductivity. The coreactive conductive compositions can be used in solar cell applications; solar energy capture applications; signage, flat panel displays; flexible displays, including light-emitting diode, organic light-emitting diode, and polymer light-emitting diode displays; backplanes and front planes for displays; and lighting, including electroluminescent and OLED lighting. The displays may be used as components of portable electronic devices, such as computers, cellular telephones, games, GPS receivers, personal digital assistants, music players, games, calculators, artificial paper and reading devices.

Compositions provided by the present disclosure can be used to fabricate housings, antennas, and other components of portable electronic devices, such as computers, cellular telephones, games, navigation systems, personal digital assistants, music players, games, calculators, radios, artificial paper and reading devices.

Compositions provided by the present disclosure can be used to fabricate can be used to make printed electronic devices that may be in the form of complete devices, parts or sub-elements of devices, and electronic components.

Printed electronics may be fabricated by applying a conductive composition provided by the present disclosure in a pattern comprising an electrically conductive pathway designed to achieve the desired electronic device. Printed electronic devices can take on a wide variety of forms and be used in many applications. Printed electronics can contain multiple layers of electronic components such as circuits and/or substrates. All or part of a printed layer(s) may include printed conductors prepared using coreactive conductive compositions provided by the present disclosure. There may also be one or more materials between the substrate and printed circuits. Layers may include semiconductors, metal foils, dielectric materials, and/or insulators. The printed electronics can include additional components, such as processors, memory chips, other microchips, batteries, resistors, diodes, capacitors, and transistors.

Other applications for compositions provided by the present disclosure include passive and active devices and components; electrical and electronic circuitry, integrated circuits; flexible printed circuit boards; transistors; field-effect transistors; microelectromechanical systems (MEMS) devices; microwave circuits; antennas; diffraction gratings; indicators; chipless tags; security and theft deterrence devices for retail, library, and other settings; key pads; smart cards; sensors; liquid crystalline displays (LCDs); signage; lighting; flat panel displays; flexible displays, including light-emitting diode, organic light-emitting diode, and polymer light-emitting diode displays; backplanes and front planes for displays; electroluminescent and OLED lighting; photovoltaic devices, including backplanes; product identifying chips and devices; membrane switches; batteries, including thin film batteries; electrodes; indicators; printed circuits in portable electronic devices, for example, cellular telephones, computers, personal digital assistants, global positioning system devices, music players, games, and calculators; electronic connections made through hinges or other movable/bendable junctions in electronic devices such as cellular telephones, portable computers, and folding keyboards; wearable electronics; and circuits in vehicles, medical devices, diagnostic devices, and electronic instruments.

The electronic devices may be radiofrequency identification (RFID) devices and/or components thereof and/or radiofrequency communication device. Examples include RFID tags, chips, and antennas. RFID devices may be ultrahigh frequency RFID devices, which may operate at frequencies in the range of about 868 to about 928 MHz. Examples of uses for RFIDs are for tracking shipping containers, products in stores, products in transit, and parts used in manufacturing processes; passports; barcode replacement applications; inventory control applications; pet identification; livestock control; contactless smart cards; and automobile key fobs.

The electronic devices may also be elastomeric such as silicone contact pads and keyboards. Such devices can be used in portable electronic devices, such as calculators, cellular telephones, GPS devices, keyboards, music players, and games. They may also be used in myriad other electronic applications, such as remote controls, touch screens, automotive buttons and switches.

Cured conductive compositions can be flexible or rigid and can be deposited onto substrates that can be flexible or rigid.

A composition of the present disclosure may include: a first coreactive component comprising a first coreactive compound, wherein the first coreactive compound comprises at least one first functional group; and a second coreactive component comprising a second coreactive compound, wherein the second coreactive compound comprises at least one second functional group, wherein the at least one first functional group is reactive with the at least one second functional group; and wherein the composition comprises a conductive filler. In certain examples, the composition has a viscosity from 200 cP to 50,000,000 cP measured using an Anton Paar MCR 3023 rheometer with a gap from 1 mm to 2 mm at 25° C. and a shear rate of 0.1 sec⁻¹. In some examples, the first coreactive component, the second coreactive component, or both the first coreactive component and the second coreactive component comprise the conductive filler. In various examples, the conductive filler comprises an electrically conductive filler, a magnetic filler, a thermally conductive filler, or a combination of any of the foregoing. In certain examples, the filler comprises an electrically conductive filler. In some examples, the electrically conductive filler comprises a metal, a nanomaterial, a conductive oxide, a conductive polymer, a semiconductor, metal-coated particles, graphite, graphene, conductive fiber, carbon nanotubes, or a combination of any of the foregoing. In various examples, the electrically conductive filler comprises graphene. In some examples, the conductive filler comprises magnetic filler. In certain examples, the conductive filler comprises thermally conductive filler. In various examples, the composition further comprises electroactive particles. In some examples, the composition further comprises glass frit. In some examples, the composition comprises from 10 wt % to 90 wt % of the conductive filler, wherein wt % is based on the total weight of the composition. In some examples, the composition comprises from 10 vol % to 90 vol % of the conductive filler, wherein vol % is based on the total volume of the composition. In certain examples, the at least one first functional group comprises a saturated functional group and the at least one second functional group comprises an unsaturated group. In some examples, each of the at least one first functional group and the at least one second functional comprises a saturated functional group. In various examples, each of the at least one first functional group and the at least one second functional comprises an unsaturated functional group. In certain examples, the saturated functional group comprises a thiol group, a hydroxyl group, a primary amine group, a secondary amine group, and/or an epoxy group. In some examples, the unsaturated functional group comprises a reactive double bond. In various examples, the unsaturated functional group comprises an alkenyl group, a Michael acceptor group, an isocyanate group, an acyclic carbonate group, an acetoacetate group, a carboxylic acid group, a vinyl ether group, a (meth)acrylate group, or a malonate group. In certain examples, the at least one first functional group is a carboxylic acid group and the at least one second functional group is an epoxy group. In some examples, the at least one first functional group is a Michael acceptor group and the at least one second functional group is a primary amine group or a secondary amine group. In various examples, the at least one first functional group is an isocyanate group and the at least one second functional group is a primary amine group, a secondary amine group, a hydroxyl group, or a thiol group. In some examples, the at least one first functional group is a cyclic carbonate group, an acetoacetate group, or an epoxy group; and the second functional group is a primary amine group or a secondary amine group. In certain examples, the at least one first functional group is a thiol group, and the second functional group is an alkenyl group, a vinyl ether group, or a (meth)acrylate group. In various examples, the at least one first functional group is a Michael acceptor group and the at least one second functional group is a malonate group. In some examples, the at least one first functional group is a thiol group, and the at least one second functional group is an alkenyl group, an epoxy group, an isocyanate group, an alkynyl group, or a Michael acceptor group. In various examples, the at least one first functional group is a Michael donor group, and the at least one second functional group is a Michael acceptor group. In certain examples, each of the at least one first functional group and the at least one second functional group is a thiol group. In some examples, each of the at least one first functional group and the at least one second functional group is an alkenyl group. In various examples, each of the at least one first functional group and the at least one second functional group is a Michael acceptor group. In certain examples, the first coreactive compound and the second coreactive compound are reactive at a temperature less than 50° C.

A cured composition of the present disclosure may have an electrical conductivity from 10⁻⁸ S/m to 10⁵ S/m. In some examples, the cured composition has surface resistivity less than 10,000 Ω/square. In various examples, the cured composition has a thermal conductivity from 0.1 W/(m-K). to 50 W/(m-K). In certain examples, the cured composition exhibits up to 120 dB attenuation at 10 GHz, 80 dB attenuation at 1 GHz, and/or up to 60 dB attenuation at 10 GHz. In some examples, the cured composition has exhibits greater than 100 dB attenuation from 1 KHz to 18 GHz. In various examples, the cured composition is electrically conductive, is semiconductive, is magnetic, is thermally conductive, exhibits EMI/RFI shielding, and/or is static dissipative. In some examples, at least a portion of an article is fabricated using the composition. In certain examples, fabricating comprises using additive manufacturing. In various examples, additive manufacturing comprises three-dimensional printing. In some examples, the article is electrically conductive, is semiconductive, is magnetic, is thermally conductive, exhibits EMI/RFI shielding, and/or is static dissipative. In certain examples, the article comprises an electrical interconnect. In some examples, the article has an electrical conductivity from 10⁻⁸ S/m to 10⁵ S/m. In various examples, the article has surface resistivity less than 10,000 Ω/square. In certain examples, the article has a thermal conductivity from 0.1 W/(m-K) to 50 W/(m-K). In some examples, the article exhibits up to 120 dB attenuation at 10 GHz, 80 dB attenuation at 1 GHz, and/or up to 60 dB attenuation at 10 GHz. In various examples, the article exhibits greater than 100 dB attenuation from 1 KHz to 18 GHz. In certain examples, the article comprises a surface having an electrical conductivity greater than 1 S cm⁻¹. In some examples, the article comprises a surface having a surface resistivity less than 10⁶ Ohm/square, wherein surface resistivity is determined according to ASTM D257. In various examples, the article comprises a portion having a volume resistivity less than 10⁶ Ohm/cm, wherein the volume resistivity is determined according to ASTM D257. In certain examples, the article comprises a portion that exhibits an attenuation greater than 10 dB at frequencies within at least a portion of the range from 10 KHz to 20 GHz. In some examples, the article comprises a portion that exhibits a thermal conductivity greater than 0.1 W/(m-K). In certain examples, the portion of the article comprises an outer surface and/or an inner surface of the article. In various examples, the portion of the article comprises an embedded portion of the article. In certain examples, electrical properties of the article are substantially homogeneous throughout a cross-section of the portion of the article. In some examples, electrical properties of the article are substantially inhomogeneous throughout a cross-section of the portion of the article.

A method of forming a conductive article may include: combining the first coreactive component and the second coreactive component to provide a composition, wherein the first coreactive component and/or the second coreactive component comprise conductive filler; and depositing the composition to provide a conductive article. In another example, a method of forming a conductive article includes: combining the first coreactive component and the second coreactive component to provide the composition; combining a third coreactive component with the first coreactive component, the second coreactive component, and/or the composition, wherein the third coreactive component comprises conductive filler; and depositing the composition to provide a conductive article. In some examples, depositing comprises additive manufacturing. In certain examples, depositing comprises three-dimensional printing. In various examples, depositing comprises forming an extrudate comprising the composition. In some examples, the method of forming a conductive article further includes applying a composition comprising a conductive filler to a surface of the extrudate. In various examples, depositing comprises co-extruding the composition and at least one additional composition. In some examples, depositing comprises applying successive layers to build the article. In certain examples, the successive layers are covalently bonded to each other. In various examples, the composition is extruded onto a substrate and covalently binds to the substrate. In some examples, depositing comprises depositing the composition on a part to provide an electrically conductive element on the part. In certain examples, an article fabricated using any of the abovementioned methods is contemplated as part of the present disclosure.

### XXIII. Properties of 3D-Printed Parts with Conductive Portions

Methods for forming an article may include forming a portion of the article with a conductive composition of the present disclosure. For example, the full article may be 3D printed using multiple materials, with one or more materials being conductive compositions of the present disclosure. In some examples, an article may be 3D printed to have regions with varying properties, such as electrical conductivities.

As an example, a method of forming an article may include combining first and second chemical components that are reactive with each other to form a coreactive composition, and depositing the coreactive composition to form a conductive portion of an article. In various examples, the conductive portion, such as 1 hr, 3 hr, 6 hr, 12 hr, 24 hr, 48 hr, 72 hr, 96 hr, or 120 hr after depositing, the conductive portion comprises a tensile modulus of at least 1 MPa, 5 MPa, or 10 MPa and/or an electrical conductivity of at least 0.1 S/m, 1 S/m, 2 S/m, or 10 S/m. I various examples, the coreactive composition may include minimal to no solvent content (e.g., less than 5 wt %). The coreactive composition may also include a conductive filler content effective for the conductive portion to reach the target electrical conductivity (e.g., at least 2 S/m).

In various examples, the method of forming an article may further include depositing a matrix composition (e.g., a non-electrically conductive composition) to form a matrix portion of the article. This matrix portion may be formed directly coupled to the conductive portion, such as covalently bound to each other. The article may include multiple matrix portions, which may sandwich or embed the conductive portion created using the conductive coreactive composition. In certain examples, the tensile elongation value and/or flexural strain value at break of the matrix portions may be equal or less than those of the conductive portions. Such property relationship may help the article to preserve its conductive portions under mechanical forces. For example, the matrix portions may be damaged under force prior to the conductive portion would, facilitating timely repairs. In various examples, the conductive portion may be deposited directly onto an object surface of an object. The object surface may be nonplanar. The object may be an aerospace object, an automobile object, an architectural object, a circuit board, or a photovoltaic cell. The conductive portion may form a circuit, a busbar, or a interconnect.

In various examples, the conductive portion achieves conductivity 0.1 S/m, 0.5 S/m, 1 S/m, 5 S/m, or 10 S/m in 30, 60, 120, 180, or 240 minutes in ambient condition without application of heat or actinic radiation. In some examples, the method of forming the article may further include curing the deposited coreactive composition at above 50° C., 70° C., 90° C., or 120° C. for 24, 48, 72, 96, or 120 hours such that the electrical conductivity of the conductive portion exceeds 0.5 S/m, 1 S/m, 5 S/m, 10 S/m, or 20 S/m. In various examples, method of forming the article may further include curing the deposited coreactive composition at above 50° C., 70° C., 90° C., or 120° C. for 24, 48, 72, 96, or 120 hours such that the tensile modulus of the conductive portion exceeds 1 MPa, 5 MPa, or 10 MPa. In some examples, the conductive portion may have a tensile modulus of at least 1 MPa, 5 MPa, or 10 MPa 24, 48, 72, 96, or 120 hours after deposition without application of heat or actinic radiation. In certain examples, the conductive portion further has a fracture strain of at least 1%, 5%, 10%, or 20% 24, 48, 72, 96, or 120 hours after deposition without application of heat or actinic radiation. In various examples, the electrical conductivity of the conductive portion maintains at least 10%, 20%, 30%, 40%, 50%, 60%, or 70% of its strain-free electrical conductivity up to a flexural strain of 1%, 5%, 10%, 15%, or 20% 24, 48, 72, 96, or 120 hours after deposition without application of heat or actinic radiation. In some examples, the method of forming the article may further include curing the deposited coreactive composition at above 50° C., 70° C., 90° C., or 120° C. for 24, 48, 72, 96, or 120 hours such that a tensile modulus of the conductive portion exceeds 100 MPa, 250 MPa, 500 MPa, or 750 MPa. In some examples, the method of forming the article may further include curing the deposited coreactive composition at above 50° C., 70° C., 90° C., or 120° C. for 24, 48, 72, 96, or 120 hours such that a fracture strain of the conductive portion exceeds 1%, 5%, or 10%. In some examples, the method of forming the article may further include curing the deposited coreactive composition at above 50° C., 70° C., 90° C., or 120° C. for 24, 48, 72, 96, or 120 hours such that the electrical conductivity of the conductive portion maintains at least 30%, 50% 70%, or 90% of its strain-free electrical conductivity up to a flexural strain of 1%, 5%, or 10%.

In various examples, conductive filler includes silver particles, copper particles, silver-coated copper particles, and/or graphene flakes. The conductive filler content may be at least 10 vol %, 20 vol %, 30 vol %, 40 vol %, 50 vol %, 60 vol %, 70 vol %, or 80 vol %. The conductive filler content may be at least 10 wt %, 20 wt %, 30 wt %, 40 wt %, 50 wt %, 60 wt %, 70 wt %, or 80 wt %. The first chemical component may include a first functional group, and the second chemical component may include a second functional group reactive with the first functional group to form a thermoset material. In an example, the first functional group may include isocyanate and the second functional group may include amine. In another example, the first functional group may include acrylate and the second functional group may include amine.

### EXAMPLES

It will be apparent to those skilled in the art that many modifications, both to materials, and methods, may be practiced without departing from the scope of the disclosure.

### Example 1: Conductive Polyurea Composition

TABLE 2

| | |
|---|---|
| Component | Wt % |

Part A Isocyanate Composition

| | |
|---|---|
| Hexamethylene diisocyanate (Desmodur N 3900 from Covestro | 20.0 |
| LLC) | |
| Silver flake (AA-192N from Metalor Technologies SA) | 80.0 |

Part B Amine Composition

| | |
|---|---|
| Aspartic ester di-amine (Desmophen NH 1220 from Covestro LLC) | 20.0 |
| Silver flake (AA-192N from Metalor Technologies SA) | 80.0 |

As shown in Table 2, an isocyanate composition was prepared by weighing Desmodur N 39001 and AA-192N2 into a Max 300 L DAC Cup from Flacktek and mixing via a standard Speedmixer procedure. This first mixture was then transferred to an Optimum cartridge via Flacktek SpeedDisc. Similarly, an amine composition was prepared by weighing Desmophen NH 12203 and AA-192N2 into a Max 300 L DAC cup from Flacktek and mixing via a typical Speedmixer procedure. This second mixture was then transferred to an Optimum cartridge via Flacktek SpeedDisc.

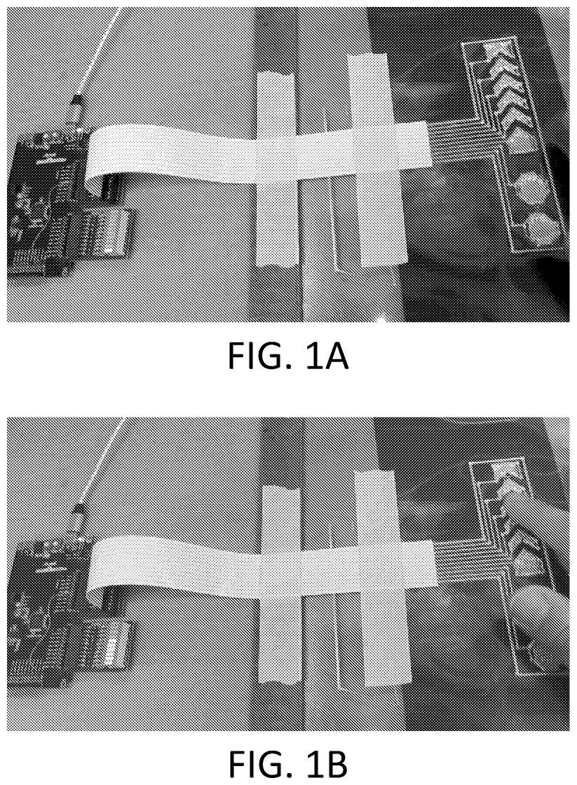

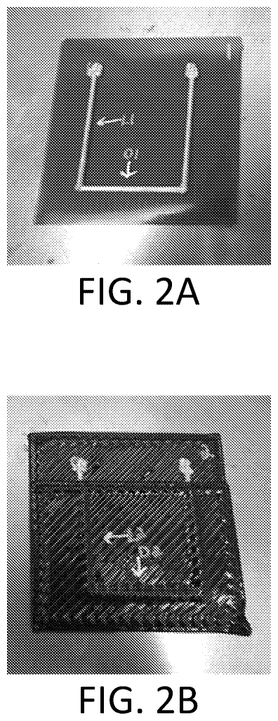

The cartridges with the first and second mixtures were then configured for 3D printing via ambient reactive extrusion utilizing Viscotec 2k extruders mounted to a Lulzbot Taz 6 gantry. Specifically, the mixtures from the two cartridges were mixed into a conductive coreactive composition and deposited onto a substrate. An impedance based sensor was then 3D printed (FIG. 1A, 1B) and tested for conductivity via resistance readings from a digital multi-meter with probes spaced 1 cm apart. See Table 3 for conductivity measurements. As shown, modest heat may be applied to accelerate curing of the conductive polyurea composition of Example 1. Once cured, this sensor was fully functional on multiple substrates such as PET films (as shown in FIG. 1A, 1B). The conductive composition was also deposited directly on a cured 3D-printed polyurea (see FIG. 2A) and deposited as part of a multi-material printing sequence such that the conductive composition is sandwiched between two 3D-printed polyurea layers (see FIG. 2B).

TABLE 3

| | Time in 70° C. Conditions | | | Time in Ambient 25° C. | | |
|---|---|---|---|---|---|---|
| | (days) | | | Conditions (days) | | |
| | 0 | 1 | 2 | 0 | 1 | 2 |
| Example 1 | ∞ | 28.0 | 2.4 | ∞ | ∞ | ∞ |
| Resistance (Ω) | | | | | | |

### Example 2: Conductive Polyurea Composition

TABLE 4

| | |
|---|---|
| Component | Wt % |

Part A Isocyanate Composition

| | |
|---|---|
| Isocyanate Prepolymer (Proprietary isocyanate from PPG | 15.0 |
| Industries, Inc.) | |
| Hexamethylene diisocyanate (Desmodur N 3900 from Covestro | 5.0 |
| LLC) | |
| Silver flake (AA-192N from Metalor Technologies SA) | 80.0 |

Part B Amine Composition

| | |
|---|---|
| Primary aliphatic polyether di-amine (Jeffamine D-2000 from | 10.0 |
| Huntsman International LLC) | |
| Aspartic ester di-amine (Desmophen NH 1220 from Covestro LLC) | 10.0 |
| Silver flake (AA-192N from Metalor Technologies SA) | 80.0 |

As shown in Table 4, an isocyanate composition was prepared by weighing Isocyanate Prepolymer, Desmodur N 39001, and AA-192N2 into a Max 300 L DAC Cup from Flacktek and mixing via a standard Speedmixer procedure. This first mixture was then transferred to an Optimum cartridge via Flacktek SpeedDisc. Similarly, an amine composition was prepared by weighing Jeffamine D-2000, Desmophen NH 12203, and AA-192N2 into a Max 300 L DAC cup from Flacktek and mixing via a typical Speedmixer procedure. This second mixture was then transferred to an Optimum cartridge via Flacktek SpeedDisc.

The cartridges with the first and second mixtures were then configured for 3D printing via ambient reactive extrusion utilizing Viscotec 2k extruders mounted to a Lulzbot Taz 6 gantry. Specifically, the mixtures from the two cartridges were mixed into a conductive coreactive composition and deposited onto a substrate. The deposited conductive composition was tested for conductivity via resistance readings from a digital multi-meter with probes spaced 1 cm apart. See Table 5 for conductivity measurements. As shown, modest heat may be applied to accelerate curing of the conductive polyurea composition of Example 2.

TABLE 5

| | Time in 70° C. Conditions | | | Time in Ambient 25° C. | | |
|---|---|---|---|---|---|---|
| | (days) | | | Conditions (days) | | |
| | 0 | 1 | 2 | 0 | 1 | 2 |
| Example 2 | ∞ | 0.5 | 0.5 | ∞ | ∞ | ∞ |
| Resistance (Ω) | | | | | | |

Tensile tests were performed on dogbones, conforming to ASTM D638, 3D printed using the conductive polyurea composition of Example 2. The dogbones were tested 2 days after printing with heat treatment (70° C.). The tensile results are shown in Table 6.

TABLE 6

| | Young's Modulus (MPa) | Percent Elongation (%) |
|---|---|---|
| Example 2 | 0.81 | 50 |

### Example 3: Conductive Aza-Michael Addition Composition

TABLE 7

| | |
|---|---|
| Component | Wt % |

Part A Acrylate Composition

| | |
|---|---|
| Melamine acrylate (Miramer SC9610 from Miwon Specialty | 20.0 |
| Chemical Co. Ltd) | |
| Silver flake (AA-192N from Metalor Technologies SA) | 80.0 |

Part B Amine Composition

| | |
|---|---|
| Amine Adduct (proprietary amine adduct from PPG Industries, | 20.0 |
| Inc.) | |
| Silver flake (AA-192N from Metalor Technologies SA) | 80.0 |

As shown in Table 7, an acrylate composition was prepared by weighing Miramer SC9610 and AA-192N2 into a Max 300 L DAC Cup from Flacktek and mixing via a standard Speedmixer procedure. This first mixture was then transferred to an Optimum cartridge via Flacktek SpeedDisc. Similarly, an amine composition was prepared by weighing proprietary amine adduct and AA-192N2 into a Max 300 L DAC cup from Flacktek and mixing via a typical Speedmixer procedure. This second mixture was then transferred to an Optimum cartridge via Flacktek SpeedDisc.

The cartridges with the first and second mixtures were then configured for 3D printing via ambient reactive extrusion utilizing Viscotec 2k extruders mounted to a Lulzbot Taz 6 gantry. Specifically, the mixtures from the two cartridges were mixed into a conductive coreactive composition and deposited onto a substrate. The deposited conductive composition was tested for conductivity via resistance readings from a digital multi-meter with probes spaced 1 cm apart. See Table 8 for conductivity measurements. As shown, electrical conductivities may be measured after a day of curing, with and without application of modest heat.

TABLE 8

| | Time in 70° C. Conditions | | | Time in Ambient 25° C. | | |
|---|---|---|---|---|---|---|
| | (days) | | | Conditions (days) | | |
| | 0 | 1 | 2 | 0 | 1 | 2 |
| Example 3 | ∞ | 0.7 | 0.6 | ∞ | 1.7 | 0.6 |
| Resistance (Ω) | | | | | | |

Tensile tests were performed on dogbones, conforming to ASTM D638, 3D printed using the conductive Aza-Michael Addition composition of Example 3. The dogbones were tested 2 days after printing with heat treatment (70° C.). The tensile results are shown in Table 9.

TABLE 9

| | Young's Modulus (MPa) | Percent Elongation (%) |
|---|---|---|
| Example 3 | 451 | 2 |

### Example 4: Conductive Polyurea Composition with Silver-Coated Copper Flakes

TABLE 10

| | |
|---|---|
| Component | Wt % |

Part A Isocyanate Composition

| | |
|---|---|
| Isocyanate Prepolymer (Proprietary isocyanate from PPG | 37.5 |
| Industries, Inc.) | |
| Hexamethylene diisocyanate (Desmodur N 3900 from Covestro | 12.5 |
| LLC) | |
| Silver-coated copper flake (AC-415 from Ames Goldsmith | 50.0 |
| Corporation) | |

Part B Amine Composition

| | |
|---|---|
| Primary aliphatic polyether di-amine (Jeffamine D-2000 from | 25.0 |
| Huntsman International LLC) | |
| Aspartic ester di-amine (Desmophen NH 1220 from Covestro LLC) | 25.0 |
| Silver-coated copper flake (AC-415 from Ames Goldsmith | 50.0 |
| Corporation) | |

As shown in Table 10, an isocyanate composition was prepared by weighing Isocyanate Prepolymer, Desmodur N 39001, and AC-415 into a Max 300 L DAC Cup from Flacktek and mixing via a standard Speedmixer procedure. This first mixture was then transferred to an Optimum cartridge via Flacktek SpeedDisc. Similarly, an amine composition was prepared by weighing Jeffamine D-2000, Desmophen NH 12203, and AC-415 into a Max 300 L DAC cup from Flacktek and mixing via a typical Speedmixer procedure. This second mixture was then transferred to an Optimum cartridge via Flacktek SpeedDisc.

The cartridges with the first and second mixtures were then configured for 3D printing via ambient reactive extrusion utilizing Viscotec 2k extruders mounted to a Lulzbot Taz 6 gantry. Specifically, the mixtures from the two cartridges were mixed into a conductive coreactive composition and deposited onto a substrate. The deposited conductive composition was tested for conductivity via resistance readings from a digital multi-meter with probes spaced 1 cm apart. See Table 11 for conductivity measurements.

TABLE 11

| | Time in 70° C. | | Time in Ambient 25° C. | |
|---|---|---|---|---|
| | Conditions (days) | | Conditions (days) | |
| | 0 | 3 | 0 | 3 |
| Example 4 | 4.2 | 1.2 | 4.2 | 3.9 |
| Resistance (Ω) | | | | |

Tensile tests were performed on dogbones, conforming to ASTM D638, 3D printed using the conductive polyurea composition of Example 4. The dogbones were tested 2 days after printing with heat treatment (70° C.). The tensile results are shown in Table 12.

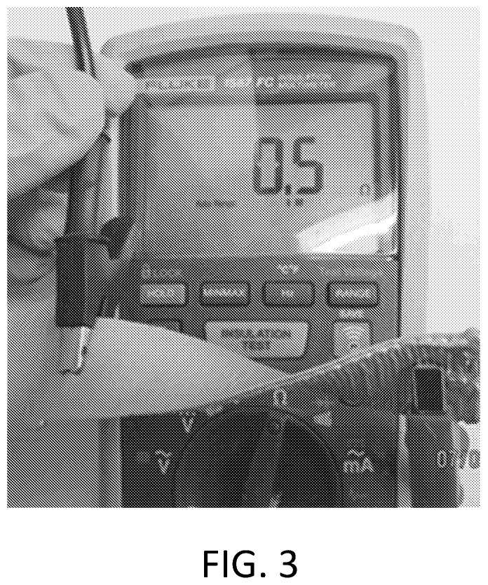

To demonstrate the mechanical integrity of features fabricated by 3D printing the composition of Example 4, a twist test was performed to a strip of 3D printed meandering pattern on a piece of flexible polyurethane. As shown in FIG. 3, the printed pattern maintained measurable conductivity even is a twisted state. Resistivity results are shown in Table 12.

TABLE 12

| | Tensile | | |
|---|---|---|---|
| | Percent | Resistivity at 0% | Resistivity at 5% |
| | Elongation | flexural strain | flexural strain |
| Sample | (%) | (Ω*m) | (Ω*m) |
| Example 4, after 2 | 39 | 0.67 | 0.95 |
| days in 70° C. | | | |
| Conditions | | | |
| Example 4, after 2 | 38 | 0.64 | 1.59 |
| days in Ambient | | | |
| Conditions | | | |

### Example 5: Conductive Polyurea Composition with Copper Flakes

TABLE 13

| | |
|---|---|
| Component | Wt % |

Part A Isocyanate Composition

| | |
|---|---|
| Isocyanate Prepolymer (Proprietary isocyanate from PPG | 15.0 |
| Industries, Inc.) | |
| Hexamethylene diisocyanate (Desmodur N 3900 from Covestro | 5.0 |
| LLC) | |
| Copper flake (from Ames Goldsmith Corporation) | 80.0 |

Part B Amine Composition

| | |
|---|---|
| Primary aliphatic polyether di-amine (Jeffamine D-2000 from | 10.0 |
| Huntsman International LLC) | |
| Aspartic ester di-amine (Desmophen NH 1220 from Covestro LLC) | 10.0 |
| Copper flake (from Ames Goldsmith Corporation) | 80.0 |

As shown in Table 13, an isocyanate composition may be prepared by weighing Isocyanate Prepolymer, Desmodur N 39001, and copper flakes into a Max 300 L DAC Cup from Flacktek and mixing via a standard Speedmixer procedure. This first mixture may then be transferred to an Optimum cartridge via Flacktek SpeedDisc. Similarly, an amine composition may be prepared by weighing Jeffamine D-2000, Desmophen NH 12203, and copper flakes into a Max 300 L DAC cup from Flacktek and mixing via a typical Speedmixer procedure. This second mixture may then be transferred to an Optimum cartridge via Flacktek SpeedDisc. The cartridges with the first and second mixtures may then be configured for 3D printing via ambient reactive extrusion utilizing Viscotec 2k extruders mounted to a Lulzbot Taz 6 gantry. Specifically, the mixtures from the two cartridges may be mixed into a conductive coreactive composition and then deposited onto a substrate.

### Aspects of the Invention

The invention can be further defined by one or more of the following aspects.

Aspect 1. A method of forming an article includes: combining first and second chemical components that are reactive with each other to form a coreactive composition; depositing the coreactive composition to form a conductive portion of an article; wherein, 48 hours after depositing, the conductive portion comprises: a tensile modulus of at least 5 MPa; and an electrical conductivity of at least 2 S/m; wherein the coreactive composition comprising: a solvent content less than 5 wt %; and a conductive filler content effective for the conductive portion to reach the electrical conductivity of at least 2 S/m.

Aspect 2. The method of aspect 1, further includes: depositing a matrix composition to form a first matrix portion of the article; wherein the first matrix portion is covalently bound to the conductive portion and arranged at least partially above the conductive portion.

Aspect 3. Any of the methods of aspects 1-2, further includes: depositing a matrix composition to form a second matrix portion of the article; wherein the second matrix portion is covalently bound to the conductive portion and arranged at least partially below the conductive portion.

Aspect 4. Any of the methods of aspects 2-3, wherein the tensile elongation value at break of the first matrix portion is equal or less than the tensile elongation value at break of the conductive portion.

Aspect 5. Any of the methods of aspects 2-4, wherein the flexural strain value at break of the first matrix portion is equal or less than the flexural strain value at break of the conductive portion.

Aspect 6. Any of the methods of aspects 1-5, wherein the conductive portion achieves conductivity 0.5 S/m in 30 minutes in ambient condition without application of heat or actinic radiation.

Aspect 7. Any of the methods of aspects 1-6, further includes: curing the deposited coreactive composition at 70° C. for 48 hours such that the electrical conductivity of the conductive portion exceeds 1 S/m.

Aspect 8. Any of the methods of aspects 1-7, further includes: curing the deposited coreactive composition at 70° C. for 48 hours such that the tensile modulus of the conductive portion exceeds 5 MPa.

Aspect 9. Any of the methods of aspects 1-8, wherein the conductive portion further has a tensile modulus of at least 5 MPa 48 hours after deposition without application of heat or actinic radiation.

Aspect 10. Any of the methods of aspects 1-9, wherein the conductive portion further has a fracture strain of at least 5% 48 hours after deposition without application of heat or actinic radiation.

Aspect 11. Any of the methods of aspects 1-10, wherein the electrical conductivity of the conductive portion maintains at least 40% of its strain-free electrical conductivity up to a flexural strain of 5% 48 hours after deposition without application of heat or actinic radiation.

Aspect 12. Any of the methods of aspects 1-11, further includes: curing the deposited coreactive composition at 70° C. for 48 hours such that a tensile modulus of the conductive portion exceeds 500 MPa.

Aspect 13. Any of the methods of aspects 1-12, further includes: curing the deposited coreactive composition at 70° C. for 48 hours such that a fracture strain of the conductive portion exceeds 5%.

Aspect 14. Any of the methods of aspects 1-13, further includes: curing the deposited coreactive composition at 70° C. for 48 hours such that the electrical conductivity of the conductive portion maintains at least 70% of its strain-free electrical conductivity up to a flexural strain of 5%.

Aspect 15. Any of the methods of aspects 1-14, wherein the conductive portion is deposited directly onto an object surface of an object.

Aspect 16. The method of aspect 15, wherein the object surface is nonplanar.

Aspect 17. Any of the methods of aspects 15-16, wherein the object is an aerospace object, an automobile object, an architectural object, a circuit board, or a photovoltaic cell.

Aspect 18. Any of the methods of aspects 1-17, wherein the conductive portion forms a capacitive sensing circuit.

Aspect 19. Any of the methods of aspects 1-18, wherein the conductive filler includes silver particles, copper particles, silver-coated copper particles, or graphene flakes.

Aspect 20. Any of the methods of aspects 1-19, wherein the conductive filler content is at least 45 vol %.

Aspect 21. Any of the methods of aspects 1-20, wherein the conductive filler content is at least 50 wt %.

Aspect 22. Any of the methods of aspects 1-21, wherein the conductive filler content is at least 75 wt %.

Aspect 23. Any of the methods of aspects 1-22, wherein the first chemical component comprising a first functional group; and the second chemical component comprising a second functional group reactive with the first functional group to form a thermoset material.

Aspect 24. The method of aspect 23, wherein the first functional group includes isocyanate and the second functional group includes amine.

Aspect 25. The method of aspect 23, wherein the first functional group includes acrylate and the second functional group includes amine.

Aspect 26. Any of the methods of aspects 1-25, wherein depositing comprises three-dimensional printing.

Aspect 27. An article fabricated using any of the methods of aspects 1-26.

Finally, it should be noted that there are alternative ways of implementing the embodiments disclosed herein. Accordingly, the present embodiments are to be considered as illustrative and not restrictive. Furthermore, the claims are not to be limited to the details given herein and are entitled to their full scope and equivalents thereof.

What is claimed is:

1.-27. (canceled)

28. A method of forming an article comprising:
combining first and second chemical components that are reactive with each other to form a coreactive composition; and
depositing the coreactive composition to form a conductive portion of an article, wherein:
48 hours after depositing, the conductive portion comprises:
a tensile modulus of at least 5 MPa; and
an electrical conductivity of at least 2 S/m, and
the coreactive composition comprises:
a solvent content less than 5 wt %; and
a conductive filler content effective for the conductive portion to reach the electrical conductivity of at least 2 S/m.

29. The method of claim 28, further comprising:
depositing a matrix composition to form a first matrix portion of the article,
wherein the first matrix portion is covalently bound to the conductive portion and arranged at least partially above the conductive portion.

30. The method of any of claim 29, further comprising:
depositing a matrix composition to form a second matrix portion of the article,
wherein the second matrix portion is covalently bound to the conductive portion and arranged at least partially below the conductive portion.

31. The method of claim 29, wherein:
the tensile elongation value at break of the first matrix portion is equal or less than the tensile elongation value at break of the conductive portion, and/or
the flexural strain value at break of the first matrix portion is equal or less than the flexural strain value at break of the conductive portion.

32. The method of claim 28, wherein the conductive portion achieves an electrical conductivity of 0.5 S/m in 30 minutes under ambient condition without application of heat or actinic radiation.

33. The method of claim 28, further comprising:
curing the deposited coreactive composition at 70° C. for 48 hours such that the electrical conductivity of the conductive portion exceeds 1 S/m, and/or the tensile modulus of the conductive portion exceeds 5 MPa.

34. The method of claim 28, wherein, 48 hours after deposition without application of heat or actinic radiation, the conductive portion further has a tensile modulus of at least 5 MPa and/or has a fracture strain of at least 5%,

35. The method of claim 28, wherein, 48 hours after deposition without application of heat or actinic radiation, the electrical conductivity of the conductive portion maintains at least 40% of its strain-free electrical conductivity up to a flexural strain of 5%,

36. The method of any of claim 28, further comprising:
curing the deposited coreactive composition at 70° C. for 48 hours such that a tensile modulus of the conductive portion exceeds 500 MPa, a fracture strain of the conductive portion exceeds 5%, and/or the electrical conductivity of the conductive portion maintains at least 70% of its strain-free electrical conductivity up to a flexural strain of 5%.

37. The method of claim 28, wherein the conductive portion is deposited directly onto a nonplanar object surface of an object.

38. The method of claim 28, wherein depositing comprises three-dimensional printing.

39. An article comprising:
a conductive portion comprising a first chemical component and a second chemical component, the first chemical component and the second chemical component reacting to form a coreactive composition, wherein:
the coreactive composition has a solvent content less than 5 wt % and a conductive filler, and
the conductive portion has a tensile modulus of at least 5 MPa and an electrical conductivity of at least 2 S/m, the electric conductivity based upon the content of the conductive filler.

40. The article of claim 39, wherein the article is an aerospace object, an automobile object, an architectural object, a circuit board, a photovoltaic cell, or a power distribution device.

41. The article of claim 39, wherein the conductive portion comprises a capacitive sensing circuit.

42. The article of claim 39, wherein the conductive filler further comprises silver particles, copper particles, silver-coated copper particles, or graphite-based materials.

43. The article of claim 39, wherein the conductive filler content is at least 45 vol % of the coreactive composition.

44. The article of claim 39, wherein the conductive filler content is at least 50 wt %.

45. The article of claim 39, wherein the first chemical component comprises an isocyanate and the second chemical component comprises an amine.

46. The article of claim 39, wherein the first chemical component comprises an acrylate and the second chemical component comprises an amine.

47. An article additively manufactured by:
combining a first chemical component and second chemical component the first chemical component and the second chemical component reactive form a coreactive composition, the coreactive composition comprising a solvent content of 5 wt. % or less and a conductive filler; and
depositing the coreactive composition to form a conductive portion of an article, wherein
the conductive portion comprising a thermoset, and 48 hours after depositing, the conductive portion comprises a tensile modulus of at least 5 MPa and an electrical conductivity of at least 2 S/m, the electric conductivity based upon the content of the conductive filler.
